(19) United States
(12) Patent Application Publication
(10) Pub. No.: US 2026/0052896 A1
(43) Pub. Date: Feb. 19, 2026

(54) METAL CARBENE COMPLEX AND ITS USE

(71) Applicant: City University of Hong Kong, Kowloon (HK)

(72) Inventors: Yun Chi, Kowloon (HK); Jie Yan, Kowloon (HK); Yixin WU, Kowloon (HK)

(21) Appl. No.: 18/805,695

(22) Filed: Aug. 15, 2024

(51) Int. Cl. H10K 85/30; C09K 11/06; H10K 50/81; H10K 50/82; H10K 85/60

(52) U.S. Cl. CPC H10K 85/342; C09K 11/06; H10K 50/81; H10K 50/82; H10K 85/654; H10K 85/6572; C09K 2211/1044

(57) ABSTRACT

A metal carbene complex for organic light emitting diodes (OLEDs) includes a ligand L having Formula (I). The metal carbene complex can be used in organic emitting diodes.

### TECHNICAL FIELD

The present invention relates to a metal carbene complex, for example, particularly, but not exclusively, a metal carbene complex having a ligand with a peri-substituent for organic emitting diodes (OLEDs) and use of the metal carbene complex in OLEDs.

### BACKGROUND OF THE INVENTION

Organic light-emitting diodes (OLEDs) have been considered to be one of the most important technologies of the 21st century. Despite the remarkable progression, both the academic and industrial sectors are still looking for better and durable RGB emitters. These emitters also need to have capability of harvesting both the electrically generated singlet and triplet excitons for less power consumption and higher performances. Meanwhile, the associate OLED should achieve longer operation lifespans, which could be, in part, solved by using more robust and durable emitters, together with the achievement of balanced carrier transports during their operation.

In particular, it is believed that OLEDs that exhibit efficient blue luminescence are one of the important components for the next-generation solid-state lighting luminaries and full color displays. Currently, transition metal complexes such as iridium(III)-based carbene emitters are considered to be one of the options for blue emitters. Such carbene complexes generally include carbene chelates with an N-alkyl substituent, which cannot undergo C—H activation and cyclometalation with the metal element under typical reaction conditions, leaving the metal atom to react only with the remaining N-aryl substituent, resulting in the formation of meridional (m-) and facial (f-)isomers. However, it is believed that, on the one hand, these iridium(III) emitters with N-alkyl appendages are generally less stable, and, on the other hand, that the f-isomers are more physically and electrochemically stable and may display narrowed emission bandwidth as compared to the m-isomers.

Thus, there remains a strong need for improved chelate design that could lead to the formation of only one or predominantly one metal carbene emitter, particularly the f-substituted iridium(III) carbene emitter during their synthesis, rather than yielding multiple products that would require tedious separation.

### SUMMARY OF THE INVENTION

In a first aspect of the present invention, there is provided a metal carbene complex for organic light emitting diodes (OLEDs) comprising a ligand L having Formula (I):

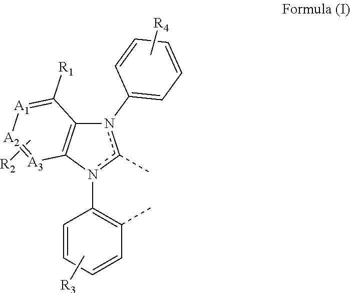

wherein: R₁ is a peri-substituent selected from the group consisting of alkyl, haloalkyl, alkoxy, aryloxy, aryl, nitrile, and isonitrile; R₂ represents mono, di, or tri substitutions; R₃ and R₄ each represent mono or di substitutions; wherein R₂, R₃ and R₄ are each independently selected from the group consisting of hydrogen, alkyl, haloalkyl, alkoxy, aryloxy, aryl, nitrile, isonitrile, cyanate, isocyanate, and a combination thereof; A₁, A₂ and A₃ are each independently selected from group consisting of C and N, provided that A₁, A₂ and A₃ are not N at the same time; and the ligand L is coordinated to a metal M having an atomic number greater than 40.

Optionally, R₁ is selected from the group consisting of C1-C10 linear or branched alkyl, unsubstituted or substituted phenyl, trifluoromethyl, and nitrile.

It is optional that R₁ is selected from the group consisting of C1-C4 linear or branched alkyl, unsubstituted phenyl, trifluoromethyl, and nitrile.

Optionally, R₂ is selected from the group consisting of hydrogen, C1-C10 linear or branched alkyl, unsubstituted or substituted phenyl, trifluoromethyl, nitrile, and a combination thereof.

It is optional that R₃ and R₄ are each independently selected from the group consisting of hydrogen, C1-C10 linear or branched alkyl, trifluoromethyl, nitrile, and a combination thereof.

Optionally, when either R₃ or R₄ includes an alkyl, the maximum number of the alkyl is 2.

It is optional that R₃ and R₄ are each independently located at para-position, meta-position or at both the para- and meta-positions.

Optionally, the metal M is iridium or platinum.

In an optional embodiment, the metal carbene complex is homoleptic.

In an optional embodiment, the metal carbene complex is heteroleptic.

In an optional embodiment, the ligand L has a Formula selected from the group consisting of:

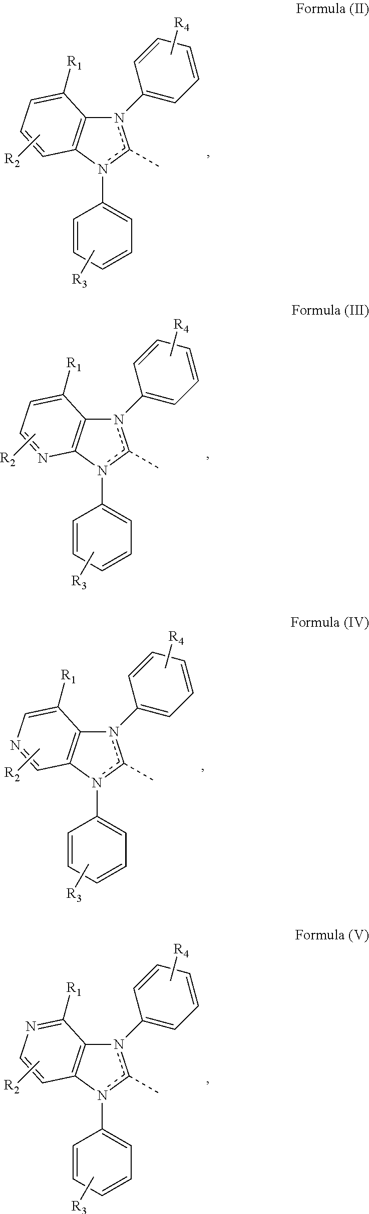

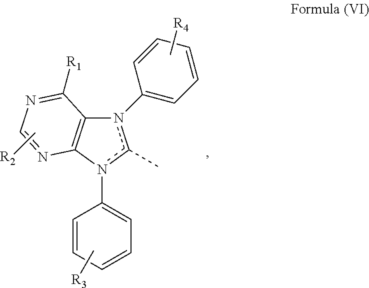

wherein: R₁ is selected from the group consisting of methyl, ethyl, iso-propyl, tert-butyl, trifluoromethyl, and nitrile; R₂ is a mono substitution selected from the group consisting of hydrogen, tert-butyl, trifluoromethyl, phenyl, 2,6-dimethylphenyl and nitrile; and R₃ and R₄ each represent a mono substitution located at para- or meta-position and are each independently selected from the group consisting of hydrogen, tert-butyl, and nitrile.

In an optional embodiment, the metal carbene complex has a Formula selected from the group consisting of:

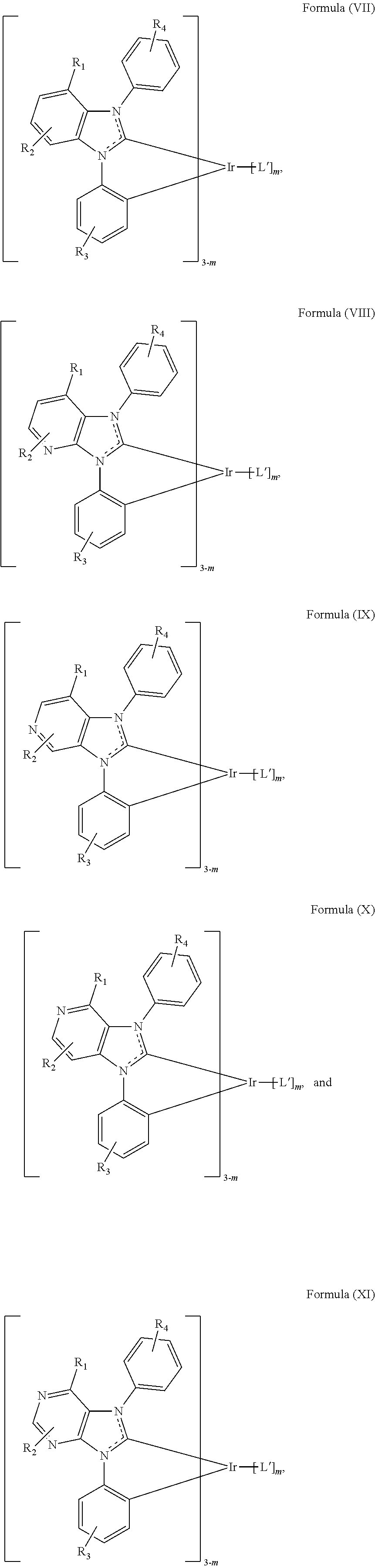

wherein: R₁ is selected from the group consisting of methyl, ethyl, iso-propyl, tert-butyl, trifluoromethyl, and nitrile; R₂ represents a mono substitution selected from the group consisting of hydrogen, tert-butyl, trifluoromethyl, phenyl, 2,6-dimethylphenyl and nitrile; R₃ and R₄ each represent a mono substitution located at para- or meta-position and are each independently selected from the group consisting of hydrogen, tert-butyl, and nitrile; L′ is a different ligand; and m is 0, 1, or 2.

Optionally, the metal carbene complex is a facial isomer.

It is optional that L′ has a Formula of:

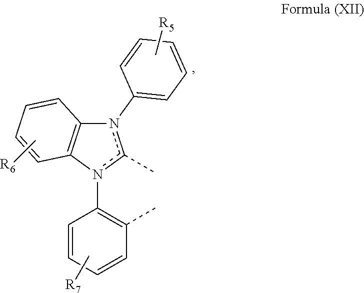

wherein R₅, R₆, and R₇ each represent mono, di, tri, or tetra substitutions; and wherein R₅, R₆, and R₇ each independently selected from the group consisting of hydrogen, alkyl, haloalkyl, alkoxy, aryloxy, aryl, nitrile, isonitrile, cyanate, and isocyanate, and a combination thereof.

In an optional embodiment, L′ has a Formula selected from the group consisting of:

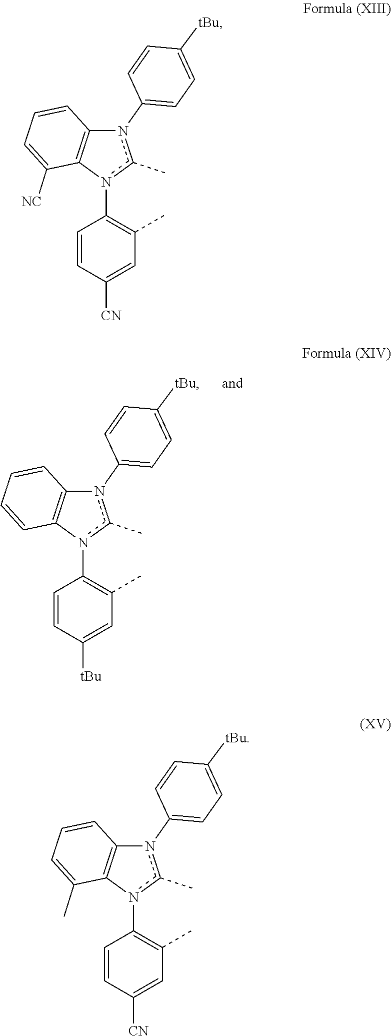

In an optional embodiment, the metal carbene complex further has a Formula selected from the group consisting of:

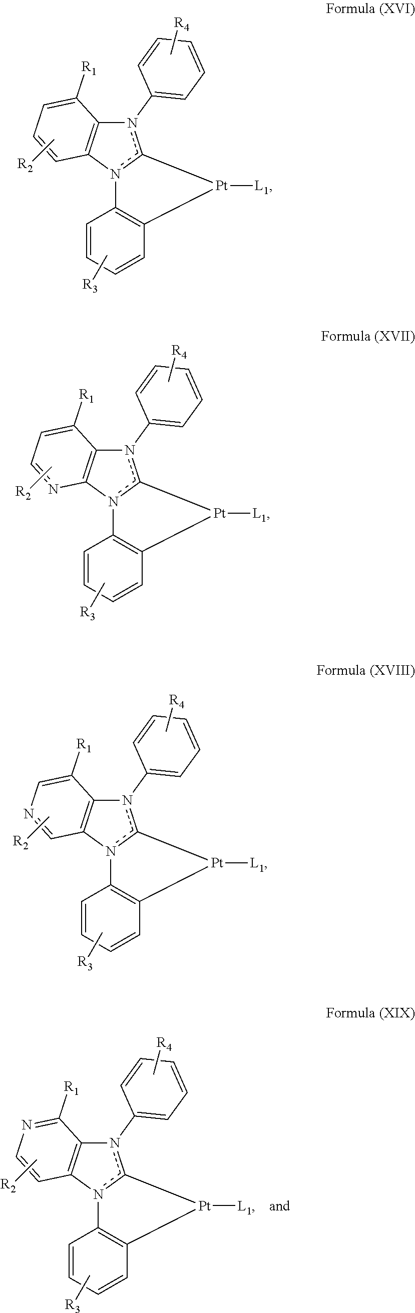

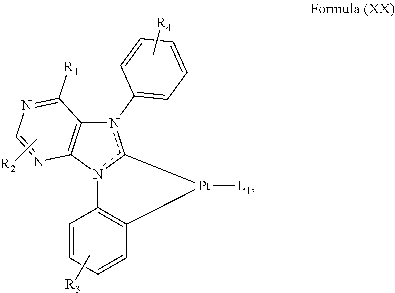

wherein: R₁ is selected from the group consisting of methyl, ethyl, iso-propyl, tert-butyl, trifluoromethyl, and nitrile; R₂ represents a mono substitution selected from the group consisting of hydrogen, tert-butyl, trifluoromethyl, phenyl, 2,6-dimethylphenyl and nitrile; R₃ and R₄ each represent a mono substitution located at para- or meta-position and are each independently selected from the group consisting of hydrogen, tert-butyl, and nitrile; and L₁ is a different bidentate ligand.

Optionally, L₁ is selected from the group consisting of:

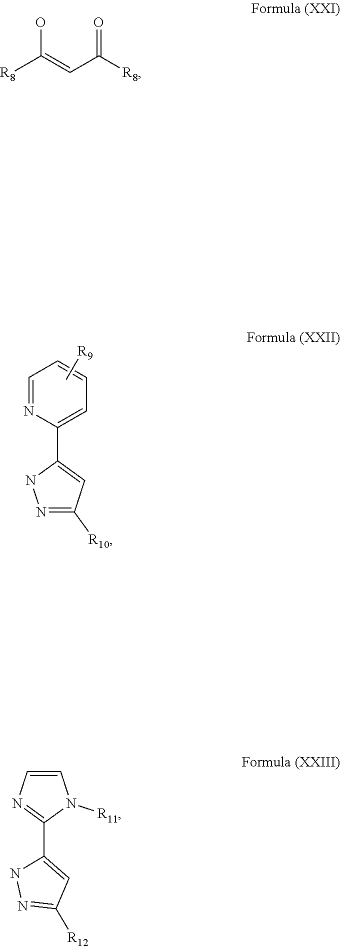

wherein: R₈ is selected from the group consisting of hydrogen, alkyl, haloalkyl, aryl, and a combination thereof; R₉ represents mono, di, tri, or tetra substitution, and is selected from the group consisting of hydrogen, alkyl, haloalkyl, alkoxy, aryloxy, aryl, nitrile, isonitrile, cyanate, isocyanate, and a combination thereof; and R₁₀, R₁₁ and R₁₂ are each independently selected from the group consisting of hydrogen, alkyl, haloalkyl, alkoxy, aryloxy, aryl, nitrile, isonitrile, cyanate, isocyanate, and a combination thereof.

In a second aspect of the present invention, there is provided an organic light emitting diodes comprising an emissive layer including at least one metal carbene complex in accordance with the first aspect of the invention.

Optionally, the emissive layer further includes a host selected from the group consisting of mCP, mCPCN, mCBP, and DPEPO, to which at least one metal carbene complex is doped.

It is optional that the emissive layer further includes at least one organoboron terminal emitter, including v-DABNA, m-DINBO, and t-DABNA.

Optionally, at least one metal carbene complex is about 5 wt % to about 30 wt % of the emissive layer.

It is optional that the at least one organoboron terminal emitter is about 1 wt % of the emissive layer.

In an optional embodiment, the organic light emitting diodes further comprises: an anode and a cathode, between which the emissive layer is disposed; a hole injection layer disposed between the anode and the emissive layer; a hole transport layer disposed between the hole injection layer and the emissive layer; and an electron transport layer disposed between the cathode and the emissive layer.

It is optional that the hole transport layer is in direct contact with the hole injection layer and the emissive layer.

Optionally, the organic light-emitting diodes further includes an electron injection layer disposed between and is in direct contact with the cathode and the electron transport layer.

### BRIEF DESCRIPTION OF DRAWINGS

The patent or application file contains at least one drawing executed in color.

Copies of this patent or patent application publication with color drawing(s) will be provided by the Office upon request and payment of the necessary fee.

The invention will now be more particularly described, by way of example only, with reference to the accompanying drawings, in which:

FIG. 1 is a schematic diagram illustrating the cross-section view of an organic emitting diodes (OLEDs) in accordance with an embodiment of the present invention;

FIG. 2 is a schematic diagram illustrating the synthetic route of the pro-chelates L(1)H₂ and L(4)H₂. Conditions (i): 4-tert-butyl aniline, KOH, RT; (ii) Fe, HCOOH, reflux; (iii) Zn(CN)₂, Pd(PPh₃)₄, 120° C.; and (iv) diphenyliodonium triflate or (3-tert-butylphenyl)(mesityl)iodonium triflate, Cu(OAc)₂, 110° C.;

FIG. 3 is a schematic diagram illustrating the synthetic route of the pro-chelates L(47)H₂ and L(48)H₂. Conditions (i): NBS, DCM, 0° C.; (ii) triethyl orthoformate, 140° C.; (iii) 4-tert-butyl aniline (or aniline), 140° C.; (iv) DBU, CuI, 120° C.; (v) diphenyliodonium triflate, Cu(OAc)₂, 110° C. and (vi) (4-tert-butylphenyl)(mesityl)iodonium triflate, Cu(OAc)₂, 110° C.;

FIG. 4 is a schematic diagram illustrating the synthetic route of the pro-chelate L(61)H₂. Conditions (i): ethyl 3-oxobutanoate, NaOH, RT; (ii) NBS, DCM, 0° C.; (iii) POCl₃, 80° C.; (iv) aniline, KOH, DMSO; (v) 4-tert-butyl aniline, Pd₂(dba)₃, Sphos, NaO^{t}Bu and (vi) triethyl orthoformate, NH₄BF₄, trimethylsilyl chloride, reflux;

FIG. 5A shows the molecular structure of f-CN1 (complex 1) with thermal ellipsoids shown at 30% probability level. Selected bond lengths of f-CN1: Ir-C13=2.037(3), Ir-C37=2.032(3), Ir-C61=2.035(3), Ir-C1=2.088(3), Ir-C25=2.081(4), Ir-C49=2.081(3) Å. All hydrogen atoms were omitted for clarity;

FIG. 5B shows the molecular structure of f-CN2 (complex 4) with thermal ellipsoids shown at 30% probability level. Selected bond lengths of f-CN2: Ir-C13=2.047(2), Ir-C41=2.042(3), Ir-C69=2.040(2), Ir-C1=2.090(3), Ir-C29=2.099(2), Ir-C57=2.084(2) Å. All hydrogen atoms were omitted for clarity;

FIG. 6 shows the molecular structure of f-Ir(tBpp)₃ (complex 48) with thermal ellipsoids shown at 30% probability level. Selected bond length (A): Ir-C13=2.0428(17), Ir-C19=2.0903(19). Selected bond angles (°): C13-Ir-C19′=168.52(8). All hydrogen atoms were omitted for clarity;

FIG. 7A shows the UV-Vis absorption and emission spectra of f-CN1 (complex 1) and f-CN2 (complex 4) in CH₂Cl₂ solution at RT; the dash lines indicated the corresponding phosphorescence recorded at 77 K;

FIG. 7B is a table summarizing the photophysical data of f-CN1 (complex 1) and f-CN2 (complex 4) recorded in CH₂Cl₂ solution and thin film states at RT;

FIG. 8A shows the UV-Vis absorption and emission spectra of f-Ir(tBpp)₃ (complex 47) and f-Ir(ptBp)₃ (complex 48) in degassed toluene at RT;

FIG. 8B is a table summarizing the photophysical data of f-Ir(tBpp)₃ (complex 47) and f-Ir(ptBp)₃ (complex 48) in degassed toluene at RT;

FIG. 9A shows the emission spectra of f-Ir(tBpp)₃ (complex 47) and f-Ir(ptBp)₃ (complex 48) in PMMA thin film at 2 wt % at RT;

FIG. 9B is a table summarizing the photophysical data of f-Ir(tBpp)₃ (complex 47) and f-Ir(ptBp)₃ (complex 48) in (solid-state) PMMA thin films at RT;

FIG. 10 shows the thermogravimetric diagrams of f-CN1 (complex 1) and f-CN2 (complex 4) measured under N₂;

FIG. 11 is a table summarizing the electrochemical data, electrical energy levels and stability data of f-CN1 (complex 1) and f-CN2 (complex 4) at RT;

FIG. 12 shows the cyclic voltammograms of f-CN1 (complex 1) and f-CN2 (complex 4) in acetonitrile (ACN) solution;

FIG. 13 shows the PYS spectra of f-CN1 (complex 1) (left) and f-CN2 (complex 4) (right);

FIG. 14A shows the UV-Vis absorption spectra of f-CN1 (complex 1) and f-CN2 (complex 4) neat film;

FIG. 14B shows the emission spectra of f-CN1 (complex 1) and f-CN2 (complex 4) neat film;

FIG. 15A shows the cyclic voltammograms of f-Ir(tBpp)₃ (complex 47) and f-Ir(ptBp)₃ (complex 48) in ACN solution;

FIG. 15B is a table summarizing the electrochemical data, energy gap and decomposition temperature of f-Ir(tBpp)₃ (complex 47) and f-Ir(ptBp)₃ (complex 48);

FIG. 16 shows the TGA data of f-Ir(tBpp)₃ (complex 47) and f-Ir(ptBp)₃ (complex 48) with decomposition temperature (T_{d}) at a weight loss of 5 wt %;

FIG. 17 is a table summarizing the calculation excitation energy (λ), oscillator strength (f), primary orbital contributions of the lowest singlet (S₁) and triplet (T₁) excited states, and T₁ transition character for f-CN1 (complex 1) and f-CN2 (complex 4) at their geometries optimized ground state;

FIG. 18 shows the natural transition orbital (NTO) pairs expressing their lowest triplet (T₁) excited states at their geometrical optimized ground state, with the contribution of Ir(III) metal to NTOs provided. The calculated eigenvalues for T₁ NTOs are 0.81 and 0.90 for f-CN1 (complex 1) and f-CN2 (complex 4), respectively. The calculated values for orbital overlap between occupied and virtual NTOs are 0.58 (a.u.) and 0.56 (a.u.) for f-CN1 (complex 1) and f-CN2 (complex 4), respectively;

FIG. 19 is a table summarizing the calculated E_{HOMO}, HOMO-LUMO (H-L) gap, vertical excitation energy (λ) and oscillator strength (f) of the lowest singlet (S₁) and triplet (T₁) excited states, main orbital transition contributions of the S₀→S₁/T₁ excitation processes, and assignment of S₀→T₁ excitation transition for f-Ir(tBpp)₃ (complex 47) and f-Ir(ptBp)₃ (complex 48) at their geometries optimized for the ground state (S₀);

FIG. 20 shows the UV-Vis absorption and emission spectra of f-Ir(tBpp)₃ (complex 47) and f-Ir(ptBp)₃ (complex 48) in degassed toluene at RT;

FIG. 21 is a table summarizing the calculated adiabatic and vertical T₁→S₀ transition energy, radiative lifetime (τ_{rad}), and radiative rate (kᵣ) of f-Ir(tBpp)₃ (complex 47) and f-Ir(ptBp)₃ (complex 48);

FIG. 22 shows the natural transition orbital (NTO) pairs expressing the S₀→T₁ excitation of f-Ir(tBpp)₃ (complex 47) and f-Ir(ptBp)₃ (complex 48) at their geometrical optimized for the ground state, with the contribution of dominant molecular orbitals (MOs) to NTOs provided;

FIG. 23A shows the UV-vis absorption spectra and emission spectra of 30 wt %-f-CN1 (complex 1) in doped mCPCN;

FIG. 23B shows the transient photoluminescence decay curve of f-CN1 (complex 1) in doped mCPCN at RT;

FIG. 23C shows the UV-vis absorption spectra and emission spectra of 30 wt %-f-CN2 (complex 4) in doped mCPCN;

FIG. 23D shows the transient photoluminescence decay curve of f-CN2 (complex 4) in doped mCPCN at RT;

FIG. 24 is a schematic diagram illustrating the cross-section view of an OLEDs in accordance with an embodiment of the present invention;

FIG. 25 shows the energy diagram of the OLEDs of FIG. 24;

FIG. 26 shows the electroluminescence spectra of the OLEDs of FIG. 24;

FIG. 27 shows the current density-voltage-luminance (J-V-L) characteristics of the OLEDs of FIG. 24;

FIG. 28 shows that (emission quantum efficiency-luminance) EQE-L characteristics of the OLEDs of FIG. 24;

FIG. 29 is a table summarizing the OLED and hyper-OLED performance characteristics;

FIG. 30A is a schematic diagram illustrating the cross-section view of a hyper-OLEDs in accordance with an embodiment of the present invention;

FIG. 30B shows the energy diagram of the hyper-OLEDs of FIG. 30A;

FIG. 31A shows the UV-Vis absorption spectrum of v-DABNA and normalized emission spectrum of f-CN1 (complex 1) in doped thin film;

FIG. 31B shows the emission spectra of 30 wt % f-CN1 (complex 1) in doped mCPCN, 1 wt % v-DABNA and 30 wt % f-CN1 (complex 1) in co-doped mCPCN film, and 1 wt % v-DABNA in doped mCPCN film;

FIG. 31C shows the UV-Vis absorption spectrum of m-DINBO and normalized emission spectrum of f-CN1 (complex 1) in doped thin film;

FIG. 31D shows the emission spectra of 30 wt % f-CN1 (complex 1) in doped mCPCN, 1 wt % m-DINBO and 30 wt % f-CN1 (complex 1) in co-doped mCPCN film, and 1 wt % m-DINBO in doped mCPCN film;

FIG. 32A shows the transient photoluminescence decay of 1 wt %-v-DABNA and 30 wt %-f-CN1 (complex 1) in doped mCPCN at RT;

FIG. 32B shows the transient photoluminescence decay of 1 wt %-m-DINBO and 30 wt %-f-CN1 (complex 1) in doped mCPCN at RT;

FIG. 33 shows the electroluminescence spectra of the hyper-OLEDs of FIG. 30A using f-CN1 (complex 1) as a sensitizer, recorded at 0.1 mA;

FIG. 34 shows the J-V-L characteristics of the hyper-OLEDs of FIG. 30A using f-CN2 (complex 4) as a sensitizer;

FIG. 35 shows the EQE-L characteristics of the hyper-OLEDs of FIG. 30A;

FIG. 36A shows the energy diagram of two component OLEDs without the employment of f-CN1 (complex 1) or f-CN2 (complex 4) as the sensitizer;

FIG. 36B shows the electroluminescence spectra of the two component OLEDs without the employment of f-CN1 (complex 1) or f-CN2 (complex 4) as the sensitizer;

FIG. 36C shows the J-V-L characteristics of the two component OLEDs without the employment of f-CN1 (complex 1) or f-CN2 (complex 4) as the sensitizer;

FIG. 36D shows the EQE-L characteristics of the two component OLEDs without the employment of f-CN1 (complex 1) or f-CN2 (complex 4) as the sensitizer;

FIG. 37 is a table summarizing the OLED performance of the two component OLEDs without the employment of f-CN1 (complex 1) or f-CN2 (complex 4) as the sensitizer;

FIG. 38A shows the UV-Vis absorption spectrum of v-DABNA and normalized emission spectrum of f-CN2 (complex 4) film;

FIG. 38B shows the transient photoluminescence decay curve of 1 wt % v-DABNA and 30 wt % f-CN2 (complex 4) in mCPCN at RT;

FIG. 38C shows the emission spectra of 30 wt % f-CN2 (complex 4) in mCPCN, 1 wt % v-DABNA and 30 wt % f-CN2 (complex 4) in mCPCN, and 1 wt % v-DABNA in mCPCN;

FIG. 38D shows the UV-Vis absorption spectrum of m-DINBO and normalized emission spectrum of f-CN2 (complex 4) film;

FIG. 38E shows the transient photoluminescence decay curve of 1 wt % m-DINBO and 30 wt % f-CN2 (complex 4) in mCPCN at RT;

FIG. 38F shows the emission spectra of 30 wt % f-CN2 (complex 4) in mCPCN, 1 wt % m-DINBO and 30 wt % f-CN2 (complex 4) in mCPCN, and 1 wt % m-DINBO in mCPCN;

FIG. 38G shows the electroluminescence spectra of the hyper-OLEDs of FIG. 30A using f-CN2 (complex 4) as a sensitizer, recorded at 0.1 mA;

FIG. 38H shows the EQE-L characteristics of the hyper-OLEDs of FIG. 30A using f-CN2 (complex 4) as a sensitizer;

FIG. 39 is a table summarizing the EQEs and emission maxima of narrowband blue OLED devices with ternary EML;

FIG. 40 shows the energy diagram of the OLEDs and hyper-OLEDs fabricated in accordance with the embodiments of the present invention;

FIG. 41A shows the J-V-L characteristics of the OLEDs using f-Ir(tBpp)₃ (complex 48) as dopant, and that of the hyper-OLEDs using f-Ir(tBpp)₃ (complex 48) as sensitizer together with v-DABNA or t-DABNA as terminal emitter;

FIG. 41B shows the EQE characteristics and power efficiency (PE) as a function of luminance of the OLEDs using f-Ir(tBpp)₃ (complex 48) as dopant, and that of the hyper-OLEDs using f-Ir(tBpp)₃ (complex 48) as sensitizer together with v-DABNA or t-DABNA as terminal emitter;

FIG. 41C shows the electroluminescence spectra of the OLEDs using f-Ir(tBpp)₃ (complex 48) as dopant, and that of the hyper-OLEDs using f-Ir(tBpp)₃ (complex 48) as sensitizer together with v-DABNA or t-DABNA as terminal emitter;

FIG. 42A shows the J-V-L characteristics of the OLEDs using f-Ir(ptBp)₃ (complex 47) as dopant, and that of the hyper-OLEDs using f-Ir(ptBp)₃ (complex 47) as sensitizer together with v-DABNA or t-DABNA as terminal emitter;

FIG. 42B shows the EQE characteristics and power efficiency (PE) as a function of luminance of the OLEDs using f-Ir(ptBp)₃ (complex 47) as dopant, and that of the hyper-OLEDs using f-Ir(ptBp)₃ (complex 47) as sensitizer together with v-DABNA or t-DABNA as terminal emitter;

FIG. 42C shows the electroluminescence spectra of the OLEDs using f-Ir(ptBp)₃ (complex 47) as dopant, and that of the hyper-OLEDs using f-Ir(ptBp)₃ (complex 47) as sensitizer together with v-DABNA or t-DABNA as terminal emitter;

FIG. 43 is a table summarizing the characteristics of OLED devices using phosphorescent dopants (f-Ir(ptBp)₃ (complex 47) and Ir(tBpp)₃ (complex 48)) and corresponding hyper-OLEDs with terminal emitters v-DABNA and t-DABNA; and

FIG. 44 is a table summarizing the blend-film PLQYs of v-DABNA and t-DABNA inf-Ir(ptBp)₃ (complex 47) and Ir(tBpp)₃ (complex 48) and PPT.

### DETAILED DESCRIPTION OF OPTIONAL EMBODIMENT

As used herein, the forms “a”, “an”, and “the” are intended to include the singular and plural forms unless the context clearly indicates otherwise.

The words “example” or “exemplary” used in this invention are intended to serve as an example, instance, or illustration. Any aspect or design described in this disclosure as “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise or clear from context, “X employs A or B” is intended to mean any of the natural inclusive permutations. That is, if X employs A, X employs B, or X employs both A and B, then “X employs A or B” is satisfied under any of the foregoing instances.

As used herein, the phrase “about” is intended to refer to a value that is slightly deviated from the value stated herein. Examples have been described throughout the present disclosure.

It is believed that carbene chelates bearing only N-aryl substituents (i.e., carbene chelates with dual N-aryl groups) may have better performance as compared to those bearing the N-alkyl substituent. In addition, such dual N-aryl groups on carbene chelates may induce a preference for yielding only the f-substituted iridium(III) complexes, which may be attributed to the steric encumbrance exerted by the non-coordinated N-aryl groups on the coordination sphere. Despite the absence of the m-isomer, this could lead to the formation of multiple f-isomers which may still cause problems in separation. Attempts in optimizing the synthesis by introducing inert N-aryl groups such as 2,6-dimethylphenyl, 3,5-dimethylphenyl and analogs thereof on carbene chelates gave no isolable products.

Without wishing to be bound by theory, the inventors have, through their own research, trials, and experiments, devised that by introducing a peri-substituent to a benzo[d]imidazole-2-ylidene, imidazo[4,5-b]pyridinylidene, imidazo[4,5-c]pyridinylidene or purinylidene cyclometalate, the peri-substituent may exert steric interference and induce a partial rotation on the nearby N-aryl substituent of these cyclometalates, resulting in a retarded reactivity toward C—H activation and cyclometallation at this N-aryl site, thereby yielding an f-substituted iridium(III) complex or predominantly an f-substituted iridium(III) complex, no matter it is a homoleptic or a heteroleptic iridium(III) complex. The inventors have further devised that such peri-substituted benzo[d]imidazole-2-ylidene, imidazo[4,5-b]pyridinylidene, imidazo[4,5-c]pyridinylidene and purinylidene cyclometalates may be applied to the preparation of other transition metal complexes, such as platinum(II)-based carbene complexes, in particular, heteroleptic platinum(II)-based carbene complexes, yielding either a cis-isomer or a trans-isomer, or either predominantly a cis-isomer or predominantly a trans-isomer. The aforementioned platinum(II)-based carbene complexes may afford efficient emission with peak maxima spanning the region of 420-550 nm.

In a first aspect of the present invention, there is provided a metal carbene complex for organic light-emitting diodes (OLEDs) comprising a ligand L having Formula (I):

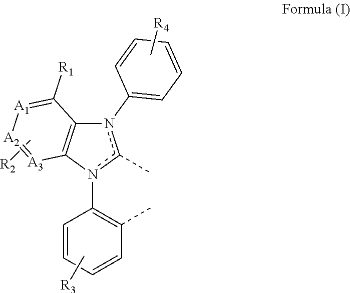

wherein: R₁ is a peri-substituent selected from the group consisting of alkyl, haloalkyl, alkoxy, aryloxy, aryl, nitrile, and isonitrile; R₂ represents mono, di, or tri substitutions; R₃ and R₄ each represent mono or di substitutions; wherein R₂, R₃ and R₄ are each independently selected from the group consisting of hydrogen, alkyl, haloalkyl, alkoxy, aryloxy, aryl, nitrile, isonitrile, cyanate, isocyanate, and a combination thereof; A₁, A₂ and A₃ are each independently selected from group consisting of C and N, provided that A₁, A₂ and A₃ are not N at the same time; the ligand L is coordinated to a metal M having an atomic number greater than 40.

The alkyl may be linear or branched, and may be with 1-10 carbon atoms. Examples of C1-C10 linear alkyl may include methyl, ethyl, propyl, butyl, pentyl, hexyl, heptyl, octyl, nonyl, and decyl. Examples of C1-10 branched alkyl may include isopropyl, n-butyl, isobutyl, sec-butyl, tert-butyl, n-pentyl (amyl), tert-pentyl, neopentyl, isopentyl (isoamyl), sec-pentyl, 3-pentyl, sec-isopentyl, active pentyl and the like.

The alkoxyl may be those derived correspondingly from the aforementioned alkyl groups. Examples of such an alkoxyl may include methoxy, ethoxy, propoxy, butoxy, pentoxy, hexoxy, heptoxy, octoxy, nonoxy, decoxy, isopropoxy, n-butoxy, isobutoxy, sec-butoxy, tert-butoxy, n-pentoxy, tert-pentoxy, neopentoxy, isopentoxy, sec-pentoxy, 3-pentoxy, sec-isopentoxy and the like.

The haloalkyl may refer to the aforementioned alkyl being substituted with one or more halogen atom such as fluorine atom (F), chlorine atom (Cl), bromine atom (Br), iodine atom (I) and the like, particularly fluorine atom and chlorine atom, and more particularly fluorine atom. Examples of the haloalkyl may include fluoroethyl, 1-chloropropyl, 1,2-difluoroethyl, 1,2-dichloroethyl, 1,2-dibromoethyl, trichloromethyl, trifluoromethyl, trichloroethyl, 1,2,3-trichloropropyl, 1,2,3,4-tetrabromobutyl and the like.

The aryl generally refers to a substituent derived from an aromatic ring such as phenyl, naphthyl and the like. The aryl as described herein may have a total carbon of 6 to 20, and may have one or more alkyl, haloalkyl, alkoxyl groups as described herein. Examples of the aryl may include phenyl, tolyl, tert-butylphenyl, xylyl, naphthyl, anisyl, fluorenyl, phenanthryl, chrysenyl, trifluoromethylphenyl, bis(trifluoromethyl)phenyl and the like.

The aryloxy group may be those derived correspondingly from the aforementioned aryl groups. Examples of the aryloxy may include phenoxy, naphthoxy, methylphenoxy (such as 2-methylphenoxy, 4-methylphenoxy and the like), 4-(1-methylethyl)phenoxy, dimethylphenoxy (such as 2,4-dimethylphenoxy, 2,3-dimethylphenoxy, 2,6-dimethylphenoxy and the like), 3-ethyl-5-methylphenoxy and the like.

In some embodiments, R₁ may be selected from the group consisting of C1-C10 linear or branched alkyl as described herein, unsubstituted or substituted phenyl as described herein, trifluoromethyl, and nitrile. In some particular embodiments, R₁ may be selected from the group consisting of C1-C4 linear or branched alkyl as described herein, unsubstituted phenyl, trifluoromethyl, and nitrile.

In some embodiments, R₂ may be selected from the group consisting of hydrogen, C1-C10 linear or branched alkyl as described herein, unsubstituted or substituted phenyl as described herein, trifluoromethyl, nitrile, and a combination thereof.

In some embodiments, R₃ and R₄ may be each independently selected from the group consisting of hydrogen, C1-C10 linear or branched alkyl as described herein, trifluoromethyl, nitrile, and a combination thereof. In some particular embodiments, R₃ and R₄ are each independently located at para-position, meta-position or at both the para- and meta-positions. It is believed that with these substituent positions, it may maximize the synthetic yields of the metal carbene complex, particularly the iridium(III) carbene complex, by minimizing the possible steric interference among coordinated carbene chelates.

Without wishing to be bound by theory, the inventors have devised that if the total number of alkyl on the N-aryl groups of the carbene ligand L is more than 2, then it may induce excessive steric congestion that prevent the formation of any homoleptic iridium(III) carbene complexes. Accordingly, in some more particular embodiments, when either R₃ or R₄ includes an alkyl, the maximum number of the alkyl is 2.

The metal M may be the metal element having an atomic of greater than 40, particularly from 40 to 79, more particularly from 44 to 79, and yet more particularly from 44 to 78. In some particular embodiments, the metal M may be selected from the group consisting of ruthenium, rhodium, rhenium, iridium and platinum. In some more particular embodiments, the metal M may be iridium or platinum.

In some embodiments, the metal carbene complex may be homoleptic. In some other embodiments, the metal carbene complex may be heteroleptic.

The ligand L may particularly have a Formula selected from the group consisting of:

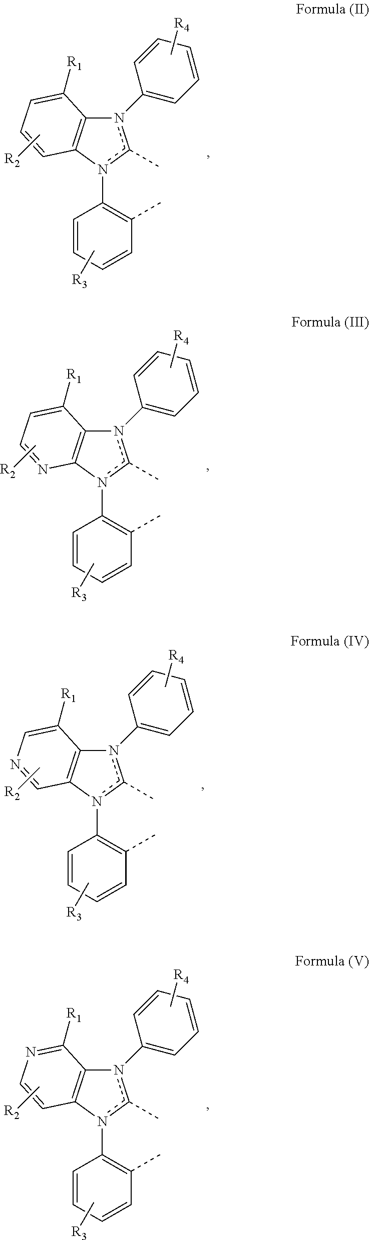

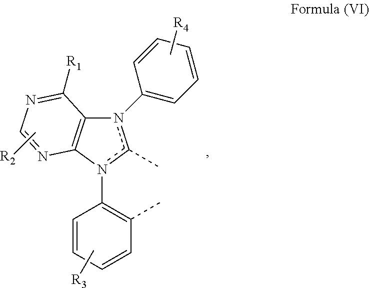

wherein: R₁ is selected from the group consisting of methyl, ethyl, iso-propyl, tert-butyl, trifluoromethyl, and nitrile; R₂ is a mono substitution selected from the group consisting of hydrogen, tert-butyl, trifluoromethyl, phenyl, 2,6-dimethylphenyl and nitrile; and R₃ and R₄ each represent a mono substitution located at para- or meta-position and are each independently selected from the group consisting of hydrogen, tert-butyl, and nitrile.

It is preferred that the ligand L have at least one electron-withdrawing group such as skeletal N atom, trifluoromethyl, nitrile and the like on the main benzo[d]imidazole-2-ylidene entity, particularly on the benzene ring of the benzo[d]imidazole-2-ylidene entity. It is believed that these electron-withdrawing groups would lower the π*-orbital of carbene chelate and reduce both the metal-to-ligand charge transfer (MLCT) and ligand-centered ππ* transition energy gaps, thereby tuning the emission of the metal carbene complex to true blue and blue region.

In some example embodiments, the metal carbene complex may have a Formula selected from the group consisting of:

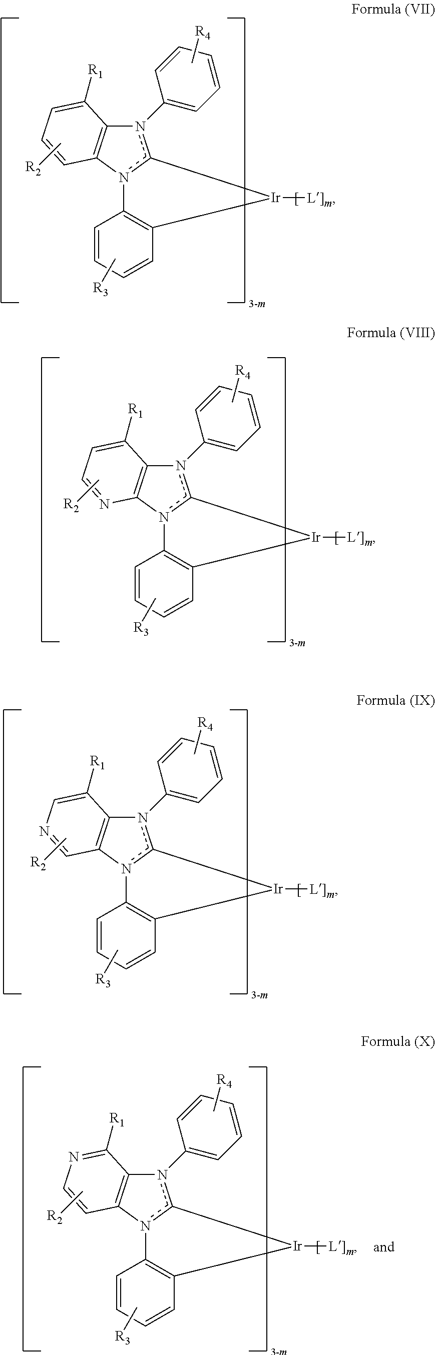

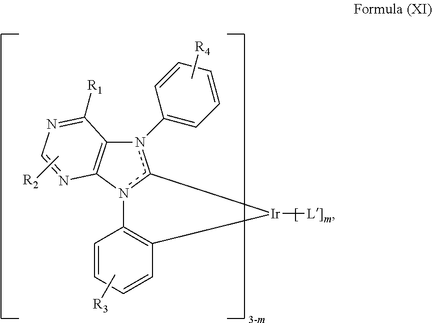

wherein: R₁ is selected from the group consisting of methyl, ethyl, iso-propyl, tert-butyl, trifluoromethyl, and nitrile; R₂ represents a mono substitution selected from the group consisting of hydrogen, tert-butyl, trifluoromethyl, phenyl, 2,6-dimethylphenyl and nitrile; R₃ and R₄ each represent a mono substitution located at para- or meta-position and are each independently selected from the group consisting of hydrogen, tert-butyl, and nitrile; L′ is a different ligand; and m is 0, 1, or 2.

Preferably, the metal carbene complexes having the Formula of (VI)-(XI) are facial isomer. In other words, the metal carbene complexes having the Formula of (VI)-(XI) are facial-substituted iridium(III) carbene complexes.

In some embodiments, L′ may have a Formula of:

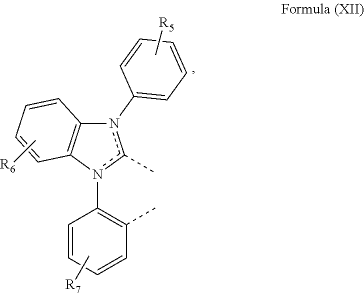

wherein R₅, R₆, and R₇ each represent mono, di, tri, or tetra substitutions; and wherein R₅, R₆, and R₇ each independently selected from the group consisting of hydrogen, alkyl, haloalkyl, alkoxy, aryloxy, aryl, nitrile, isonitrile, cyanate, and isocyanate, and a combination thereof. The alkyl, haloalkyl, alkoxy, aryloxy, and aryl are those as described herein.

In some particular embodiments, L′ may have a Formula selected from the group consisting of:

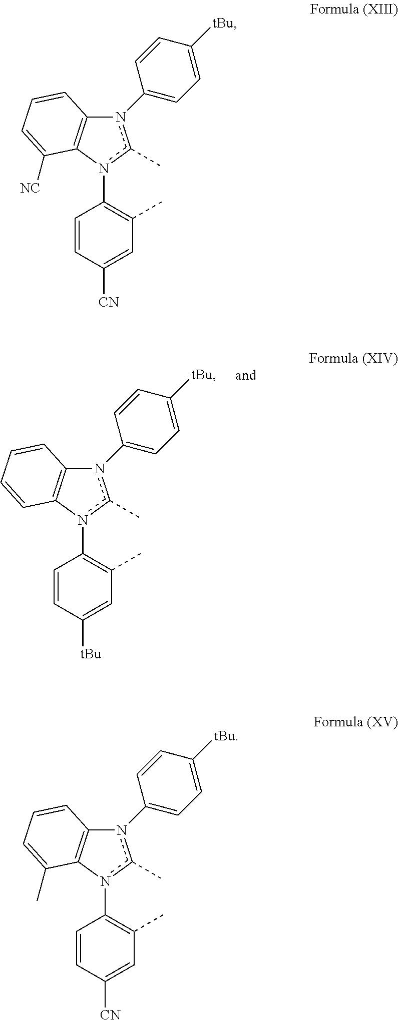

As some specific exemplary embodiments, when m is 0, the metal carbene complex may be selected from the group consisting of:

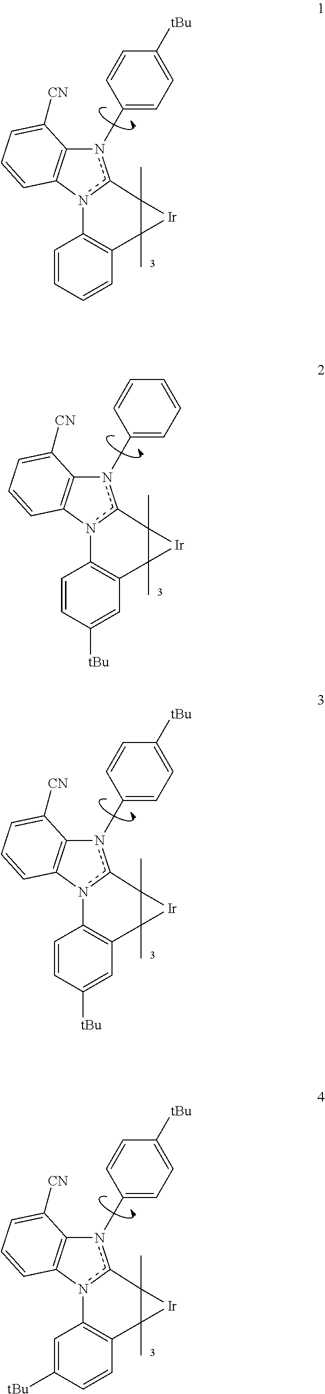

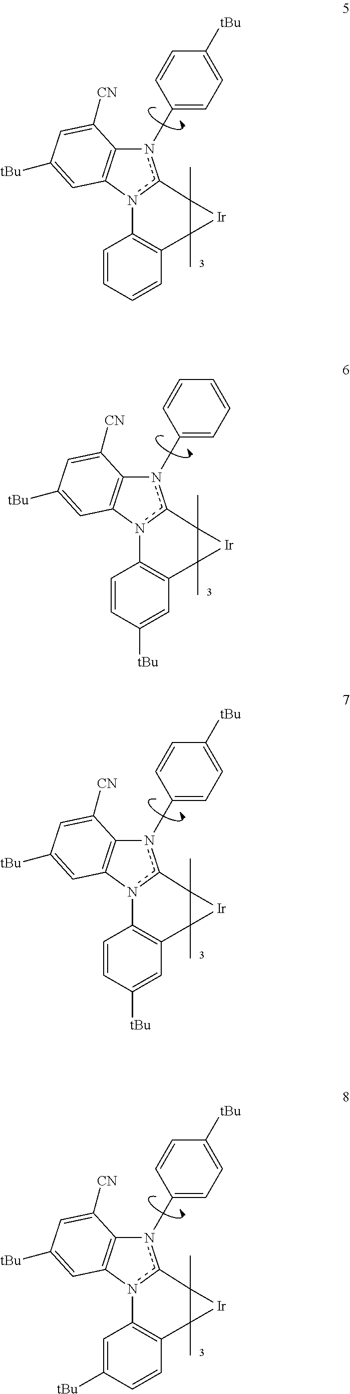

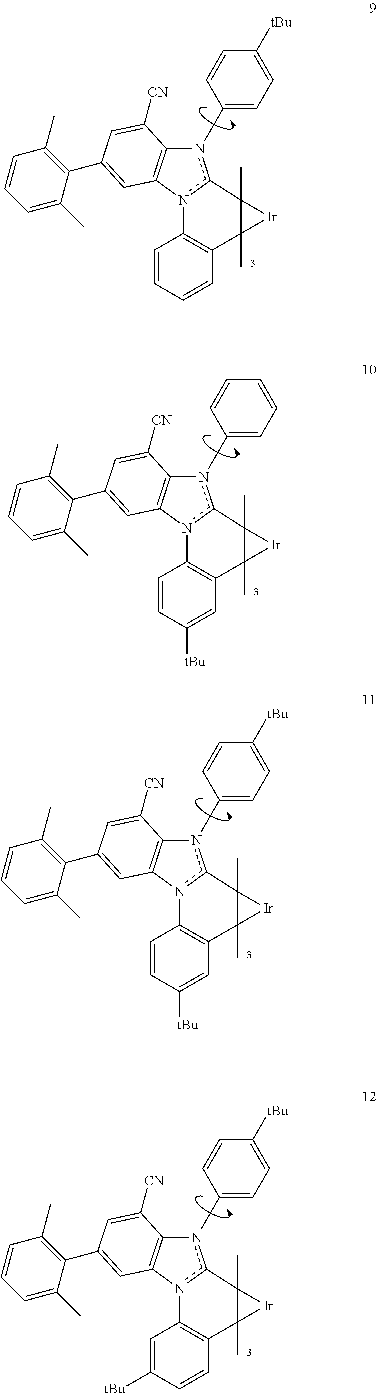

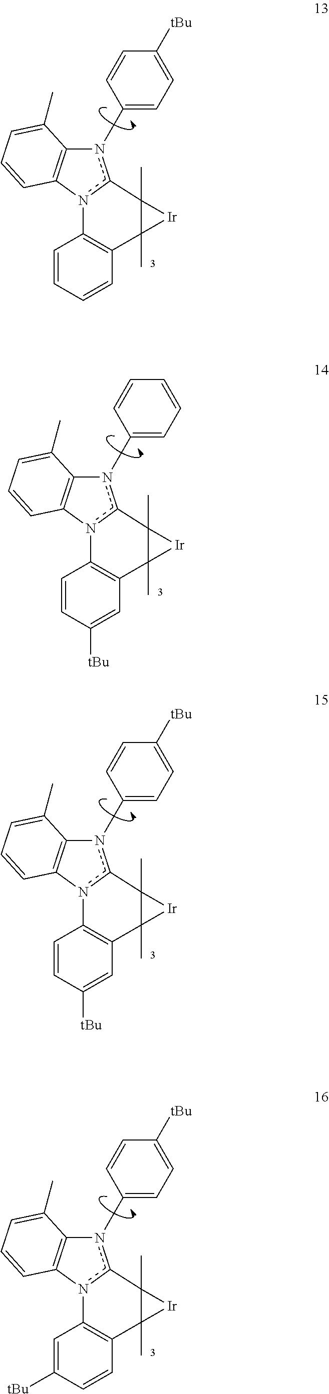

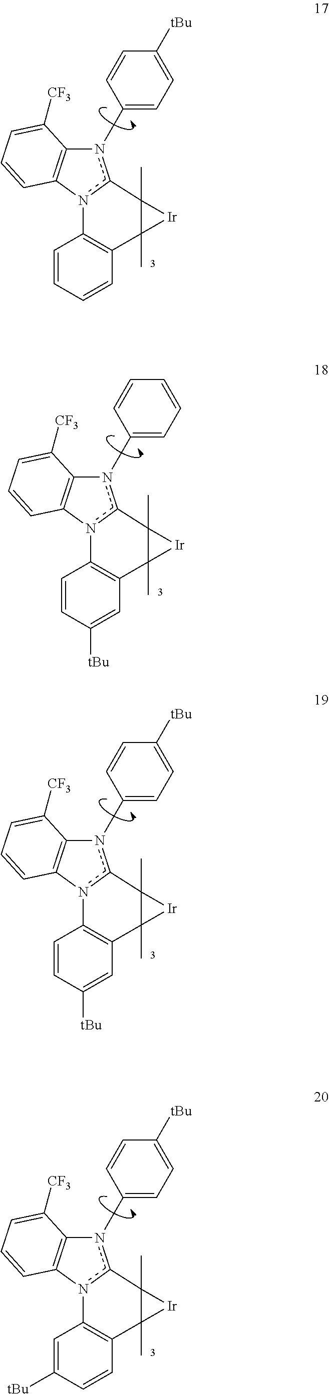

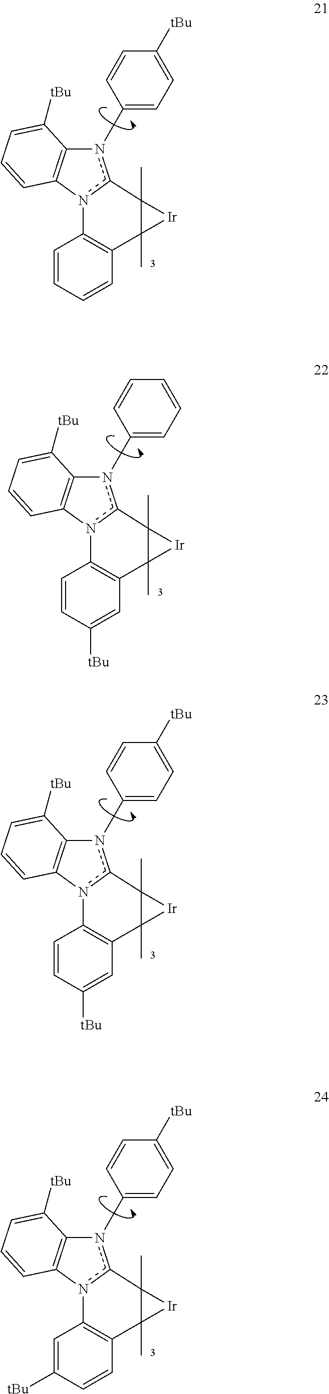

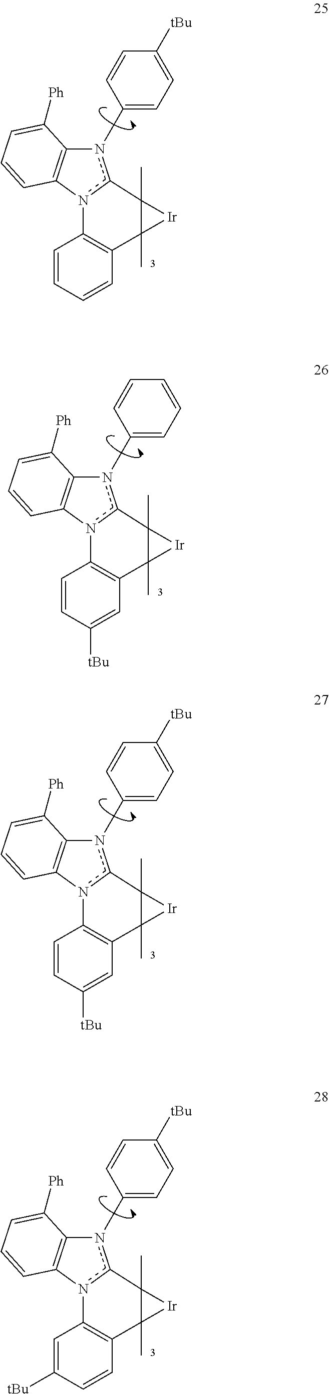

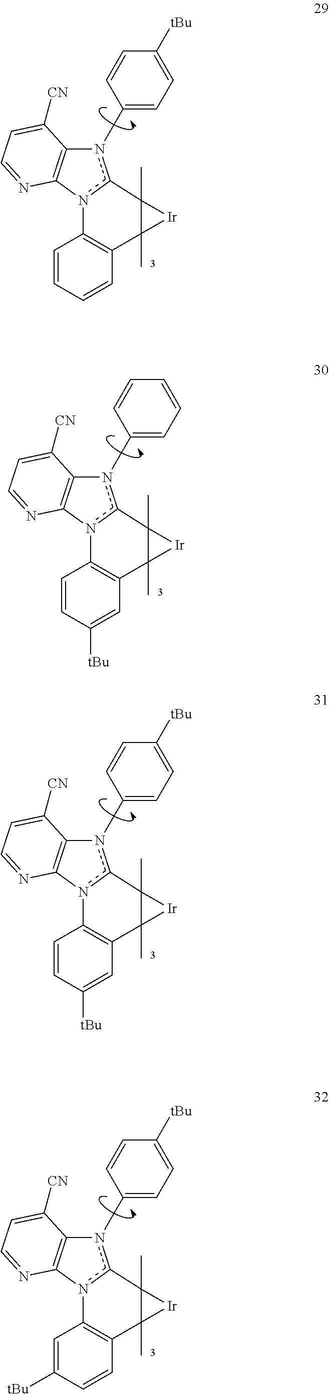

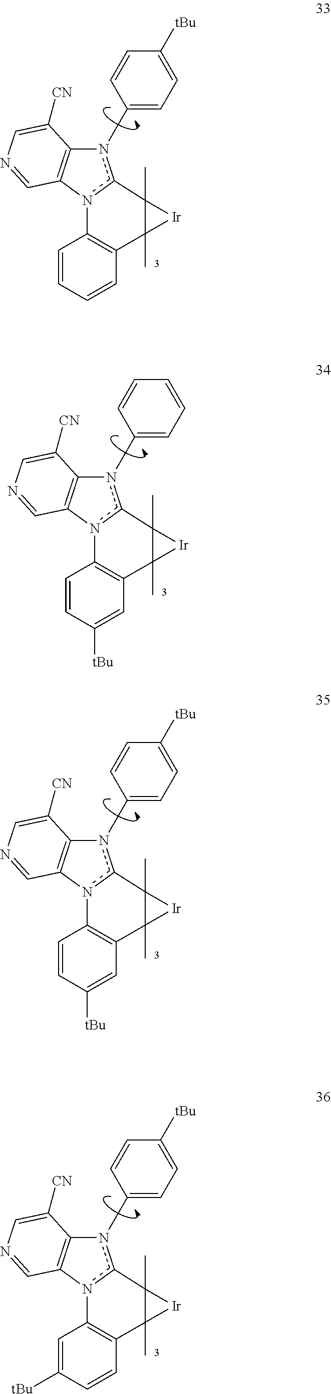

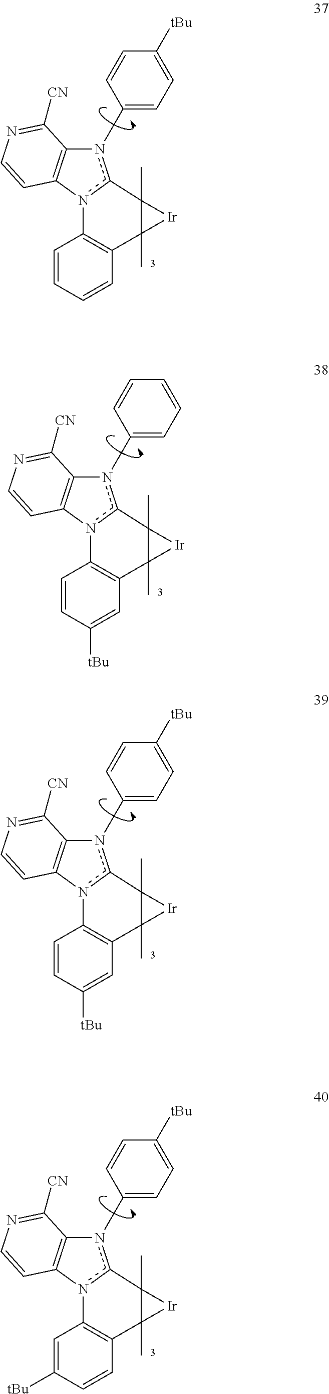

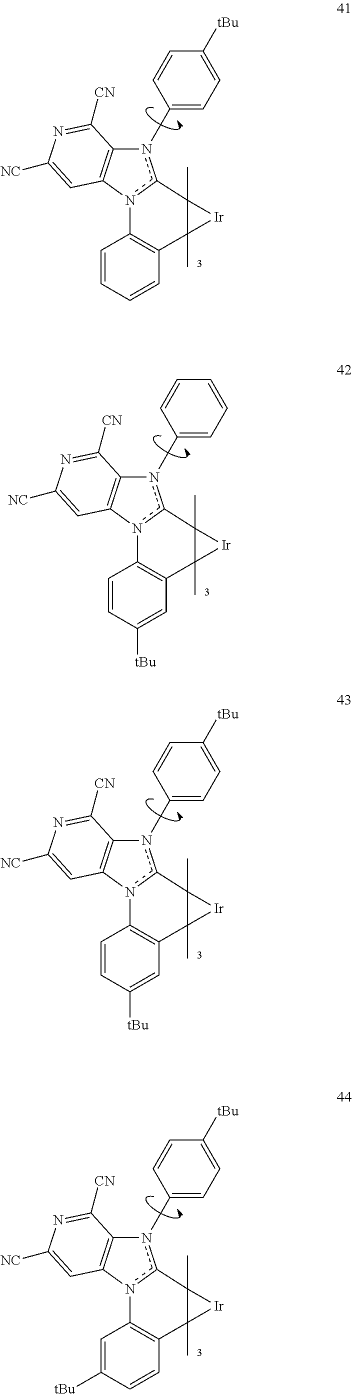

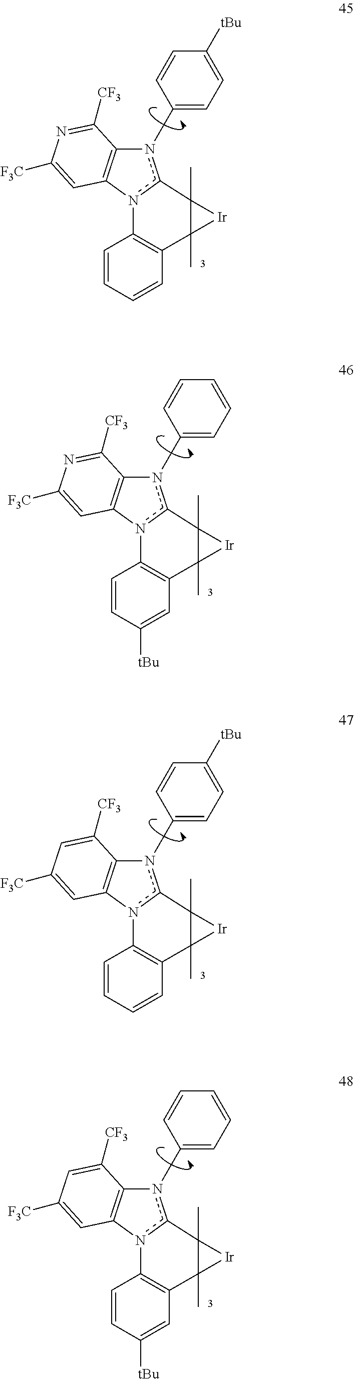

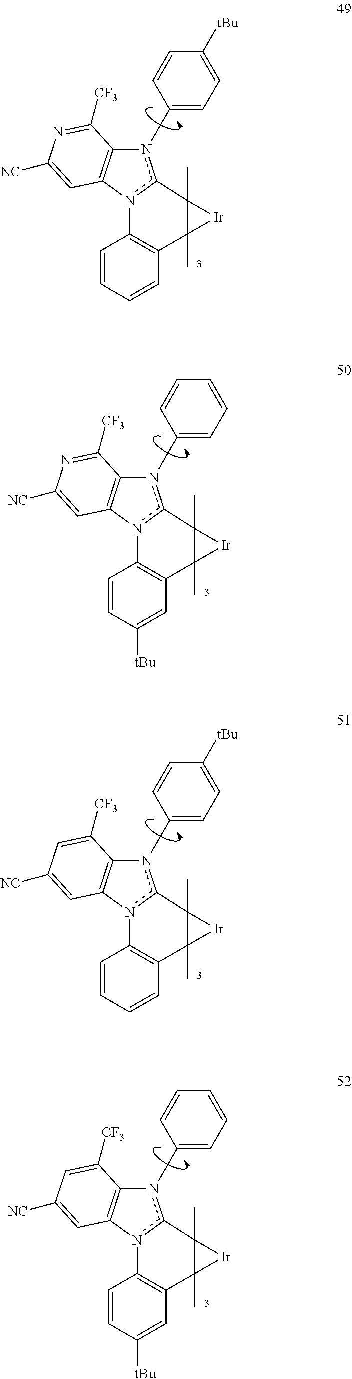

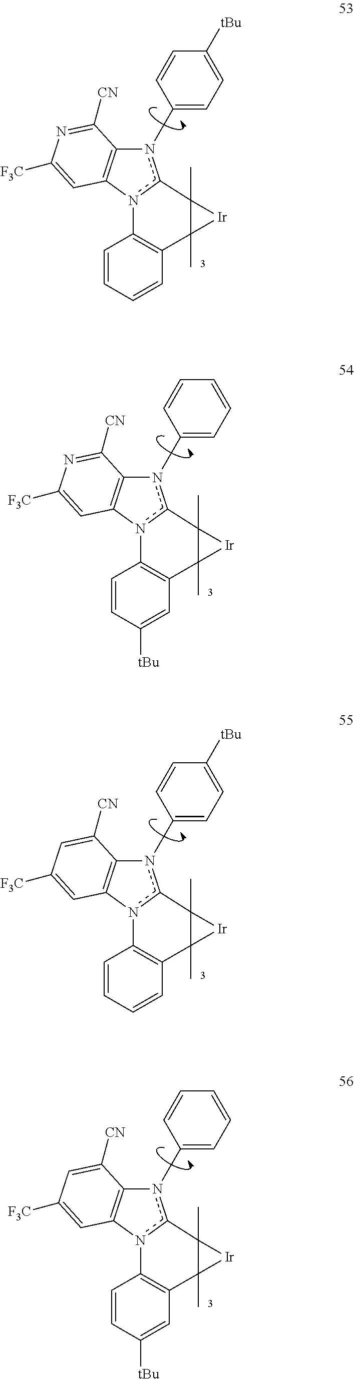

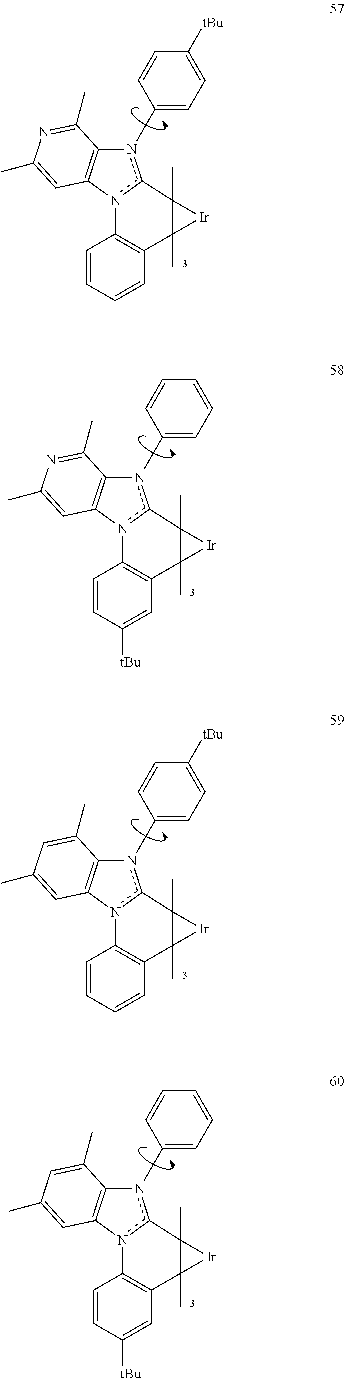

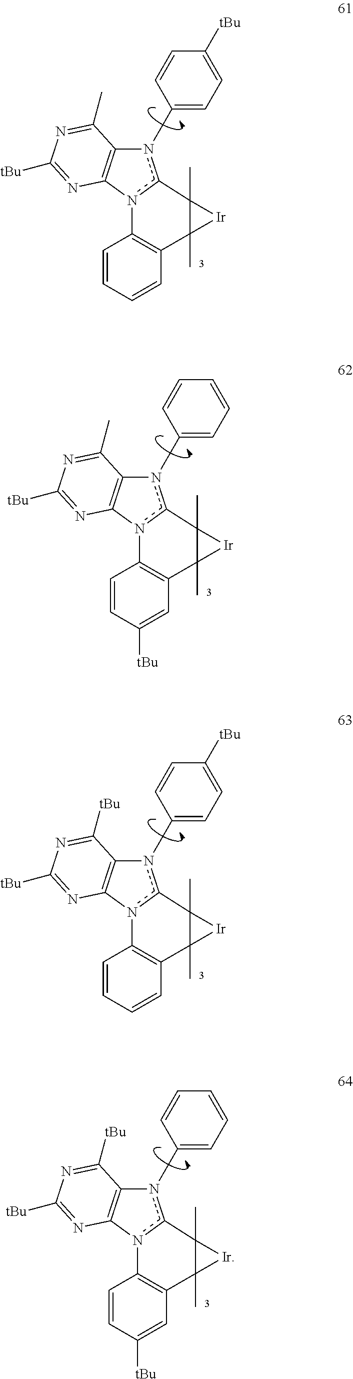

In some embodiments, when m is 1 or 2, the metal carbene complex may be selected from the group consisting of:

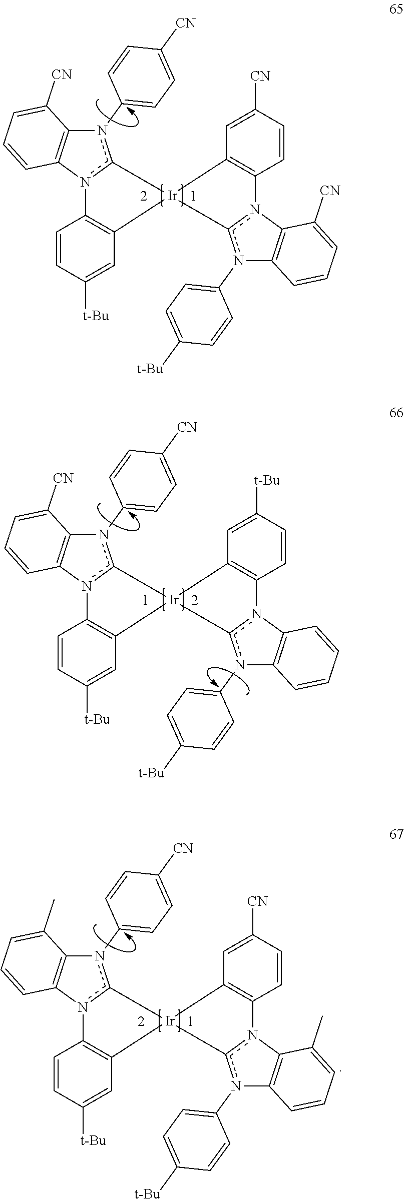

As used herein, the twisted arrows in the above Formula are intended to indicate the partially rotated configuration of such an N-aryl group as a result of the steric interference exerted by the nearby peri-substituent.

In some other embodiments, where the metal M is platinum, the metal carbene complex may further have a Formula selected from the group consisting of:

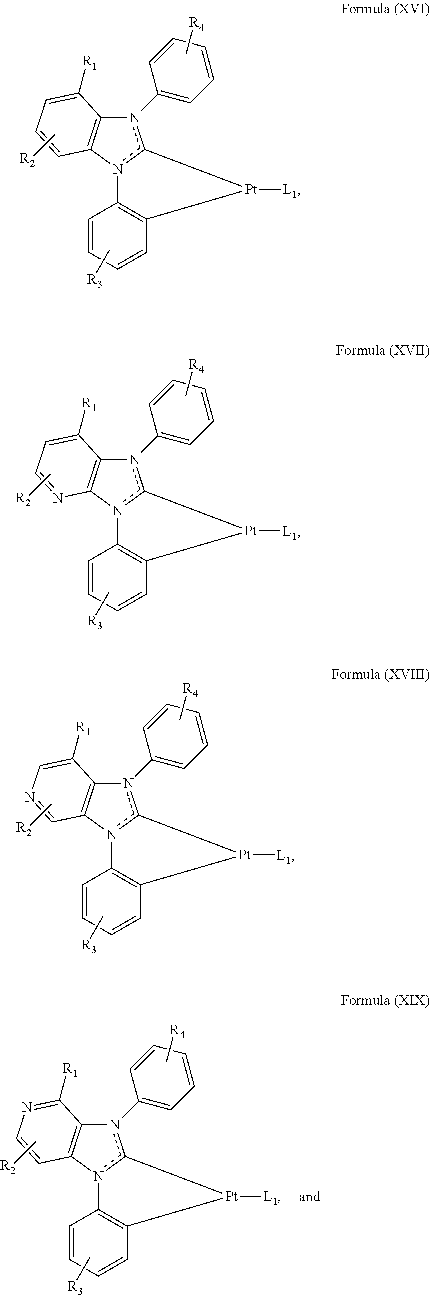

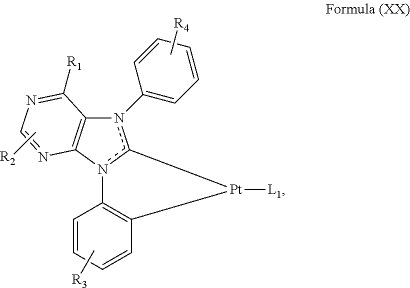

wherein: R₁ is selected from the group consisting of methyl, ethyl, iso-propyl, tert-butyl, trifluoromethyl, and nitrile; R₂ represents a mono substitution selected from the group consisting of hydrogen, tert-butyl, trifluoromethyl, phenyl, 2,6-dimethylphenyl and nitrile; R₃ and R₄ each represent a mono substitution located at para- or meta-position and are each independently selected from the group consisting of hydrogen, tert-butyl, and nitrile; and L₁ is a different bidentate ligand.

In some embodiments, L₁ is selected from the group consisting of:

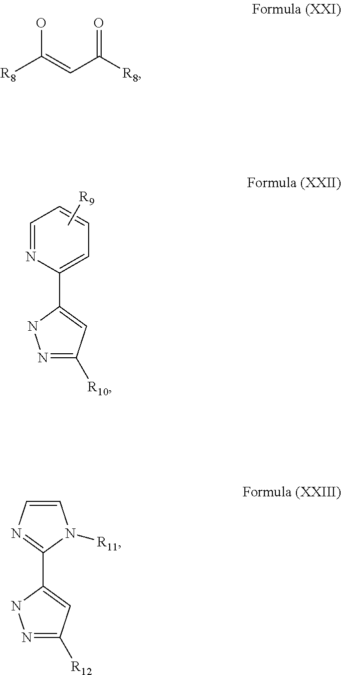

wherein: R₈ is selected from the group consisting of hydrogen, alkyl, haloalkyl, aryl, and a combination thereof; R₉ represents mono, di, tri, or tetra substitution, and is selected from the group consisting of hydrogen, alkyl, haloalkyl, alkoxy, aryloxy, aryl, nitrile, isonitrile, cyanate, isocyanate, and a combination thereof; and R₁₀, R₁₁ and R₁₂ are each independently selected from the group consisting of hydrogen, alkyl, haloalkyl, alkoxy, aryloxy, aryl, nitrile, isonitrile, cyanate, isocyanate, and a combination thereof. The alkyl, haloalkyl, alkoxy, aryloxy, and aryl are those as described herein.

As mentioned herein, the metal carbene complexes of the present invention may be used as a true blue or blue emitter for OLEDs and/or hyper-OLEDs. With reference to Table 1 below, there is provided a summary of photophysical data of some of the iridium(III) carbene complexes as described herein recorded in solution state.

TABLE 1
Photophysical data of the studied Ir(III) carbene
complexes recorded in solution state.

| | PL | | | | | kᵣ | kₙᵣ |
|---|---|---|---|---|---|---|---|
| | λₘₐₓ | FWHM | Φ | τ_{obs} | τ_{rad} | (10⁵ | (10⁴ |
| | (nm) ^{[a]} | (nm) ^{[c]} | (%) ^{[d]} | (μs) | (μs) | s⁻¹) | s⁻¹) |
| 1 | 435, | 57 | 83 | 1.41 | 1.70 | 5.9 | 1.2 |
| | 455 | | | | | | |
| | (sh) | | | | | | |
| 2 | 447 | 61 | 81 | 1.33 | 1.64 | 6.1 | 1.4 |
| 3 | 445 | 86 | 69 | 1.44 | 2.09 | 4.8 | 2.1 |
| 4 | 445 | 94 | 71 | 1.19 | 1.67 | 5.9 | 2.4 |
| 47 | 435 | 55 | 61 | 0.85 | 1.40 | 7.1 | 4.6 |
| 48 | 444 | 60 | 79 | 0.98 | 1.24 | 8.1 | 2.2 |
| 65 | 442 | 53 | 80 | 1.90 | 2.38 | 4.2 | 1.1 |
| 66 | 465 | 51 | 72 | 1.16 | 1.61 | 6.2 | 2.4 |
| 67 | 434, | 87 | 72 | 2.90 | 4.06 | 2.5 | 1.0 |
| | 454 | | | | | | |

^{[a]} Those were recorded in toluene at a conc. of 10⁻⁵ M at RT.
^{[c]} Full width at half maximum.
^{[d]} Coumarin 102 (C102) in methanol (Q.Y. = 87% and λₘₐₓ = 480 nm) were employed as standard.

As shown, these complexes showed high photoluminescence quantum yields, emission peak max. located in the region 435-540 nm, and shortened radiative lifetime. It is believed that these properties would render the complexes being efficient and robust blue phosphors in OLED applications. In addition, it is believed that the emission may be further blue-shifted in actual OLED fabrication as a result of using non-polar solvent such as methylcyclohexane or co-deposition in solid-state matrix such as PMMA and host materials. Without wishing to be bound by theory, it is believed that further blue-shifted emission may be achieved by lowering the HOMO energy level of iridium(III) complexes using molecular engineering. For example, by introducing different substituents, particularly electron-withdrawing substituents to the iridium(III) complexes, it may reduce the electron density at Ir(III) metal center, thereby lowering the HOMO energy level, which is mainly located at the Ir(III) metal center.

The preparation of the metal carbene complexes as described herein may comprise the step of contacting a suitable compound including the metal M with the appropriate ligands or ligand precursors. In particular, the suitable compound may comprise iridium or platinum, and the appropriate ligands or ligand precursors may be the carbene ligand L having Formula (I), particularly in deprotonated form.

In some embodiments, the preparation may comprise the step of contacting the suitable M-containing compound with the ligand L having any one of the Formula (II) to Formula (VI), with R₁ to R₄ as being defined herein.

In some other embodiments, such as when the desired metal carbene complex is a heteroleptic complex as defined herein, the preparation may comprise the step of contacting the suitable M-containing compound with the ligand L having any one of the Formula (II) to Formula (VI), and with L′ having any one of Formula (XIII) to Formula (XV) or L₁ having any one of Formula (XXI) to (XXIII), with R₈ to R₁₂ as defined herein.

Appropriate compounds, especially complexes, comprising the appropriate metal M, are known to those skilled in the art. Examples of particularly suitable compounds comprising platinum or iridium may include mer-IrCl₃(tht)₃ (tht=tetrahydrothiophene), [Ir(COD)Cl]₂, [Ir(COE)₂Cl]₂, IrCl₃×H₂O, Ir(acac)₃, Ir(COD)₂BF₄, Ir(COD)₂BARF (BARF=tetrakis[3,5-bis(trifluoromethyl)phenyl]borate)), Pt(COD)Cl₂, Pt(acac)₂, Pt(DMSO)₂Cl₂, [Pt(C₆H₁₀)Cl₂]₂, K₂PtCl₆ and the like.

The carbene ligand precursors are deprotonated, such as during the reaction, for example, by basic compounds known to those skilled in the art, for example basic metalates, basic metal acetates, acetylacetonates or alkoxides, or bases such as KO^{t}Bu, NaO^{t}Bu, LiO^{t}Bu, NaH, NaOAc, silylamides, Ag₂O and phosphazene bases. In some example embodiments, the carbene ligand precursors (i.e. carbene pro-chelate) may be deprotonated by a deprotonating agent of NaOAc.

The contacting is preferably effected in a solvent. Suitable solvents are known to those skilled in the art and are preferably selected from the group consisting of aromatic or aliphatic solvents, for example benzene, toluene, xylene or mesitylene, cyclic or acyclic ethers and the like, for example dioxane or THF, alcohols, esters, amides, ketones, nitriles, halogenated compounds and mixtures thereof. In some particular embodiments, the suitable solvents may be any one of o-dichlorobenzene and 1,2,4-trichlorobenzene.

In some embodiments, the molar ratio of metal-noncarbene complex used such as mer-IrCl₃(tht)₃ to the carbene ligand precursor used such as ligand L having any one of the Formula (II) to Formula (VI) to the deprotonating agent such as NaOAc (i.e. metal-noncarbene complex: carbene ligand precursor: deprotonating agent) may be from about 1:2.8:10 to about 1:3.5:10 such as 1:2.9:10, 1:2.95:10, 1:2.98:10, 1:3:10, 1:3.05:10, 1:3.2:10, 1:3.33:10 and the like. In some particular embodiments, the molar ratio may be from about 1:3:10 to about 1:3.33:10.

The contacting is generally affected at a refluxing temperature of about 180° C. to about 215° C. (such as 180.5° C. to 214.4° C.), depending on the suitable solvent used. The reaction time depends on the desired carbene complex and may be from about 12 hours to about 36 hours, such as from about 12 hours to about 24 hours.

Optionally or additionally, the as-prepared carbene complex may be isolated and from the reaction and may be purified by processes known to those skilled in the art, for example washing, crystallization or chromatography (such as column chromatography) and the like.

As mentioned above, the metal carbene complexes of the present invention are particularly suitable as emitter molecules in OLEDs and/or hyper-OLEDs. Accordingly, also pertained to the present invention is an organic light-emitting diodes comprising an emissive layer including at least one metal carbene complex as described herein.

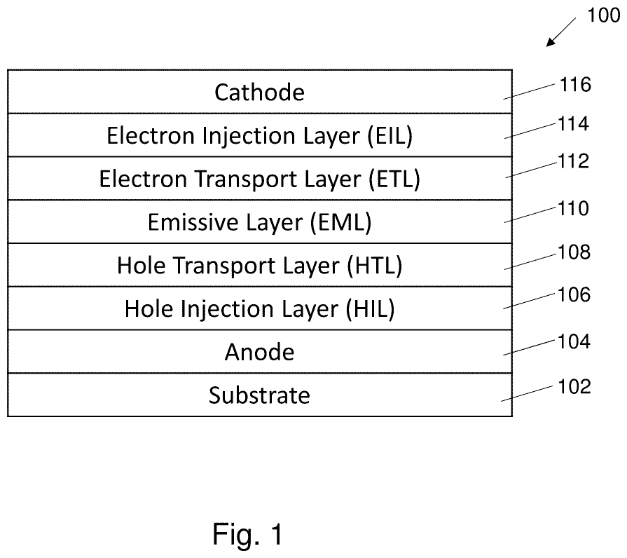

With reference to FIG. 1, there is provided a cross-sectional view illustrating a structure of an OLED 100 in accordance with an embodiment of the present invention. Referring to FIG. 1, the OLED in this embodiment includes a substrate 102, an anode 104, a hole injection layer (HIL) 106, a hole transport layer (HTL) 108, an emissive layer (EML) 110, an electron transport layer (ETL) 112, an electron injection layer (EIL) 114 and a cathode 116. In an optional embodiment, the OLED 100 may further include an electron blocking layer (EBL) 118 (not shown) disposed between, and particularly is in direct contact with the HIL 106 and HTL 108.

The substrate 102 may be any suitable substrate that can be used in OLEDs. In particular, the substrate may be a glass substrate and/or a transparent plastic substrate such as indium tin oxide coated glass slide and/or transparent polyimide, that has high mechanical strength, thermal stability, transparency, surface smoothness, can be easily treated, and is waterproof. A planarization layer and/or an insulating layer may further be interposed between the substrate and the anode, if required.

The anode 104 is formed on the substrate 102. The anode may be a transparent electrode, a semi-transparent electrode or a reflective electrode and the like. Examples of anode material may include ITO, IZO, SnO₂, ZnO, and the like. In some embodiments, the anode may have a structure having at least two layers using at least two materials and/or other structures. For example, the anode may have a structure including an anode material such as ITO and a polymer buffer layer such as poly(3,4-ethylene-dioxythiophene):polystyrenesulfonate (PEDOT:PSS) formed on the anode material.

The HIL 106 may be selectively formed by thermal vacuum deposition and/or spin coating. As shown in FIG. 1, the HIL may be disposed between the anode 104 and HTL 108, particularly is in direct contact with the anode 104 and HTL 108. The HIL may be formed of a material that can be suitably used to form a HIL. Examples of such a material may include a phthalocyanine compound, such as copperphthalocyanine; a star-burst type amine derivative, such as TCTA, m-MTDATA, and m-MTDAPB and the like; a soluble and conductive polymer such as polyaniline/dodecylbenzenesulfonic acid (Pani/DBSA); poly(3,4-ethylenedioxythiophene)/poly(4-styrenesulfonate) (PEDOT/PSS): polyaniline/camphor sulfonic acid (Pani/CSA); (polyaniline)/poly(4-styrenesulfonate) (PANI/PSS) and the like; carbazole derivatives such as N,N′-dicarbazolyl-3,5-benzene (mCP), 4,4′-bis(N-carbazolyl)-1,1′-biphenyl (CBP), 3,3′-di(9H-carbazol-9-yl)-1,1′-biphenyl (mCBP) and the like; metal oxides such as ReO₃, MoO₃ and the like; a composite of metal oxides and the star-burst type amine derivative such as ReO₃:TAPC and the like; a composite of metal oxides and the carbazole derivatives such as ReO₃:mCP and the like. In an embodiment where the HIL is formed of ReO₃:mCP, the HIL may have, for example, about 4 wt % (such as about 3.8 wt % . . . 3.85 wt % . . . 3.9 wt % . . . 3.98 wt % . . . 4 wt %, 4.02 wt % . . . 4.1 wt % . . . 4.14 wt % . . . 4.2 wt %) of ReO₃.

The HTL 108 may be disposed between the HIL 106 and the ETL 110, particularly is indirect contact with the HIL 106 and the ETL 110. The HTL may be formed by vacuum deposition, spin coating, casting, Langmuir Blodgett (LB) deposition and the like. Examples of a material that can be used to form the HTL may include N,N′-bis(3-methylphenyl)-N,N′-diphenyl-[1,1-biphenyl]-4,4′diamine (TPD), N,N′-di(naphthalene-1-il)-N,N′-diphenyl benzidine (α-NPD), mCP and the like.

The EML 110 is disposed between the anode 104 and the cathode 116, particularly in direct contact with the HTL 108 and the ETL 112. The EML 110 may include at least one metal carbene complex as described herein. In some example embodiments, the at least one metal carbene complex may be selected from the group consisting of the complex 1, complex 4, complex 47, complex 48 and a combination thereof. In some embodiments, the EML 110 may further include at least one organoboron terminal emitter including v-DABNA, m-DiNBO, and t-DABNA.

Optionally, the EML 110 may further include other blue dopant in accordance with practical needs. Examples of such a blue dopant may include oxadiazole dimer dyes (Bis-DAPDXP)), spiro compounds (Spiro-DPVBi, Spiro-6P), triarylamine compounds, bis(styryl)amine (DPVBi, DSA), 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)(BCzVB), 4,4-bis[4-(di-p-tolylamino)styryl]biphenyl (DPAVBi), 4-(di-p-tolylamino)-4′-[(di-p-tolylamino)styryl]benzene (DPAVB), 4,4′-bis[4-(diphenylamino)styryl]biphenyl (BDAVBi), and bis(3,5-difluoro-2-(2-pyridyl)phenyl-(2-carboxypyridyl)iridium III (FlrPic) and the like.

The EML 110 may further include a host to which the at least one metal carbene complex as described herein and/or the at least one organoboron terminal emitter is doped. The host may be made of any suitable materials such as tris(8-hydroxy-quinorate)aluminum (Alq3), 9,10-di(naphthyl-2-yl)anthracene (AND), 3-tert-butyl-9,10-di(naphthyl-2-yl)anthracene (TBADN), 4,4′-bis(2,2-diphenyl-ethene-1-yl)-4,4′-dimethylphenyl (DPVBi), 4,4′-bis(2,2-diphenyl-ethene-1-yl)-4,4′-dimethylphenyl (p-DMDPVBi), Tert(9,9-diarylfluorene)s (TDAF), 2-(9,9′-spirobifluorene-2-yl)-9,9′-spirobifluorene (BSDF), 2,7-bis(9,9′-spirobifluorene-2-yl)-9,9′-spirobifluorene (TSDF), bis(9,9-diarylfluorene)s (BDAF), 4,4′-bis(2,2-diphenyl-ethene-1-yl)-4,4′-di-(tert-butyl)phenyl (p-TDPVBi), mCP, 1,3,5-tris(carbazole-9-yl)benzene (tCP), 9-(3-(9H-carbazol-9-yl)phenyl)-9H-carbazole-3-carbonitrile (mCPCN), 4,4′,4″-tris(carbazole-9-yl)triphenylamine (TcTa), CBP, mCBP, 4,4′-bis(9-carbazoleyl)-2,2′-dimethyl-biphenyl (CBDP), 4,4′-bis(carbazole-9-yl)-9,9-dimethyl-fluorene (DMFL-CBP), 4,4′-bis(carbazole-9-yl)-9,9-bis(9-phenyl-9H-carbazole)fluorene (FL-4CBP), 4,4′-bis(carbazole-9-yl)-9,9-di-tolyl-fluorene (DPFL-CBP), 9,9-bis(9-phenyl-9H-carbazole)fluorene (FL-2CBP), 2,8-bis(diphenylphosphoryl)dibenzo[b,d]thiophene (PPT), bis[2-(diphenyl-phosphino)phenyl]ether oxide (DPEPO) and the like.

The amount of metal carbene complex used in the EML may vary in accordance with practical needs. In some embodiments, the at least one metal carbene complex may be of about 5 wt % to about 30 wt % of the EML. For example, the at least one metal carbene complex may be of 5 wt % to 31 wt %, 4.9 wt % to 31 wt %, 4.9 wt % to 30 wt %, 8 wt % to 30 wt %, 8.5 wt % to 30 wt %, 10 wt % to 30 wt %, 10 wt % to 31 wt %, 15 wt % to 30 wt %, 14.8 wt % to 30 wt %, 15 wt % to 29.5 wt %, 18 wt % to 31 wt %, 18.6 wt % to 31 wt %, 19 wt % to 31 wt %, 19.5 wt % to 30.5 wt %, 20.2 wt % to 31 wt %, 20.5 wt % to 30 wt %, 20.8 wt % to 30 wt %, 20 wt % to 29 wt %, 20 wt % to 29.4 wt %, 20 wt % to 29.8 wt % and the like.

In some embodiments where the EML further includes the at least one organoboron terminal emitter, the amount of the emitter may be of about 1 wt % (such as 0.8 wt % . . . 0.85 wt % . . . 0.89 wt % . . . 0.92 wt % . . . 0.99 wt %, 1 wt %, 1.01 wt % . . . 1.06 wt % . . . 1.1 wt % . . . 1.2 wt %) of the EML.

The EML may be formed by vacuum deposition, spin coating, casting, LB deposition and the like The ETL 112 may be formed on, particularly in direct contact with the EML.

The ETL may be generally formed of a material having high electron-transport capability. Examples of such a material may include tris(8-quinolinorate)aluminum (Alq3), lithium hydroxyquinolinorate (Liq), TAZ, and Balq, bis(10-hydroxybenzo[h]quinolinato beryllium (Bebq2), tris-[3-(3-pyridyl)mesityl]borane (3TPYMB) and the like.

The EIL 114 may be disposed between and is in direct contact with the cathode 116 and the ETL 112. Examples of suitable materials used in EIL may include LiF, NaCl, CsF, Li₂O, BaO, Liq and the like.

The ETL and EIL may be formed by vacuum deposition, spin coating, casting, and the like.

The cathode 116 is formed on, particularly in direct contact with the EIL 114. Examples of suitable cathode material may include Li, Mg, Al, Al—Li, Ca, Mg—In, Mg—Ag, ITO, IZO and the like.

Detailed performance of the OLEDs and/or hyper-OLEDs described herein will be discussed in the later part of the present disclosure.

Hereinafter, the present invention is described more specifically by way of examples, but the present invention is not limited thereto.

### EXAMPLES

### Materials and Methods

### Materials

All solvents were dried and degassed before used, and commercially available reagents were used without further purification. All reactions were conducted under N₂ atmosphere and monitored by pre-coated TLC plates (0.20 nm with fluorescent indicator F254). ¹H, ¹³C and ¹⁹F spectra were recorded with Bruker 400 MHz AVANCE III (BBO probe) Nuclear Magnetic Resonance System. The high-resolution mass spectra were obtained on Bruker microTOF-Q, where acetonitrile was applied as the solvent or were obtained on an Applied Biosystems 4800 Plus MALDI TOF/TOF Analyzer using 2,5-dihydroxybenzoic acid as the matrix substance. TGA measurements were performed on a TA Instrument TGAQ50, at a heating rate of 10° C. min⁻¹ under N₂ atmosphere.

### Photophysical Measurements

All photophysical measurements in this work were performed at RT (298 K). UV-visible spectra were recorded on HITACHI UH5700. The steady-state emission spectra and lifetime decay spectra were measured with a spectrofluorometer (Fluormax-4) and/or an Edinburgh FL 980 instrument. Both wavelength-dependent excitation and emission responses were calibrated. The studied complexes were measured in degassed toluene solution at RT, and coumarin 480 was used as the standard, where spectral grade solvents were employed. To specify the quantum yield in the fluid state, samples were degassed using at least three freeze-pump-thaw cycles. The solution quantum yields are calculated using coumarin 480 that has a known quantum yield, according to the following equation:

$$Φ = {Φ}_{R} \frac{I}{{I}_{R}} \frac{{A}_{R}}{A} \frac{{η}^{2}}{{η}_{R}^{2}}$$

where Φ is the PL quantum yield, the subscript R refers to the reference compound of known quantum yield, I is the integrated fluorescence intensity, and q is the refractive index of solvent. A is the absorbance at the excitation wavelength with the measured absorbance between 0.05-0.1. Quantum yields in PMMA thin film was measured by an integrated sphere. Lifetimes were performed by an Edinburgh FLS980 time-correlated single photon counting (TCSPC) system with an EPL-375 diode laser as the excitation source.

### Electrochemistry

Cyclic voltammetry was conducted on a CHI660 Electrochemical Analyzer. Ag/Ag⁺ (0.01 M AgNO₃) electrode was employed as the reference electrode. Oxidation and reduction potentials were measured using platinum working electrode with 0.1 M of NBu₄PF₆ as electrolyte in acetonitrile. The potentials were referenced externally to a ferrocenium/ferrocene (Fc⁺/Fc) couple.

### Single X-Ray Structural Determination

The single crystals suitable for X-ray diffraction study were obtained via the slow diffusion of methanol into a saturated CH₂Cl₂ solution of f-CN1 (complex 1), f-CN2 (complex 4), f-Ir(ptBp) (complex 47) and f-Ir(tBpp) (complex 48) at RT, respectively. Single crystal X-ray diffraction data were recorded on a Bruker D8 Venture Photon II diffractometer with microfocus X-ray sources using phi and omega scans mode (APEX3) at 233 K. All deposited data can be obtained free of charge on application to CCDC, 12 Union Road, Cambridge CB21EZ, UK (fax: (+44) 1223-336-033; e-mail: deposit@ccdc.cam.ac.uk)

### Computational Details of Theoretical Investigations

In one embodiment, the geometries, electronic structures, and electronic excitations of the studied Ir(III) complexes were investigated by methods based on DFT and TD-DFT using the B3LYP functional with Gaussian 16 set of programs. The polarizable continuum model (PCM) was used to include solvent effects. The 6-31G(d,p) basis set was used for light elements such as hydrogen, carbon and nitrogen, while the LANL2DZ basis set with the Los Alamos National Laboratory (LANL) effective core potentials (ECPs) was used for iridium. The corresponding ground state (S₀) geometries were optimized based on the X-ray structural data of f-CN1 and f-CN2. The low-energy excited states were then calculated by the TD-DFT method based on the optimized ground state structures including solvent effect of dichloromethane. Avogadro software was used to visualize the orbitals presented in this work. Orbital composition analysis was performed using the Hirshfeld method to calculate the contribution of Ir atom to each molecular orbital using Multiwfn software. The orbital overlap (overlap integral of the norm of two orbitals) was also calculated with Multiwfn software.

In another embodiment, the geometries, electronic structures, and electronic excitations of the studied Ir(III) complexes were investigated at the B3LYP-D3(BJ)/def2-SVP level with Gaussian 16 set of programs. The solvent effect of toluene was taken account by the polarizable continuum model (PCM). The corresponding ground state (S₀) and lowest triplet state (T₁) geometries were optimized based on the X-ray structural data of f-Ir(tBpp)₃ (Complex 48). A total of 10 low-lying excited states (T₁˜T₅ and S₁˜S₅) were included in the TD-DFT calculation based on the optimized S₀ structure. Natural transition orbital (NTO) analysis was applied to obtain a clear and compact orbital representation for the electronic excitation described by a variety of orbital transitions without a single predominant one (e.g. S₀→T₁ excitation in this work) at optimized S₀ structure. The IFCT (interfragment charge transfer) method analysis in the S₀→T₁ excitation is using Multiwfn software. The Hirshfeld method is used to calculate the density in IFCT analysis.

The spin-orbit coupling (SOC)-TDDFT calculation was performed using B3LYP functional with ZORA Hamiltonian (SARC-ZORA-SVP for Ir and ZORA-def2-SVP for other elements) at the optimized S₀ and T₁ structures in ORCA (v5.0.3) software. A total of 100 low-lying excited states (50 for singlet and 50 for triplet) were included in the SOC-TDDFT calculation in toluene with COSMO model. The radiative lifetime (τ_{rad}) and radiative rate (kᵣ) are calculated by the arithmetic average and Boltzmann average (at 298 K) of the SOC substates of T₁.

### OLED Fabrication and Measurement

In one embodiment, the substrates were cleaned with ultrapurified water and organic solvents, and then dry-cleaned for 30 minutes by exposure to UV-ozone. The organic layers were deposited onto the ITO substrates under the vacuum (=10⁻⁵ Pa), successively. Aluminum was patterned using a shadow mask with an array of 2 mm×2 mm openings without breaking the vacuum (=10⁻⁵ Pa). The electroluminescent (EL) were taken using an optical multichannel analyzer Hamamatsu Photonics PMA-11. The current density-voltage and luminance-voltage characteristics were measured by using a Keithley source measure unit 2400 and a Minolta CS200 luminance meter, respectively.

In another embodiment, all chemicals were purified by vacuum sublimation before fabrications. The OLED in this embodiment were fabricated through vacuum deposition of the materials at 10⁻⁶ torr onto the ITO coated glass substrates possessing a sheet resistance of 15 Ωsq⁻¹. The ITO surface was cleaned ultrasonically, i.e., with acetone, methanol, and deionized water in sequence and finally with N₂ plasma. The deposition rate of each organic material was ca. 1-2 Å·s⁻¹. The J-V-L characteristics of the devices were measured in a glovebox at the same time. For device characterization, the driving source was supplied from the programmable source measurement unit (2614B, Keithley) while the light intensity was measured by a calibrated silicon detector. EL spectra were recorded using a photodiode array (Ocean Optics USB2000+).

### Example 1

### Preparation of 1-(4-(t-butyl)phenyl)-7-cyano-3-phenyl-1H-benzo[d]imidazol-3-ium trifluoromethanesulfonate (L(1)H₂) and 3-(3-(t-butyl)phenyl)-1-(4-(t-butyl)phenyl)-7-cyano-1H-benzo[d]imidazol-3-ium trifluoromethane-sulfonate (L(4)H₂)

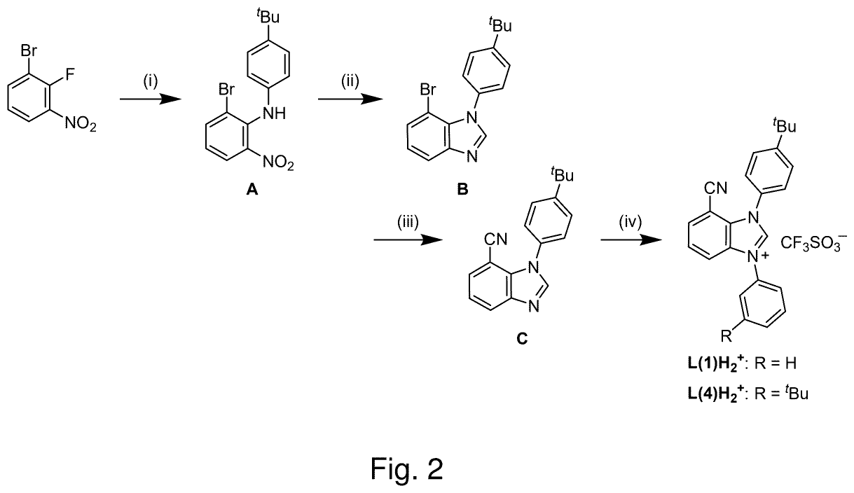

The synthesis of the peri-cyano substituted benzo[d]imidazol-2-ylidene pro-chelates L(1)H₂ and L(4)H₂ is illustrated in FIG. 2, which involves a multi-step protocol. As shown, firstly, the C—N coupling of 1-bromo-2-fluoro-3-nitrobenzene with 4-t-butylaniline was conducted in DMSO at 120° C. to afford 2-bromo-N-(4-(t-butyl)phenyl)-6-nitroaniline (A). Then, a two-step in one-pot approach was applied to reduce the nitro group with iron metal powder in giving amino group in excess of formic acid, followed by concomitant cyclization in giving 7-bromo-1-(4-(t-butyl)phenyl)-1H-benzo[d]imidazole (B). Next, the Pd-catalyzed nucleophilic cyanation of B afforded 1-(4-(t-butyl)phenyl)-1H-benzo[d]imidazole-7-carbonitrile (C). Finally, the desired benzo[d]imidazolylidene pro-chelates L(1)H₂ and L(4)H₂ were obtained by the Cu(OAc)₂ catalyzed N-arylation of C with diphenyliodonium triflate or (3-t-butylphenyl)(mesityl)iodonium triflate, respectively. Detailed synthetic procedures for each of the above compounds are discussed below.

### 2-bromo-N-(4-(tert-butyl)phenyl)-6-nitroaniline (A)

1-Bromo-2-fluoro-3-nitrobenzene (5.0 g, 22.8 mmol) was dissolved in a 70 mL DMSO in a 250 mL flask. After then, 4-t-butylaniline (4.0 mL, 25.1 mmol) was added and, the solution was heated to 120° C. with vigorous stirring overnight. After cooled to RT, the mixture was concentrated and the residue was dissolved in excess of ethyl acetate. The solution was washed with deionized water (50 mL×3). The organic layer was dried over anhydrous Na₂SO₄, filtered, and concentrated to give a red solid. (A, 6.4 g, 80%).

Selected spectral data of A: ¹H NMR (400 MHz, CDCl₃, 296 K): δ 8.03 (dd, J=8.0, 1.6 Hz, 1H), 7.95 (s, 1H), 7.81 (dd, J=8.0, 1.6 Hz, 1H), 7.28 (d, J=8.4 Hz, 2H), 6.97 (t, J=8.0 Hz, 1H), 6.79 (d, J=8.4 Hz, 2H), 1.30 (s, 9H).

### 7-bromo-1-(4-(t-butyl)phenyl)-1H-benzo[d]imidazole (B)

A mixture of A (6.0 g, 17.2 mmol) and iron powder (7.7 g, 137 mmol) in formic acid (100 mL) was heated to reflux for 48 hours. After then, formic acid was removed under vacuum and ethyl acetate was added to dissolve the residue. The solution was filtered through Celite and then, washed with 100 mL of saturated NaHCO_{3(aq)}, dried over anhydrous Na₂SO₄, and concentrated to dryness. The crude product was further purified via silica gel column chromatography to afford a white solid (B, 4.1 g, 73%).

Selected spectral data of B: ¹H NMR (400 MHz, CDCl₃, 296 K): δ 8.03 (s, 1H), 7.84 (dd, J=8.0, 1.2 Hz, 1H), 7.52 (d, J=8.4 Hz, 2H), 7.46 (dd, J=8.0, 1.2 Hz, 1H), 7.35 (d, J=8.4 Hz, 2H), 7.20 (t, J=8.0 Hz, 1H), 1.40 (s, 9H).

### 1-(4-(t-butyl)phenyl)-1H-benzo[d]imidazole-7-carbonitrile (C)

To a 100 mL flask was added B (1.5 g, 4.6 mmol), zinc cyanide (0.64 g, 5.5 mmol), Pd(PPh₃)₄ (0.32 g, 0.27 mmol), and anhydrous DMF (30 mL). The mixture was heated at 120° C. overnight. The reaction mixture was concentrated under vacuum, the residue was dissolved in ethyl acetate (60 mL) and washed with a diluted solution of ammonia water (NH₄OH), followed by deionized water. The combined organic phase was dried over anhydrous Na₂SO₄ and concentrated under reduced pressure. The residue was further purified via silica gel column chromatography to afford a white solid (C, 1.1 g, 85%).

Selected spectral data of C: ¹H NMR (400 MHz, CDCl₃, 296 K): δ 8.12 (dd, J=8.0, 1.2 Hz, 1H), 8.08 (s, 1H), 7.66 (dd, J=8.0, 1.2 Hz, 1H), 7.60 (d, J=8.8 Hz, 2H), 7.43-7.36 (m, 3H), 1.04 (s, 9H).

### 1-(4-(t-butyl)phenyl)-7-cyano-3-phenyl-1H-benzo[d]imidazol-3-ium trifluoromethanesulfonate (L(1)H₂)

A mixture of C (0.65 g, 2.4 mmol), diphenyliodonium triflate (1.5 g, 2.8 mmol) and Cu(OAc)₂ (23 mg, 0.12 mmol) in anhydrous DMF (20 mL) was heated at 110° C. for 3 hours. After C was fully consumed, DMF was removed under reduced pressure and the residue was triturated with deionized water (50 mL). The resulting precipitate was filtered, washed with n-hexane, and dried under vacuum to provide a white solid. It was further purified by recrystallization from acetone and diethyl ether to give white solid L(1)H₂, 1.0 g, 85%).

Selected spectral data of L(1)H₂: ¹H NMR (400 MHz, CDCl₃, 296 K): δ 9.58 (s, 1H), 7.97 (d, J=8.0 Hz, 1H), 7.94 (J=8.0 Hz, 1H), 7.86 (dd, J=8.0, 1.6 Hz, 2H), 7.79-7.75 (m, 3H), 7.70-7.64 (m, 5H), 1.42 (s, 9H); ¹⁹F NMR (376 MHz, CDCl₃, 296 K): 6-78.55 (s, 3F).

### 3-(3-(t-butyl)phenyl)-1-(4-(t-butyl)phenyl)-7-cyano-1H-benzo[d]imidazol-3-ium trifluoromethane-sulfonate (L(4)H₂)

White solid of L(4)H₂ (0.64 g, 90%) was attained following the same approach reported for its analogue L(1)H₂.

Selected spectral data of L(4)H₂: ¹H NMR (400 MHz, CDCl₃, 296 K): δ 9.33 (s, 1H), 7.99 (d, J=7.2 Hz, 1H), 7.92 (d, J=8.0 Hz, 1H), 7.85 (s, 1H), 7.79 (d, J=8.4 Hz, 2H), 7.78 (t. J=8.0 Hz, 1H), 7.72 (t. J=7.2 Hz, 1H), 7.69 (d, J=8.4 Hz, 2H), 7.65-7.59 (m, 2H), 1.42 (s, 9H), 1.41 (s, 9H); ¹⁹F NMR (376 MHz, CDCl₃, 296 K): δ −78.55 (s, 3F).

### Example 2

Preparation of Peri-Cyano Substituted Benzo[d]imidazol-2-ylidene-Based Ir(III) Metal Complexes f-CN1 and f-CN2 (Complexes 1 and 4)

The Ir(III) carbene complex f-CN1 (complex 1) was prepared by heating mer-trichloridotris(tetrahydrothiophene-KS)iridium(III) (mer-IrCl₃(tht)₃) with pro-chelate L(1)H₂ and nearly 10 equiv. of NaOAc in refluxing o-dichlorobenzene for 24 hours. In accordance with this reactivity pattern, treatment of m-Ir(tht)₃Cl₃ with the carbene pro-chelate L(4)H₂ afforded the analogue f-CN2 (complex 4) in high yield. Both f-CN1 and f-CN2 can be easily separated by silica gel column chromatography, followed by recrystallization from mixed CH₂Cl₂ and methanol at RT. The detailed synthetic procedures are as follows:

The pro-chelate L(1)H₂ (963 mg, 1.9 mmol), sodium acetate (512 mg, 6.2 mmol), mer-IrCl₃(tht)₃ (350 mg, 0.62 mmol) and o-dichlorobenzene (80 mL) were added to a 250 mL flask. The mixture was refluxed for 24 hours with vigorous stirring. After removal of solvent under vacuum, the residue was taken into CH₂Cl₂ and washed with deionized water. The organic phase was separated, dried over anhydrous Na₂SO₄, and concentrated. The residue was purified by column chromatography with a mixture of n-hexane, ethyl acetate and CH₂Cl₂ (2/1/1, v/v/v) to afford complex 1. Further recrystallization with CH₂Cl₂ and methanol attained a light-yellow solid of 1 (470 mg, 61%).

Spectroscopic data of complex 1: HRMS (ESI) for C₇₂H₆₀IrN₉ [M]⁺: calcd 1243.4601, found 1243.4597; ¹H NMR (400 MHz, CDCl₃) δ 8.38 (dd, J=6.0, 3.2 Hz, 3H), 7.89 (d, J=8.0 Hz, 3H), 7.45 (dd, J=8.4, 2.4 Hz, 3H), 7.35-7.30 (m, 6H), 7.14 (tb, J=7.6, 1.6 Hz, 3H), 6.75 (dd, J=8.4, 1.6 Hz, 3H), 6.72 (t, J=7.2 Hz, 3H), 6.58 (dd, J=7.2, 1.2 Hz, 3H), 6.49 (dd, J=8.4, 2.4 Hz, 3H), 6.17 (dd, J=8.4, 2.4 Hz, 3H), 0.97 (s, 27H). Anal. Calcd. for C₇₂H₆₀IrN₉: C, 69.54; H, 4.86; N, 10.14. Found: C, 69.59; H, 4.80; N, 10.20.

Selected crystal data of complex 1: CCDC number: 2261894. C₇₃H₆₂IrN₉Cl₂; M=1328.41; triclinic; space group P-1; a=14.0313(3) Å, b=20.1148(4) Å, c=23.2016(4) Å; α=101.8540(10)°, β=102.6870(10)°, γ=99.7580(10)°; V=6092.2(2) Å³; Z=4; ρ_{Calcd}=1.448 g·cm⁻³; μ=5.452 mm⁻¹; F(000)=2696.0, λ(Cu-K_{α})=1.54178 Å; T=223 (2) K; Crystal size/mm³: 0.23×0.11×0.03; 78160 reflections collected, 24707 independent reflections (Rᵢₙₜ=0.0632), data/restraints/parameters=24707/370/1618, GOF=1.002, final R₁[I>2σ(I)]=0.0435 and wR₂(all data)=0.1204. Light-yellow solid of complex 4 (0.64 g, 70%) was attained following the same approach reported for its analogue 1.

Spectroscopic data of complex 4: HRMS (ESI) for C₈₄H₈₄IrN₉ [M]⁺: calcd 1411.6479, found 1411.6477; ¹H NMR (400 MHz, CDCl₃) δ 8.36 (dd, J=8.0, 1.6 Hz, 3H), 7.87 (d, J=2.0 Hz, 3H), 7.43 (dd, J=8.4, 2.0 Hz, 3H), 7.36-7.30 (m, 6H), 6.75 (dd, J=7.6, 1.6 Hz, 3H), 6.64 (d, J=8.4, 2.4 Hz, 3H), 6.43 (dd, J=8.4, 2.0 Hz, 3H), 6.36 (d, J=7.6 Hz, 3H), 6.16 (dd, J=8.0, 2.4 Hz, 3H), 1.38 (s, 27H), 0.99 (s, 27H). Anal. Calcd. for C₈₄H₈₄IrN₉: C, 77.46; H, 6.00; N, 8.93. Found: C, 77.51; H, 5.95; N, 8.89.

Selected crystal data of complex 4: CCDC number: 2302875. Cs₆H₈₈IrN₉Cl₄; M=1581.65; tetragonal; space group I4₁/a; a=34.4710(8) Å, c=27.1729(7) Å; V=32288.2(17) Å³; Z=16; ρ_{Calcd}=1.301 g·cm⁻³; μ=4.792 mm⁻¹; F(000)=12992.0, λ(Cu-K_{α})=1.54178 Å; T=203 (2) K; Crystal size/mm³: 0.32×0.12×0.02; 110152 reflections collected, 16489 independent reflections (Rᵢₙₜ=0.0512), data/restraints/parameters=16489/182/972, GOF=1.018, final R₁[I>2σ(I)]=0.0360 and wR₂(all data)=0.1014.

### Example 3

### Preparation of 1-(4-(tert-Butyl)phenyl)-3-phenyl-5,7-bis(trifluoromethyl)-1H-benzo[d]imidazol-3-ium trifluoromethanesulfonate (L(47)H₂) and 3-(4-(tert-Butyl)phenyl)-1-phenyl-5,7-bis(trifluoromethyl)-1H-benzo[d]imidazol-3-ium trifluoromethanesulfonate (L(48)H₂)

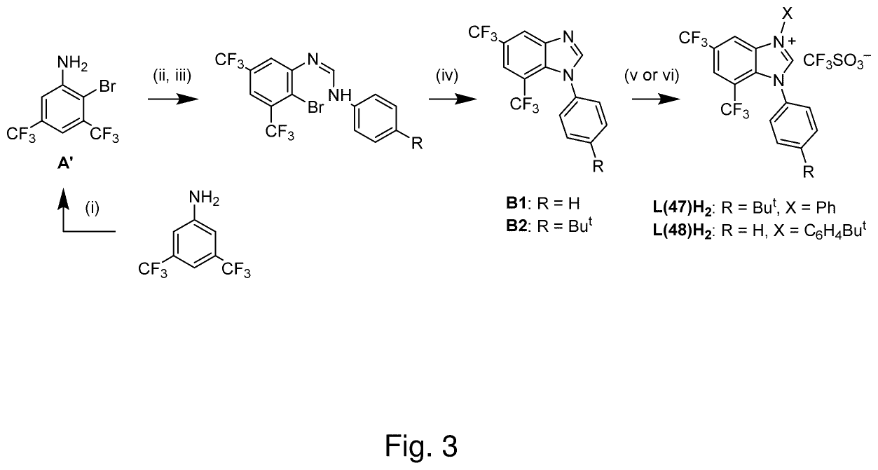

The synthesis of the pro-chelates L(47)H₂ and L(48)H₂ is illustrated in FIG. 3. As shown, the key starting material 2-bromo-3,5-bis(trifluoromethyl)aniline (A′) was firstly prepared by bromination of commercially available 3,5-bis(trifluoromethyl)aniline using N-bromosuccinimide in CH₂Cl₂ at ˜5° C. After then, it was treated with stoichiometric amount of triethyl orthoformate in presence of glacial acetic acid as catalyst at 120° C., followed by addition of aniline or 4-t-butylaniline at 140° C. This two-step operation procedure is aimed at in-situ preparation of functional ethyl N-arylformimidate as an intermediate, which is expected to undergo further coupling with aniline in giving asymmetric N,N′-diarylformamidines with a 2-bromo-3,5-bis(trifluoromethyl)phenyl substituent. After then, a copper-catalyzed intramolecular C—N bond coupling was executed in giving the imidazole derivatives B1 and B2 in moderate yields. Reaction of B1 and B2 with diaryliodonium salt in DMF and with Cu(OAc)₂ as catalyst afforded the respective di-N-aryl substituted pro-chelates L(47)H₂ and L(48)H₂ in high yields. The detailed synthetic procedures are as follows:

### 2-Bromo-3,5-bis(trifluoromethyl)aniline (A′)

A solution of 3,5-bis(trifluoromethyl)aniline (11.46 g, 50 mmol) in 50 mL CH₂Cl₂ was cooled to 0° C. and a solution of N-bromosuccinimide (8.90 g, 50 mmol) in 350 mL of CH₂Cl₂ was slowly added at a temperature below 5° C. The reaction was monitored by TLC. After completed, the reaction mixture was washed with a saturated aqueous solution of NaHCO₃ (2×100 mL) and water (100 mL) in sequence. The organic phase was dried over Na₂SO₄ and the solvent was evaporated under reduced pressure. The crude product was purified by column chromatography on silica gel using petroleum ether/CH₂Cl₂ (4:1, v/v) as eluent to give of f-white needles. Yield: 12.5 g (81.2%). ¹H NMR (400 MHz, CDCl₃) δ 7.28 (d, J=2.0 Hz, 1H), 7.14 (d, J=2.0 Hz, 1H), 4.62 (s, 2H); ¹⁹F NMR (376 MHz, CDCl₃) δ −63.06 (s, 3F), −63.30 (s, 3F).

### 1-Phenyl-5,7-bis(trifluoromethyl)-1H-benzo[d]imidazole (B1)

The mixture of A′ (3.08 g, 10 mmol), triethyl orthoformate (1.48 g, 1.66 mL, 10 mmol) and glacial acetic acid (30 mg, 29 μL, 0.5 mmol) was stirred at 120° C. for 4 h, then cooled to RT. Aniline (0.93 g, 0.91 mL, 10 mmol) was added and the resulting mixture was stirred at 140° C. for 12 h. After cooled to RT, DBU (1.52 g, 1.5 mL, 10 mmol), CuI (190 mg, 1.0 mmol) and DMSO (20 mL) were added, and the reaction mixture was stirred overnight at 150° C. After then, ethyl acetate (50 mL) was added and, the mixture was filtered through a Celite pad. The filtrate was washed with brine and water in sequence, dried over anhydrous Na₂SO₄ and concentrated by rotatory evaporation. The crude product was purified by column chromatography using petroleum ether/ethyl acetate (4/1, v/v) as eluent to give a white solid. Yield: 1.49 g (45.2%). ¹H NMR (400 MHz, CDCl₃) δ 8.36 (s, 1H), 8.09 (s, 1H), 7.87 (s, 1H), 7.62-7.53 (m, 3H), 7.42 (d, J=6.4 Hz, 2H); ¹⁹F NMR (376 MHz, CDCl₃) δ −57.30 (s, 3F), −61.15 (s, 3F).

### 1-(4-(tert-Butyl)phenyl)-5,7-bis(trifluoromethyl)-1H-benzo[d]imidazole (B2)

This compound was prepared similarly as B1, giving an of f-white solid. Yield: 1.60 g (41.5%). ¹H NMR (400 MHz, CDCl₃) δ 8.35 (s, 1H), 8.07 (s, 1H), 7.86 (s, 1H), 7.54 (d, J=8.4 Hz, 2H), 7.30 (d, J=8.4 Hz, 2H), 1.40 (s, 9H); ¹⁹F NMR (376 MHz, CDCl₃, 296 K): 6-57.31 (s, 3F), −61.13 (s, 3F)

### Example 4

Preparation of Benzo[d]imidazol-2-ylidene-Based Ir(III) Metal Complexes f-Ir(ptBp) and f-Ir(tBpp) (Complexes 47 and 48)

A mixture of L(48)H₂ (394 mg, 0.64 mmol), IrCl₃(tht)₃ (110 mg, 0.2 mmol), sodium acetate (164 mg, 2 mmol), and degassed 1,2,4-trichlorobenzene (10 mL) was heated at reflux overnight under N₂. After then, the solvent was removed under vacuum. The residue was dissolved in CH₂Cl₂ (30 mL), washed with brine, dried over anhydrous Na₂SO₄ and, evaporated to dryness. The crude product was purified by column chromatography using hexane/ethyl acetate (9/1, v/v) as eluent to give a single product of 48 as white powder. Yield: 217 mg (69%).

Selected spectroscopic data for complex 48: HRMS (ESI, ¹⁹³Ir): m/z 1577.3892 [M+H⁺], calcd. for C₇₅H₅₈F₁₈IrN₆: 1577.4065; ¹H NMR (400 MHz, CDCl₃) δ 8.46 (s, 3H), 7.79 (d, J=8.0 Hz, 3H), 7.71 (s, 3H), 7.62 (d, J=8.4 Hz, 3H), 7.19 (td, J=7.6, 1.2 Hz, 3H), 7.10 (dd, J=8.4, 2.4 Hz, 3H), 6.59 (td, J=8.0, 1.6 Hz, 3H), 6.49 (tt, J=7.6, 1.2 Hz, 3H), 6.42 (d, J=2.4 Hz, 3H), 6.08 (dt, J=8.0, 1.6 Hz, 3H), 0.98 (s, 27H); ¹⁹F NMR (376 MHz, CDCl₃) δ −56.25 (s, 9F), −61.03 (s, 9F). Anal. Calcd. for C₇₅H₅₇F₁₈IrN₆: C, 57.14; H, 3.64; N, 5.33. Found: C, 57.07; H, 3.60; N, 5.37.

Selected crystal data of complex 48: CCDC deposition number: 2242122. C₇₅H₅₇F₁₈IrN₆; M=1576.46; trigonal; space group=P-3; a=16.3890(5) Å, b=16.3890(5) Å, c=17.8634(5) Å; γ=120°; V=4155.3(3) Å³; Z=2; ρ_{Calcd}=1.260 g·cm⁻³; F(000)=1576.0, crystal size=0.29×0.14×0.04 mm³; λ(Cu-K_{α})=1.54178 Å; T=213 (2) K; μ=3.811 mm⁻¹; 74392 reflections collected, 5712 independent reflections (Rᵢₙₜ=0.0498), max. and min. transmission=0.754 and 0.520, data/restraints/parameters=5712/901/424, GOF=1.068, final R₁[I>2σ(I)]=0.0239 and wR₂(all data)=0.0651.

The complex 47 was prepared from L(47)H₂ and IrCl₃(tht)₃ using a procedure in accordance with that reported for complex 48, giving a single product of complex 47 as white powder. Yield: 150 mg (47%).

Selected spectroscopic data for complex 47: HRMS (ESI, ¹⁹³Ir): m/z 1577.3932 [M+H⁺], calcd. for C₇₅H₅₈F₁₈IrN₆: 1577.4065; ¹H NMR (400 MHz, CDCl₃) δ 8.57 (s, 3H), 7.80 (dd, J=8.0, 1.2 Hz, 3H), 7.66 (s, 3H), 7.53 (dd, J=8.4, 2.4 Hz, 3H), 7.36 (dd, J=8.4, 2.4 Hz, 3H), 7.17 (td, J=8.0, 1.6 Hz, 3H), 6.71 (td, J=8.0, 1.2 Hz, 3H), 6.68 (dd, J=8.0, 2.0 Hz, 3H), 6.54 (dd, J=8.0, 2.0 Hz, 3H), 5.84 (dd, J=8.0, 1.6 Hz, 3H), 0.84 (s, 27H).; ¹⁹F NMR (376 MHz, CDCl₃) δ −56.09 (s, 9F), −61.18 (s, 9F). Anal. Calcd. for C₇₅H₅₇F₁₈IrN₆: C, 57.14; H, 3.64; N, 5.33. Found: C, 57.16; H, 3.66; N, 5.29.

### Example 5

### Preparation of 2-(tert-butyl)-7-(4-(tert-butyl)phenyl)-6-methyl-9-phenyl-7H-purin-9-ium di-hexafluorophosphate (L(61)H₂)

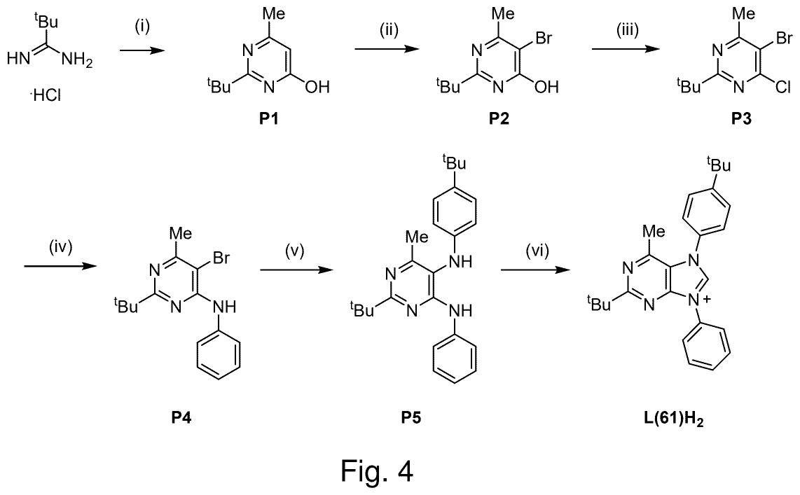

The synthesis of the pro-chelate L(61)H₂ is illustrated in FIG. 4 and the detailed synthetic procedures are as follows:

### 2-(tert-butyl)-6-methylpyrimidin-4-ol (P1)

A solution of pivalimidamide hydrochloride (4.0 g, 29.4 mmol) was added small portions to a stirred solution of NaOH (2.4 g, 60 mmol) in DI water (48 mL) at 0° C. Ethyl acetoacetate (7.5 mL, 58.8 mmol) was added dropwise. After stirred at RT for 12 hours, the mixture was neutralized with aqueous HCl (2.4 M). The induced precipitation was separated and dried. The of f-white solid (3.7 g, 75.8%) was used in the next step without further purification. ¹H NMR (400 MHz, CDCl₃, 296 K): δ 11.61 (br, 1H), 6.15 (s, 1H), 2.27 (s, 3H), 1.37 (s, 9H).

### 5-bromo-2-(tert-butyl)-6-methylpyrimidin-4-ol (P2)

To a 100 mL round flask was added P1 (1.0 g, 6.0 mmol) and 40 mL of dichloromethane. After cooled to 0° C., N-bromosuccinimide (NBS, 1.1 g, 6.0 mmol) was added slowly and the solution was stirred for 30 minutes. It was warmed up to RT and stirred for another 2 hours and, the reaction was quenched by addition of water. The organic phase was separated and concentrated and, the residue was purified by column chromatography eluting with hexane/EA (2/1, v/v) to attain a light yellow solid (1.3 g, 90%). ¹H NMR (400 MHz, CDCl₃, 296 K): δ 11.28 (br, 1H), 2.48 (s, 3H), 1.38 (s, 9H).

### 5-bromo-2-(tert-butyl)-4-chloro-6-methylpyrimidine (P3)

A mixture of P2 (3.2 g, 13.1 mmol) in 10 mL of POCl₃ was refluxed for 30 minutes under N₂ atmosphere. The excess POCl₃ was then distilled off under reduced pressure. The resulting residue was quenched with an ice and water mixture and extracted several times with CH₂Cl₂. Then, the CH₂Cl₂ solution was evaporated under reduced pressure, yielding a slightly viscous, yellow oil, which was used for the next step without further purification. Yield: 2.93 g, 85%. ¹H NMR (400 MHz, CDCl₃) δ 2.65 (s, 3H), 1.36 (s, 9H).

### 5-bromo-2-(tert-butyl)-6-methyl-N-phenylpyrimidin-4-amine (P4)

A mixture of P3 (0.5 g, 1.9 mmol), aniline (0.15 mL, 2.1 mmol) and 10 mL ethylene glycol was stirred at 120° C. for 12 hours. Next, the contents were dissolved in CH₂Cl₂ and washed with H₂O and brine in sequence. The organic layer was collected, dried over anhydrous Na₂SO₄ and concentrated to dryness. The solvent was removed, and the residue was purified by silica gel column chromatography, giving a yellow solid with yield: 0.44 g (73%). ¹H NMR (400 MHz, CDCl₃) δ 7.73 (d, J=8.0 Hz, 2H), 7.36 (t, J=8.0 Hz, 2H), 7.26 (s, 1H), 7.09 (t, J=8.0 Hz, 1H), 2.55 (s, 3H), 1.37 (s, 9H).

### 2-(tert-butyl)-N⁵-(4-(tert-butyl)phenyl)-6-methyl-N⁴-phenylpyrimidine-4,5-diamine (P5)

P4 (500 mg, 1.57 mmol), 4-tert-butylaniline (0.27 mL, 1.73 mmol), NaOtBu (225 mg, 2.35 mmol), Pd₂(dba)₃ and SPhos (66 mg, 0.16 mmol) were dissolved in 50 mL toluene. After refluxed for 8 hours, the solvent was removed under reduced pressure. The residue was dissolved in ethyl acetate and washed with brine. The organic layer was collected and dried over anhydrous Na₂SO₄. The solvent was removed, and the residue was purified by silica gel column chromatography, giving an off-white solid with yield: 481 mg (79%). ¹H NMR (400 MHz, CDCl₃) δ 7.75 (d, J=8.8 Hz, 2H), 7.49 (s, 1H), 7.33 (t, J=8.8 Hz, 2H), 7.24 (d, J=8.8 Hz, 2H), 7.03 (t, J=8.8 Hz, 1H), 6.59 (d, J=8.8 Hz, 2H), 4.78 (s, 1H), 2.31 (s, 3H), 1.45 (s, 9H), 1.30 (s, 9H).

### 2-(tert-butyl)-7-(4-(tert-butyl)phenyl)-6-methyl-9-phenyl-7H-purin-9-ium di-hexafluorophosphate (L(61)H₂)

To a mixture of P5 (100 mg, 0.26 mmol) and NH₄BF₄ (270 mg, 2.6 mmol) was added 10 ml of triethyl orthoformate. After refluxed for 3 hours, the solvent was removed under reduced pressure. The residue was dissolved in MeOH (2 mL), followed by addition 15 mL aqueous solution of KPF₆ (4.60 g, 40.0 mmol) and stirred at RT for 2 h. The precipitation was filtered, washed with deionized water and diethyl ether, and dried under vacuum to afford a light yellow solid of L(61)H₂. Yield: 2.15 g (98%). ¹H NMR (400 MHz, DMSO-d₆, 296 K) δ 8.78 (s, 1H), 7.77 (d, J=8.0 Hz, 2H), 7.44 (d, J=8.0 Hz, 2H), 7.31 (t, J=7.6 Hz, 2H), 7.21 (d, J=8.0 Hz, 2H), 7.02 (t, J=7.6 Hz, 1H), 2.07 (s, 3H), 1.34 (s, 9H), 1.26 (s, 9H).

### Example 6

Preparation of Purin-8-ylidene-Based Ir(III) Metal Complex 61

The pro-chelate L(61)H₂ (48 mg, 0.1 mmol), sodium acetate (24 mg, 0.3 mmol), mer-IrCl₃(tht)₃ (24 mg, 0.03 mmol) and o-dichlorobenzene (8 mL) were added to a 25 mL flask. The mixture was refluxed for 12 hours with vigorous stirring. After removal of solvent under vacuum, the residue was taken into CH₂Cl₂ and washed with deionized water. The organic phase was separated, dried over anhydrous Na₂SO₄, and concentrated. The residue was purified by column chromatography with a mixture of n-hexane and ethyl acetate (1/9) to afford complex 61. Further recrystallization with CH₂Cl₂ and methanol attained a light-yellow solid of complex 61 (25 mg, 61%).

Spectroscopic data of complex 61: HRMS (ESI) for C₇₈H₈₇IrN₁₂ [M+H⁺]: calcd 1385.6884, found 1385.6712; ¹H NMR (400 MHz, CDCl₃) δ 8.96 (dd, J=8.0, 1.2 Hz, 3H), 7.36 (dd, J=8.0, 2.0 Hz, 3H), 7.15 (td, J=7.6, 1.2 Hz, 3H), 6.76 (td, J=7.6, 1.2 Hz, 3H), 6.54 (dd, J=7.2, 1.6 Hz, 3H), 6.48-6.44 (m, 6H), 6.33 (dd, J=8.0, 2.0 Hz, 3H), 1.52 (s, 27H), 1.46 (s, 9H), 0.99 (s, 27H). Anal. Calcd. For C₇₂H₆₀IrN₉: C, 67.65; H, 6.33; N, 12.14. Found: C, 67.60; H, 6.38; N, 12.16.

### Example 7

Structural Characterization of Complexes f-CN1 and f-CN2 (Complexes 1 and 4)

The structures of complexes f-CN1 and f-CN2 are initially verified by ¹H and ¹³C NMR spectroscopy and high-resolution mass spectrometry. The ¹H NMR analyses indicated the possession of symmetrically arranged cyclometalating chelates, which unambiguously ruled out the formation of both the meridional isomer and facial isomer with asymmetrically arranged carbene chelates.

In contrast to the formation of mixed products, which are believed to be commonly observed in other reported systems, the selective formation of a single product of this work can be rationalized by the steric encumbrance exerted between the peri-substituted cyano group and nearby N-aryl group of benzo[d]imidazol-2-ylidene entity. Influence of this peri-substituent is more-or-less equivalent to the employment of 2,6-dialylphenyl or 3,5-dialylphenyl substituent on the typical N-heterocyclic carbene in controlling the site of cyclometalation reaction, but the latter turned out to be fruitless in obtaining the wanted tris-bidentate Ir(III) carbene complexes. For further verification, the isolated complexes f-CN1 and f-CN2 were heated in the presence of the mixed acidic catalyst (NaOAc+TsOH) and in refluxing 1,2,4-trichlorobenzene at 214° C. Again, neither substantial decomposition nor isomerization was observed under the applied condition, which reaffirmed their high thermal and chemical stability.

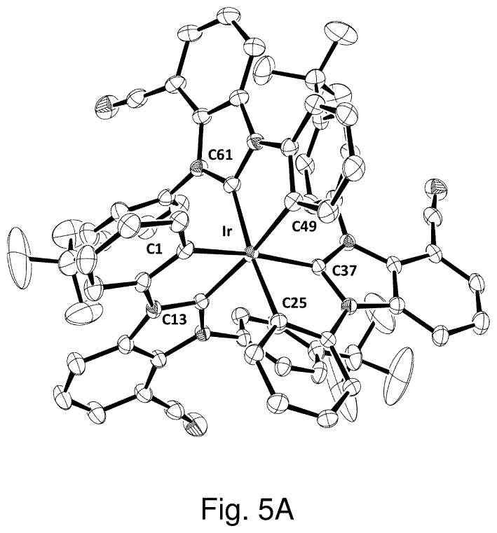

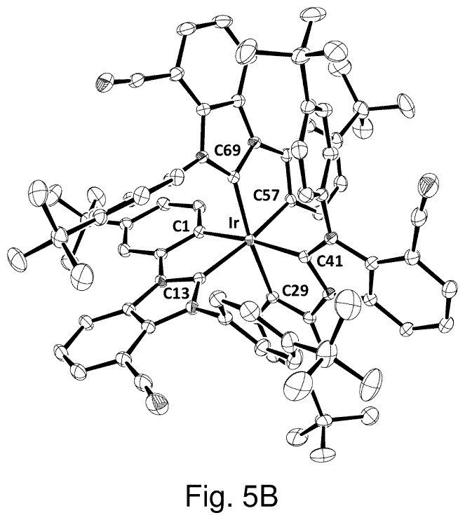

To confirm the identity of chelates and gross coordination arrangement of these complexes, single crystal X-ray diffraction studies were conducted. The single crystals of f-CN1 and f-CN2 were successfully grown in layered methanol-CH₂Cl₂ solution at RT. As depicted in FIGS. 5A and 5B, both complexes possess quasi-octahedral structures with facially coordinated chelates. And all Ir-C(carbene) distances (2.032-2.047 Å) are shorter than Ir-C(aryl) distances (2.081-2.099 Å), indicating stronger Ir-carbene dative interactions in reference to the cyclometalating Ir-C bond lengths. Notably, f-CN2 exhibited relatively longer average Ir-C(aryl) distance (2.043 Å) and Ir-C(carbene) distance (2.091 Å) in reference to those of f-CN1, c.f., 2.035 Å and 2.083 Å, reconfirming the remarkable influence of electron-donating t-butyl substituent.

### Example 8

Structural Characterization of Complexes f-Ir(ptBp) and f-Ir(tBpp) (Complexes 47 and 48)

The gross arrangement of chelates can be further confirmed by ¹H and ¹⁹F NMR spectroscopy. For f-Ir(ptBp)₃, its structural assignment is confirmed by the observation of a total of four sets of doublet of doublet at δ 7.53 (dd, J=8.4, 2.4 Hz), 7.36 (dd, J=8.4, 2.4 Hz), 6.68 (dd, J=8.0, 2.0 Hz) and 6.54 (dd, J=8.0, 2.0 Hz) at room temperature, to which the distinctive JHH coupling constants of 8.4 and 2.4 Hz, 8.0 and 2.0 Hz were assigned for the ABXY spin coupling pattern, due to the hindered rotation of these t-butylphenyl appendages. Notably, in addition to the formation of solely the f-isomers for both f-Ir(tBpp)₃ and f-Ir(ptBp)₃, the pro-chelates L(47)H₂ and L(48)H₂ possess two distinctive aryl groups which, in principle, have equal probability of undergoing metal cyclometalation in affording isomeric products. However, only the aryl group that is far-away from the ortho-substituted CF₃ group underwent selective cyclometalation, leaving the adjacent aryl group as free appendage, as shown in f-Ir(tBpp)₃ and f-Ir(ptBp)₃.

This enhanced selectively is most probably caused by the steric encumbrance exerted between the CF₃ group at 7-position and adjacent 1-aryl group of benzo[d]imidazol-2-ylidene entity. Furthermore, the reversible C—H activation and cyclometalation of aryl appendages is also responsible for the selective formation of single product in presence of sodium acetate at elevated temperature.

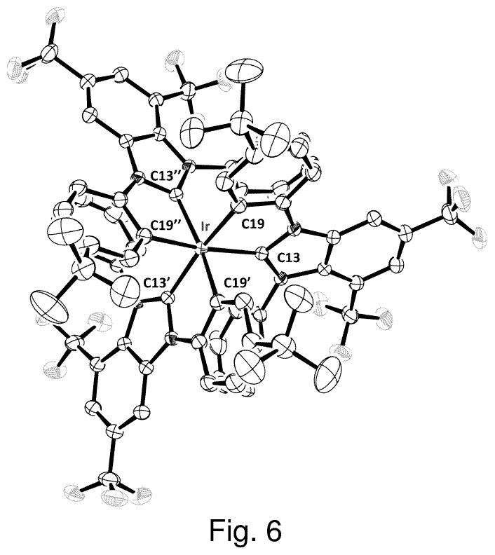

Single crystal X-ray diffraction study on f-Ir(tBpp)₃ was executed to confirm the coordination arrangement of chelates. As depicted in FIG. 6, C_{(aryl)}-Ir-C_{(carbene)} distances, with Ir-C19=2.0903(19) and Ir-C13=2.0428(17) Å, were observed in the f-coordinated f-Ir(tBpp)₃. The averaged torsional angle is calculated to be around 23°, which is believed to be a major driving force in giving the structural selectivity as observed in Ir(III) complexes f-Ir(tBpp)₃ and f-Ir(ptBp)₃.

### Example 9

Photophysical Properties of Complexes f-CN1 and f-CN2 (Complexes 1 and 4)

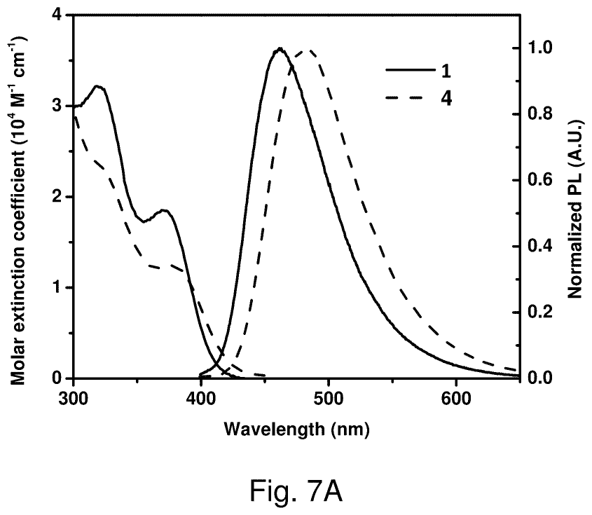

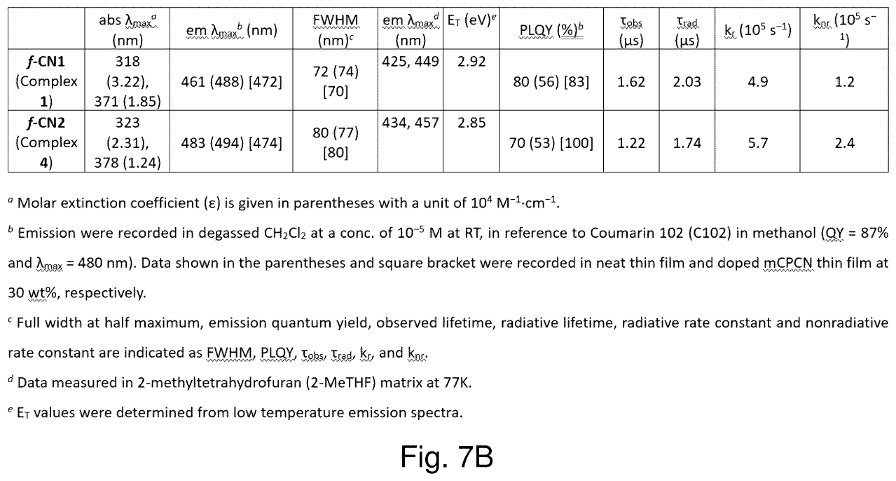

Both f-CN1 and f-CN2 gave similar absorption spectral pattern. As shown in FIG. 7A, the absorption peak max. of f-CN1 (318 and 371 nm) occurred at the higher energy than those of f-CN2 (323 and 378 nm), c.f. FIG. 7B. They can be attributed to the intra-ligand charge transfer (ILCT) and metal-to-ligand charge transfer (MLCT) process, to which the red shifting of f-CN2 was attributed to the electron donating effect of the t-butyl group on the aryl cyclometalates. Upon excitation, they exhibited structureless emission peak max. (λₘₐₓ) at 461 and 483 nm in degassed CH₂Cl₂ solution, affirming the inherent electron deficiency of the peri-cyano substituent. Moreover, both f-CN1 and f-CN2 exhibited photoluminescent quantum yield (PLQY) of 80% and 70% and relative short observed lifetime (τ_{obs}) of 1.62 and 1.22 s, from which we obtained the radiative lifetime of 2.03 and 1.74 s according to the formula of τ_{rad}=τ_{obs}/PLQY. Upon lowering the temperature to 77 K, both f-CN1 and f-CN2 displayed notable blue-shifted emission (425 and 434 nm) in comparison to those recorded at RT due to the rigidochromism occurred in the frozen 2-MeTHF solution. Moreover, both samples have exhibited structured profiles with an additional lower energy shoulder at 449 and 457 nm for f-CN1 and f-CN2, respectively, due to the increased ligand-centered ππ* contribution.

### Example 10

Photophysical Properties of Complexes f-Ir(ptBp) and f-Ir(tBpp) (Complexes 47 and 48)

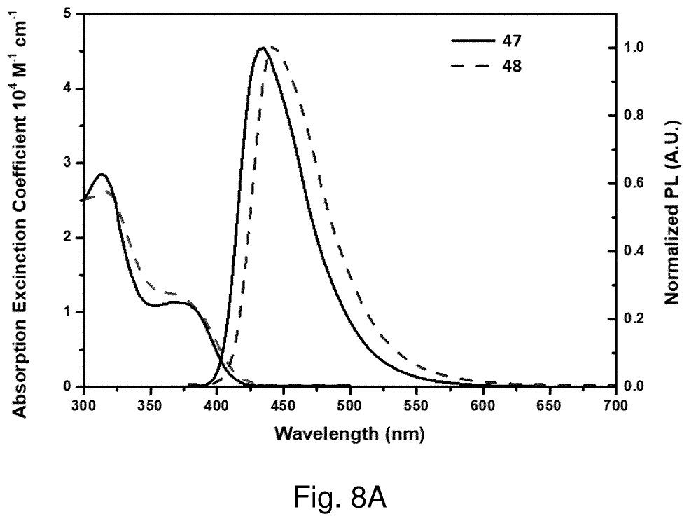

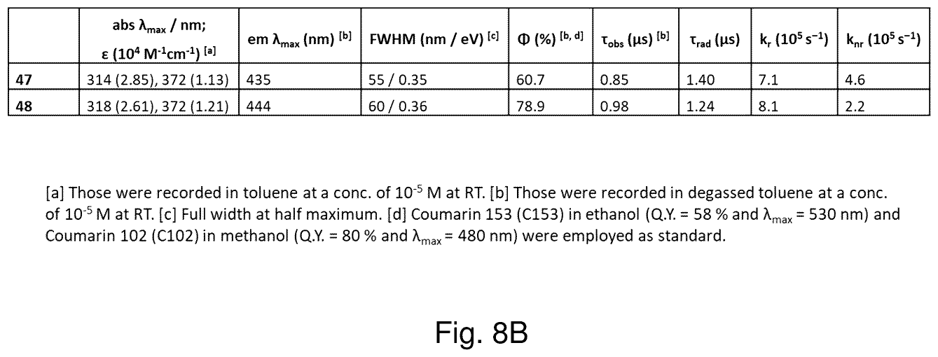

FIG. 8A depicted the UV-Vis absorption and emission spectra of the studied Ir(III) complexes f-Ir(tBpp)₃ and f-Ir(ptBp)₃ in toluene and degassed toluene, to which the respective numeric data are summarized in FIG. 8B. Generally speaking, both complexes exhibit multiple high energy bands beyond 320 nm, which can be assigned to ligand-centered ππ* and/or ligand-to-ligand charge transfer (LLCT) transitions. Notably a strong absorption band centered at ˜370 nm was observed, which is believed to be a signature of f-arranged Ir(III) carbene complexes.

For photoluminescence, the emission difference between f-Ir(tBpp)₃ (444 nm) and f-Ir(ptBp)₃ (435 nm) may be rationalized by which the former possesses t-butyl substituent at the cyclometalating sites. Interestingly, these two complexes with di-N-aryl substituted chelates display both the blue emission peak and narrowed emission band with FWHM of <60 nm, showing the reduced influence from the solvation. Moreover, these facial-arranged complexes exhibit high quantum yield of 60.7-78.9% and short radiative lifetime between 1.24 s and 1.40 s under the same measurement conditions, confirming their potential in fabricating efficient OLED devices.

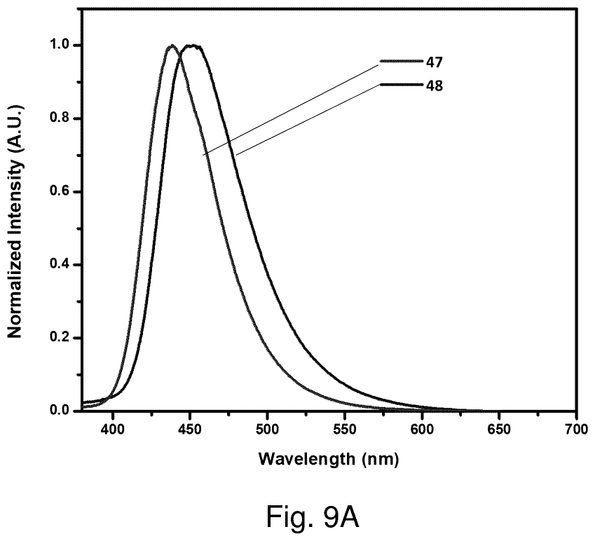

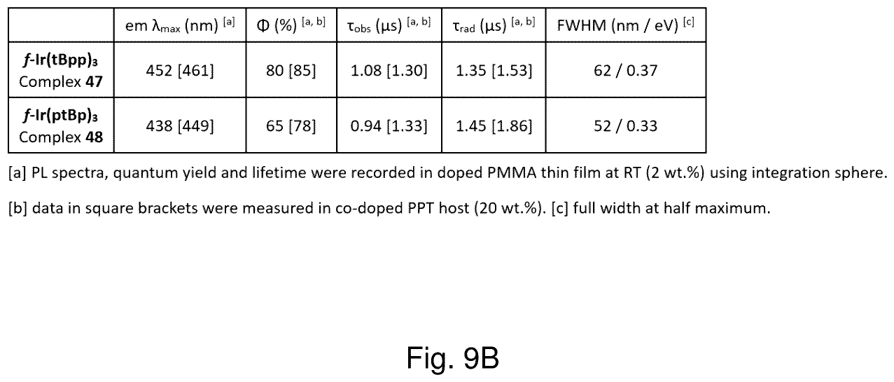

Furthermore, the emission of these Ir(III) complexes with a concentration of 2 wt % dopped in PMMA were measured and summarized in FIGS. 9A and 9B. both complexes afforded red-shifting in emission and no notably change in band width at the same time, affirming their good photophysical properties in both the solution and thin film states.

### Example 11

Thermal and Electrochemical Properties of Complexes f-CN1 and f-CN2 (Complexes 1 and 4)

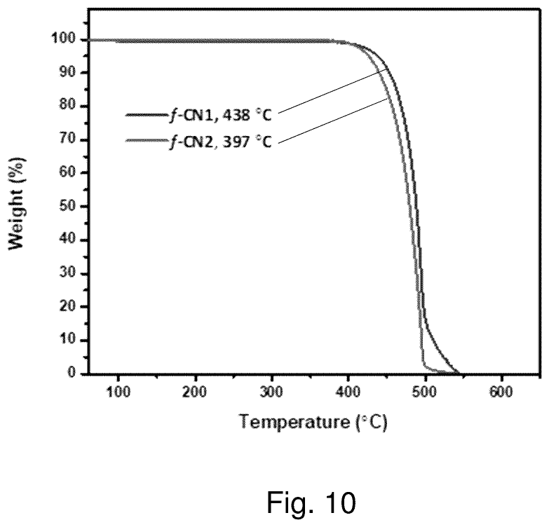

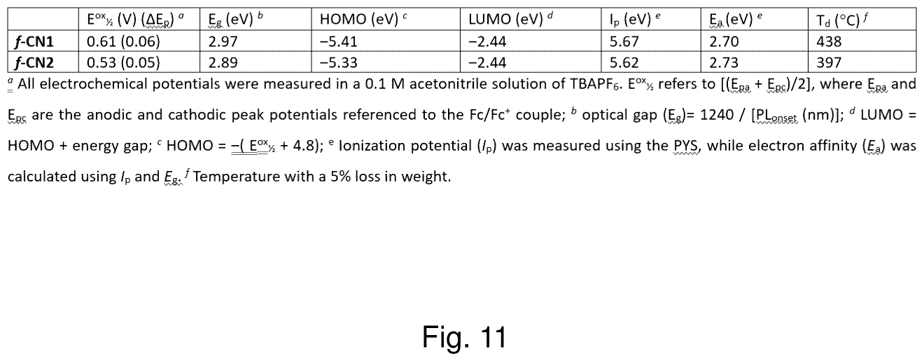

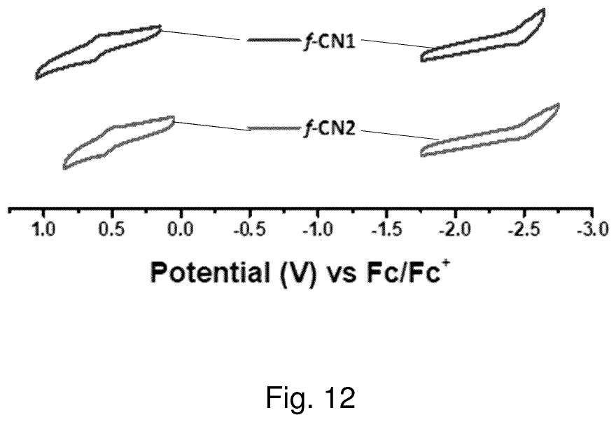

Both f-CN1 and f-CN2 possess good thermal stability with high decomposition temperature (T_{d}, 5% weight loss) up to 397° C. under N₂ atmosphere (FIG. 10), to which the decomposition temperature (T_{d}) is defined as the temperature with a 5% loss in weight during heating. Moreover, as depicted in FIGS. 11 and 12, these carbene complexes presented reversible metal-centered oxidation with potential calculated to be 0.61 and 0.53 V (vs Fc/Fc⁺), from which their HOMO levels were calculated to be −5.41 and −5.33 V, respectively. After then, optical energy gap was estimated using the onset of emission band, from which the LUMO energy level of −2.44 V for both f-CN1 and f-CN2 can be estimated using the equation: LUMO=HOMO+optical gap.

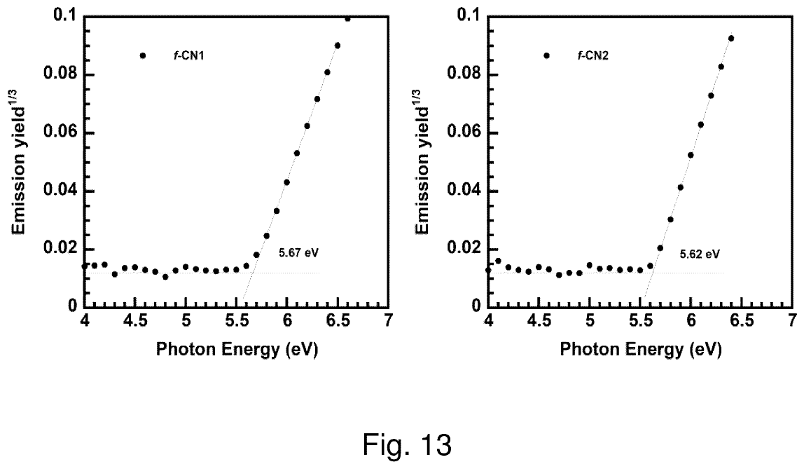

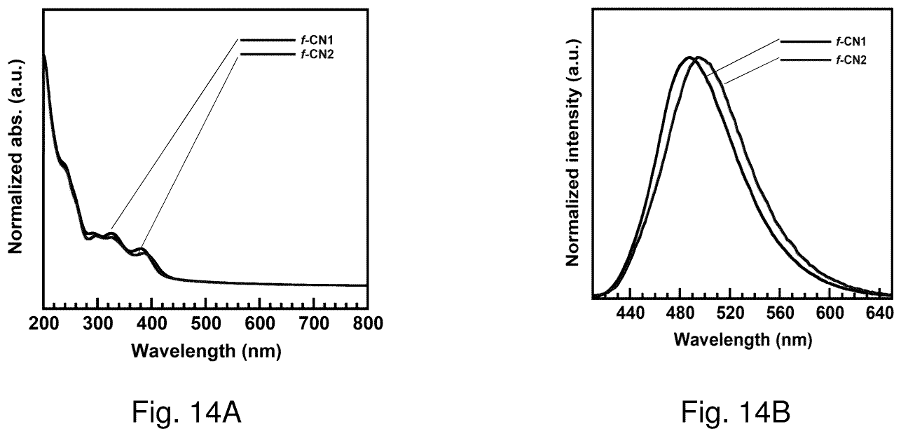

For further comparison, the ionization potential and electron affinity of both complexes were also measured as neat thin film, to which the data were also depicted in FIG. 11. For verification, their ionization potential (Iₚ) was also evaluated using photoelectron yield spectrometry (PYS), giving 5.67 eV for f-CN1 and 5.62 eV for f-CN2, respectively (FIG. 13). The introduction of electron-donating t-butyl group made the Iₚ value 0.05 eV shallower. Then, the energy gap (E_{g}) was estimated from the edge of UV-vis absorption spectra to be 2.97 eV for f-CN1, and 2.89 eV for f-CN2 (FIGS. 14A and 14B). From the Iₚ and E_{g} values, the electron affinity (Eₐ) values were calculated to be ˜2.7 eV. Despite having some discrepancy, they showed the high potential of being the efficient emitters in the fabrication of blue OLED devices.

### Example 12

Thermal and Electrochemical Properties of Complexes f-Ir(ptBp) and f-Ir(tBpp) (Complexes 47 and 48)

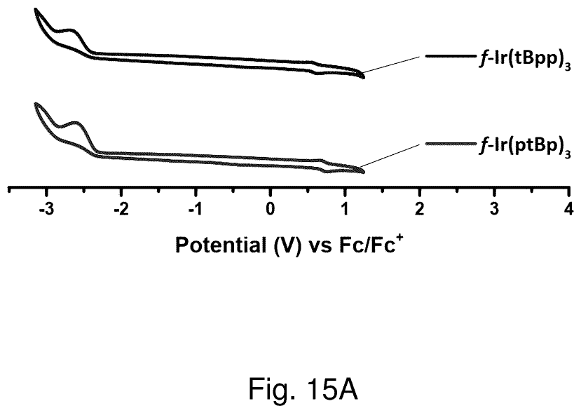

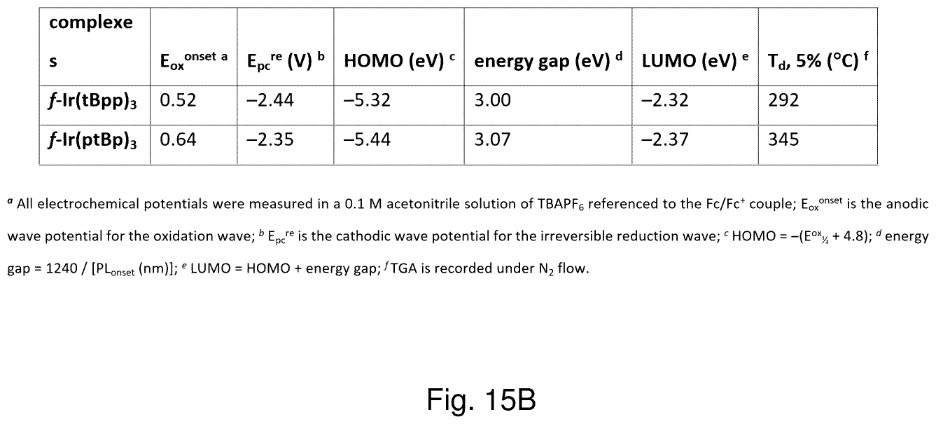

Cyclic voltammetry of complexes f-Ir(ptBp) and f-Ir(tBpp) was measured in acetonitrile solution at RT (FIGS. 15A and 15B). The oxidation mainly occurred at the Ir(III) metal center, with the oxidation onset potentials of f-isomers occurring between the region of 0.52-0.64 V (vs. Fc/Fc⁺). Complexes f-Ir(tBpp)₃ and f-Ir(ptBp)₃ showed quasi-reversible oxidation peaks with the anodic onsets at 0.52 and 0.64 V, respectively. It appears that the pendent N-aryl group had improved the reversibility to the oxidized complexes. Alternatively, all these Ir(III) complexes presented irreversible reduction peak spanning from −2.44 to −2.35 V.

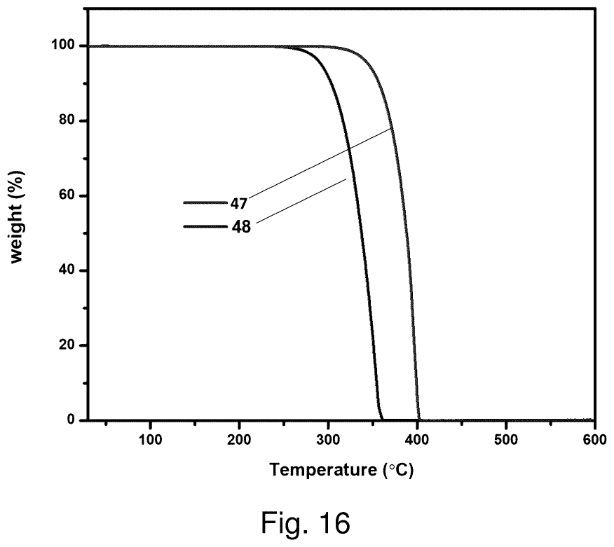

Thermal gravimetric data were next recorded and given in FIGS. 15B and 16. As can be seen, f-Ir(tBpp)₃ appeared to possess a lower decomposition temperature (T_{d}) (292° C.) as compared with f-Ir(ptBp) (T_{d}>345° C.). Interestingly, all these emitters can be purified by vacuum sublimation with operational temperature being ˜60° C. lower than their T_{d}, indicating the CF₃ group has greatly improved their volatility and enables the fabrication of OLED devices via more convenient vacuum deposition processes.

### Example 13

Theoretical Investigation of Complexes f-CN1 and f-CN2 (Complexes 1 and 4)

The lowest singlet (S₁) and lowest triplet (T₁) excited states of these Ir(III) complexes were investigated by time-dependent density functional theory (TD-DFT) calculations, for identifying absorption/emission bands and effect of chelate modification versus photophysical properties.

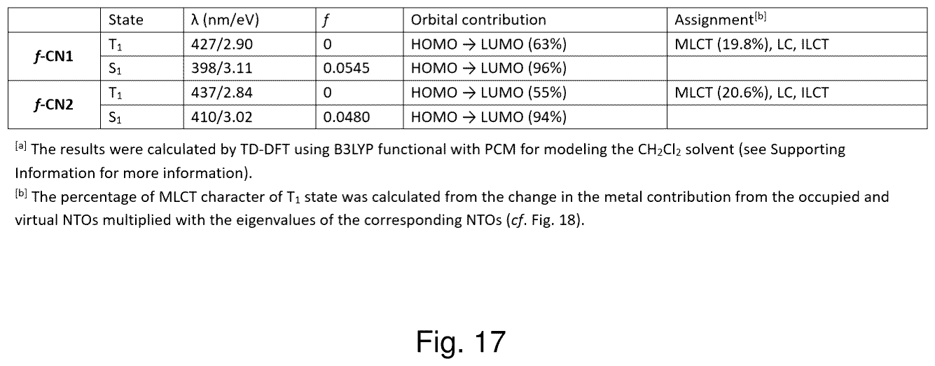

The calculated S₁ energies were 398 nm and 410 nm for f-CN1 and f-CN2, respectively (cf. FIG. 17), which are correlated to their experimental lowest-energy absorption tails around 410 and 420 nm, respectively (cf. FIGS. 7A and 7B). The calculated T₁ energies were 427 nm and 437 nm for f-CN1 and f-CN2, respectively (cf. FIG. 17), showing the same trend versus their experimental phosphorescence (peaking at 461 nm and 483 nm, respectively; cf. FIGS. 7A and 7B). This trend shows the substitution of t-butyl groups for the N-aryl cyclometalates (cf. f-CN1→f-CN2), that red-shifts the emission energy moderately (less than 0.1 eV).

Note the deviation between the calculated T₁ excitation energy and the experimental emission wavelength is around 0.25 eV (˜6 kcal mol⁻¹). It is believed that this deviation is commonly observed in cyclometalating Ir(III) complexes, which is mainly caused by the uncertainties of both the applied theoretical levels and adopted structure of emissive excited states. Nevertheless, the trend of the energy gap obtained by the theoretical approach is consistent with that of experimental results and the analysis of calculated T₁ state would allow gaining necessary information of the emissive states.

The orbital pairs representing the T₁ excited state were further analysed to reveal its essential characters and the radiative rate of the emissive states. The frontier molecular orbitals (MOs) involved in the electronic excitations to the T₁ state from ground state were listed in FIG. 17. For both complexes, the T₁ states are contributed by a list of transitions without a single dominant component (i.e., contribution >75%).

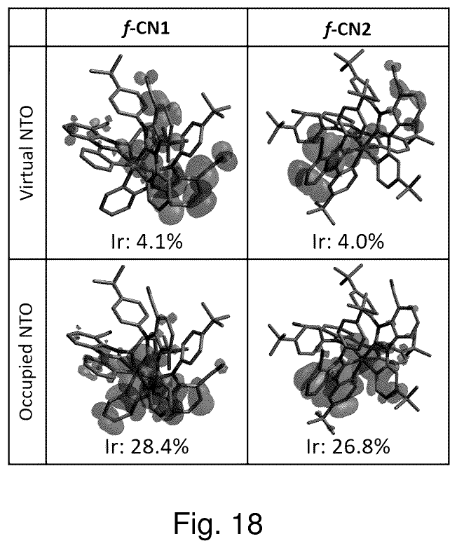

To obtain a clear and compact orbital representation for the T₁ state, natural transition orbitals (NTOs) analysis was applied to express the T₁ state as a single pair of orbitals. The predominant NTO pair found for the T₁ state were present in FIG. 18. Both complexes show similar localization of occupied and virtual NTOs for the T₁ excited state. The occupied NTOs are delocalized over the Ir(III) atom and three chelates except the N-aryl group near the peri-cyano group (cf. FIG. 18), which is consistent with our expectation that a peri-cyano group blocks its nearby N-aryl group for undergoing metal cyclometalation. However, the virtual NTOs are mainly localized at solely the peri-cyano groups and benzo[d]imidazolylidenes (no localization on both N-aryl groups). Therefore, these Ir(III) complexes show a mixture of metal-to-ligand charge transfer (MLCT), intra-ligand charge transfer (ILCT), and ligand-centered (LC) characters. Notably, the orbital overlap between a NTO pair and Ir(III) metal atom (cf. FIG. 18) and the percentage of MLCT transition in the T₁ state (cf. FIG. 17) differs slightly. The addition of t-butyl groups (cf. f-CN1→f-CN2) leads to a slightly increased MLCT percentage but a slightly decreased orbital overlap. Thus, it is believed that this would further affect the radiative rate of the studied Ir(III) complexes.

It is believed that the calculated radiative rate constant of the T₁ state is mainly determined by two components, that is, the percentage of MLCT transition and the localization of the pair of orbitals dominantly contributing to the T₁ state (such as NTO pair for T₁ state in this work). On one hand, more MLCT percentage should give greater radiative rate constant due to the direct involvement of Ir(III) metal atom that facilitates intersystem crossing. On the other hand, the increasing orbital overlap also leads to an increased radiative rate constant due to an increased transition dipole moment. For this family of Ir(III) complexes, f-CN2 achieved larger MLCT percentage (20.6%) but a less orbital overlap (0.56 a.u.). The competition of these distinctive components resulted in a slightly greater radiative rate constant for f-CN2 (5.7×10⁵ s⁻¹) than that of f-CN1 (4.9×10⁵ s⁻¹).

### Example 14

Theoretical Investigation of Complexes f-Ir(ptBp) and f-Ir(tBpp) (Complexes 47 and 48)

The lowest singlet (S₁) and triplet (T₁) excited states for the Ir(III) complexes 47 and 48 were investigated by TD-DFT calculations to gain understanding of the nature of the absorption/emission bands and the effect of chelate modification on their photophysical properties.

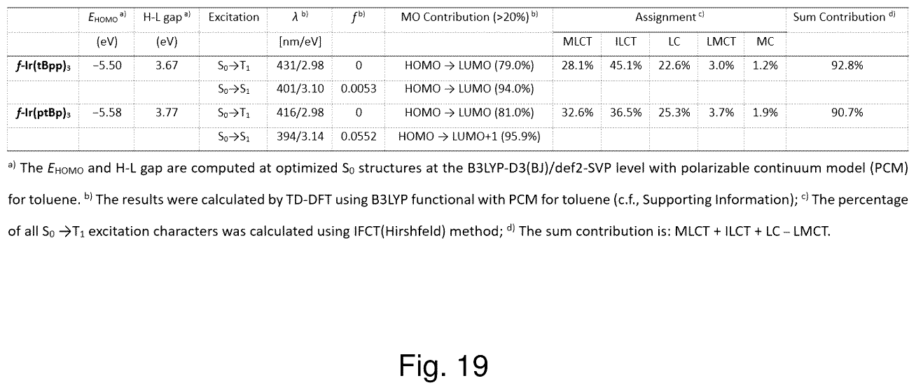

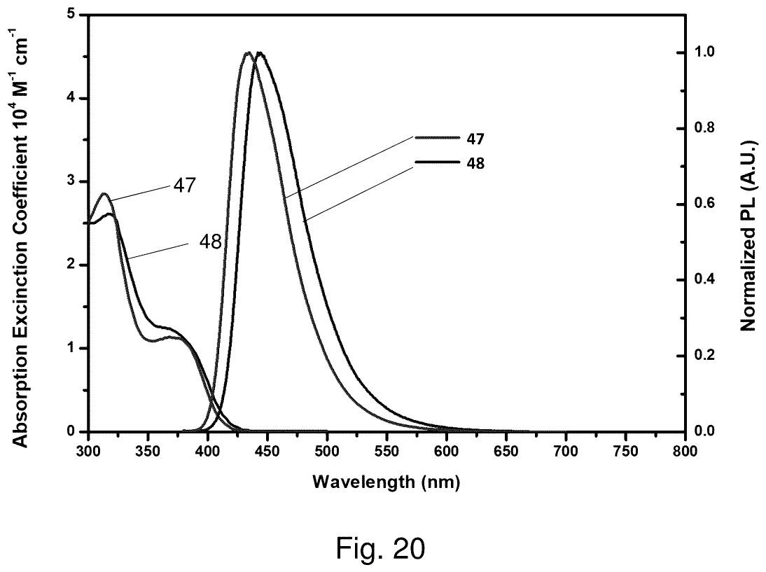

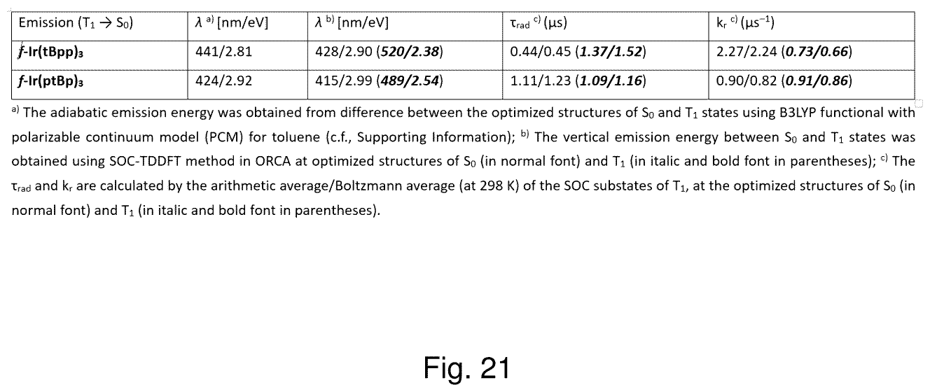

The vertical excitation energies of the S₀→S₁ transition were calculated to be 401 and 394 nm for f-Ir(tBpp)₃ and f-Ir(ptBp)₃, respectively (FIG. 19), which are correlated with their experimental lowest-energy absorption tails around 400 nm (FIG. 20). The calculated vertical excitation energies for the S₀→T₁ transition, which is usually used to represent the T₁→S₀ emission at equilibrium structure of S₀, were 431 and 416 nm for f-Ir(tBpp)₃ and f-Ir(ptBp)₃, respectively (FIG. 19). Those values are comparable with the experimental phosphorescence (λPL max=444 and 435 nm in toluene; λₘₐₓ=452 and 438 nm in doped PMMA thin film, respectively; see FIGS. 8B, 9B and 20) with a MAD (mean absolute deviation) about ≈0.25 eV (≈5.7 kcal·mol⁻¹) in toluene. Moreover, the calculated adiabatic emission energy (441 and 424 nm, FIG. 21) is much closer to the experimental wavelengths in toluene with a smaller MAD (0.06 eV or 1.4 kcal·mol⁻¹).

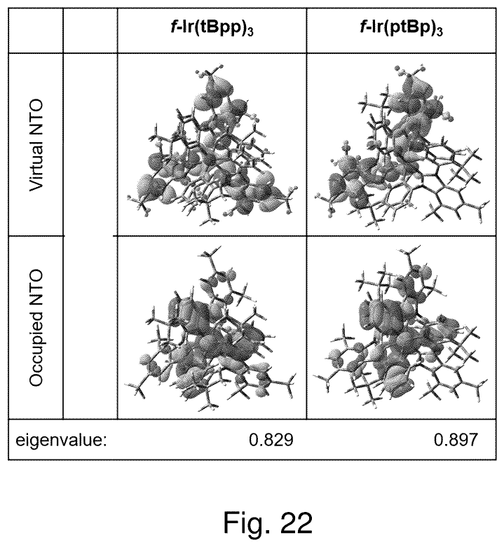

To further understand the emission properties of the Ir(III) complexes 47 and 48, the natural transition orbitals (NTOs) analysis to express the S₀→T₁ transition as a single pair of orbitals was applied. The predominant NTO pairs found for the S₀→T₁ transition are present in FIG. 22. For both complexes, namely f-Ir(tBpp)₃ and f-Ir(ptBp)₃, the occupied NTOs are delocalized at both the Ir(III) metal center and cyclometalating carbene chelates (in π orbitals); while the virtual NTOs are mainly localized at the carbene donor fragments (in π* orbitals).

The inter-fragment charge transfer (IFCT) method, available from the Multiwfn software package, was employed to quantify the contributions of relevant molecular orbitals (MOs) to the selected electronic transition. This manipulation is to provide a better picture of S₀→T₁ transition, to which the percentage of MLCT, intra-ligand charge transfer (ILCT), ligand-centered (LC), ligand-to-metal charge transfer (LMCT) and metal-centered (MC) dd contributions are depicted in FIG. 21. Based on the IFCT analysis, the effect of ligand modification on the kᵣ is summarized as follows: (i) to f-Ir(tBpp)₃ has the highest ILCT percentage (45.1%) observed among all complexes, suggesting its effective ILCT character. (ii) The LMCT character (3.0%) of f-Ir(tBpp)₃ is the smallest one among all complexes. (iii) Simultaneous replacement of both the 4-(t-butyl)phenyl cyclometalate and N-phenyl appendage on f-Ir(tBpp)₃ to the phenyl cyclometalate and 4-(t-butyl)phenyl appendage (i.e., f-Ir(ptBp)₃). The ILCT character of f-Ir(ptBp)₃ turns lower (36.5%), but its MLCT (32.6%) and LC (25.3%) characters are increased slightly. The percentages of ILCT character of f-Ir(ptBp)₃ was 36.5%.

The IFCT method suggests that the S₀→T₁ excitation exhibits a dominant mixture of MLCT, ILCT and LC characters for both facial Ir(III) complexes 47 and 48. The respective sum contribution (FIG. 19) of “MLCT+ILCT+LC-LMCT” of 92.8% and 90.7% for f-Ir(tBpp)₃ and f-Ir(ptBp)₃ correlates excellently with the respective measured kᵣ values (in μs⁻¹, FIG. 8B) of 0.81 and 0.71 from experimental measurements. Based on the IFCT method, it appears that both the facial complexes of f-Ir(ptBp)₃ and f-Ir(tBpp)₃ have fast radiative decay rate (90.7% and 92.8%).

Following the IFCT prediction, calculations were performed to investigate the theoretical τ_{rad} and kᵣ. As it is believed that the “actual” emitting species sit between the ground state (S₀) and excited state (T₁) levels, spin-orbit coupling (SOC)-TDDFT method was applied on both the optimized S₀ and T₁ structures for estimation of τ_{rad} and kᵣ.

The calculated emission energies, τ_{rad} and kᵣ at both optimized S₀ and T₁ geometries are summarized in FIG. 21, to which the results obtained using arithmetic average or Boltzmann average of the SOC substates are similar. Here, focus is put on the arithmetic average results. (i) For f-Ir(tBpp)₃, the experimental Trad of 1.24 μs deviates from the calculated τ_{rad} of 0.44 μs (at the S₀ structure) and 1.37 μs (at the T₁ structure) by +0.80 and −0.13 μs, respectively. It is suggested that the actual emitting intermediate of f-Ir(tBpp)₃ is resemble to both S₀ and T₁ structures. (ii) The calculated Trad of 1.11 μs (at the S₀ geometry) and 1.09 s (at the T₁ geometry) of f-Ir(ptBp)₃ are almost the same, suggesting that its emitting intermediate is resemble to both the S₀ and T₁ structures. It is worth noting here, the uncertainty (˜1.7 s) of τ_{rad} for other Ir(III) complexes predicted with the SOC-TDDFT method is relatively large. From the above analysis, it is concluded that the phosphorescence process of both the facial Ir(III) complexes are likely happened near the S₀ structure.

### Example 15

Solid State Properties, Performance of OLED and Hyper-OLED Devices Derived from Complexes f-CN1 and f-CN2 (Complexes 1 and 4)

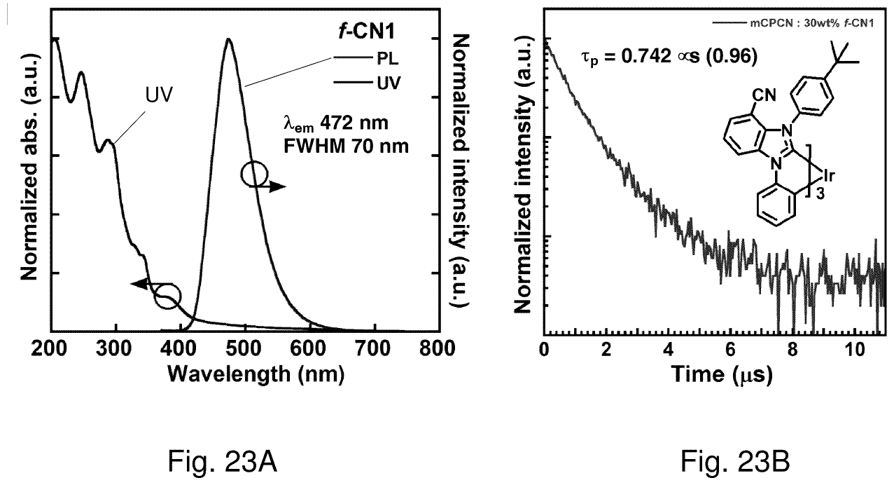

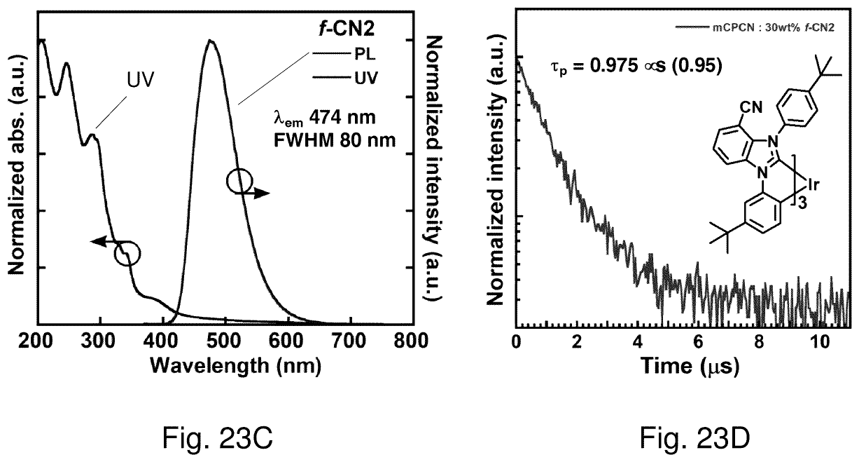

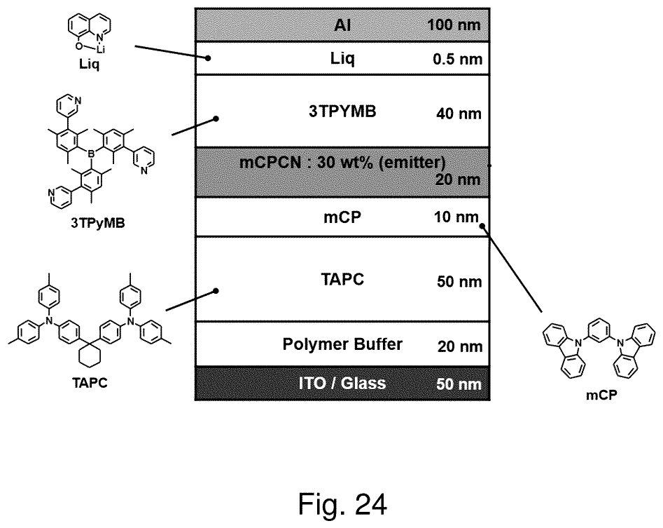

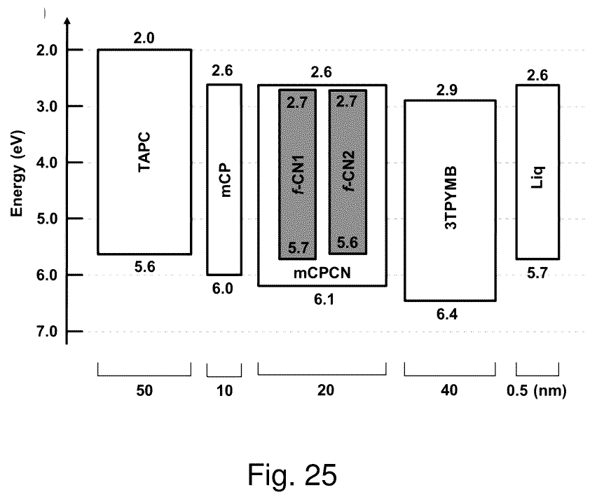

The photophysical properties of f-CN complexes in doped thin films of host material such as mCPCN were investigated. At the doping conc. of 30 wt %, they exhibited PL peak max. at 472 nm and 474 nm, and very high PLQY/narrow FWHM values of 83%/70 nm for f-CN1, and 100%/80 nm for f-CN2, respectively (FIGS. 23A-23D). These excellent photophysical performance characteristics indicated their high resistance toward aggregation caused quenching (ACQ). Additionally, they display very short radiative lifetimes of 0.89 μs and 0.98 μs for f-CN1 and f-CN2, respectively. These superior photophysical data indicate that f-CN1 and f-CN2 can serve as both the sole emitter and superior sensitizer for phosphorescent OLED and hyper-OLED devices. Hence, the f-CN-based OLEDs were first fabricated with a structure of [ITO/polymer buffer (20 nm)/di-[4-(N,N-ditolyl-amino)-phenyl]cyclohexane (TAPC, 50 nm)/mCP (10 nm)/30 wt %, f-CN emitters doped mCPCN (20 nm)/tris[3-(3-pyridyl)-mesityl]borane (3TPYMB, 40 nm)/Liq (0.5 nm)/Al(100 nm)] (FIG. 24). The energy diagram is shown in FIG. 25.

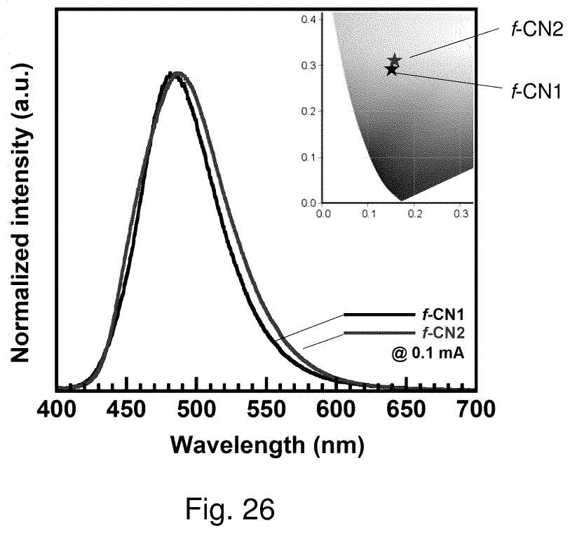

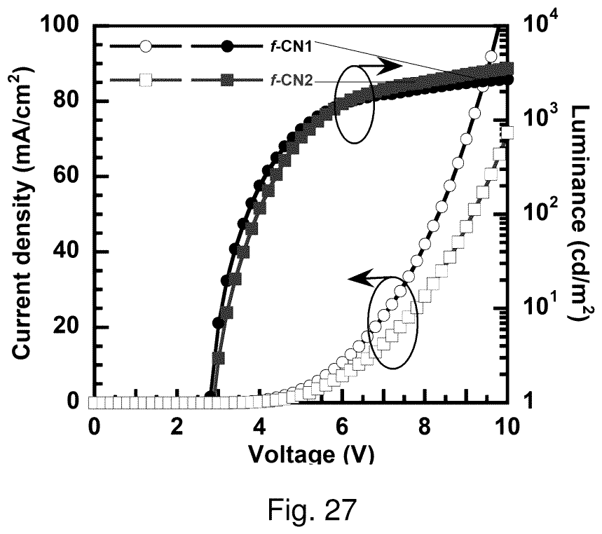

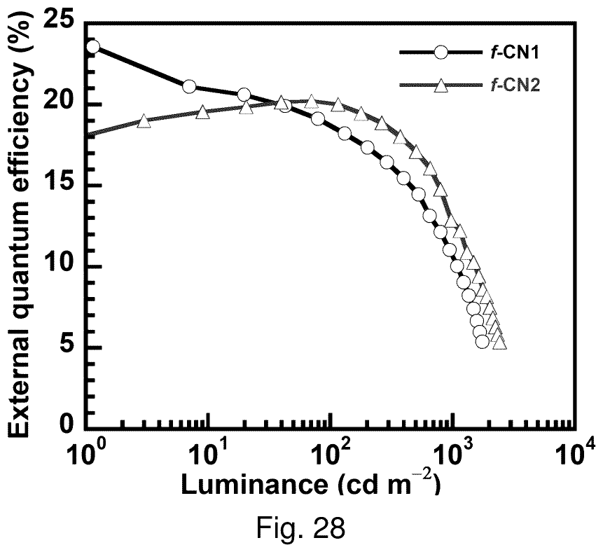

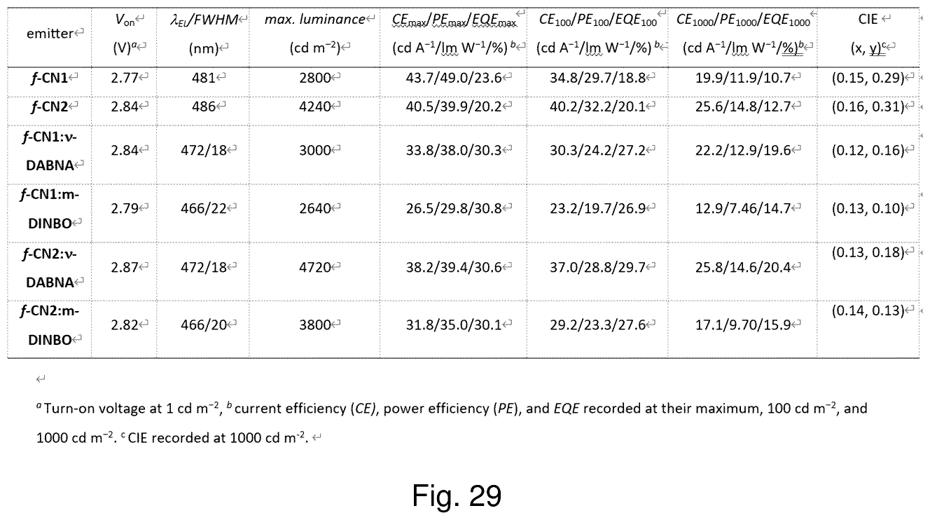

These devices exhibited blue emission with the EL peak wavelength at 481 nm and CIE (0.15, 0.29) for f-CN1, 486 nm and (0.16, 0.31) for f-CN2 (FIG. 26). The FWHM values were recorded to be 64 nm for f-CN1, and 72 nm for f-CN2, respectively. The current density-voltage-luminance (J-V-L) characteristics were displayed in FIG. 27. f-CN1 based device achieved higher current density and luminance compared with those of f-CN2 based device at the driving voltages below 6 V. This can be attributed to the smaller energy difference of 0.3 eV in Iₚ values between mCP and f-CN1. In other words, the larger density-of-state (DOS) overlapping to enhance hole-injection. Because the Eₐ values of both f-CN emitters are identical, these phosphors realized high EQE values up to 23.6% (FIG. 28). Their device performances are summarized in FIG. 29.

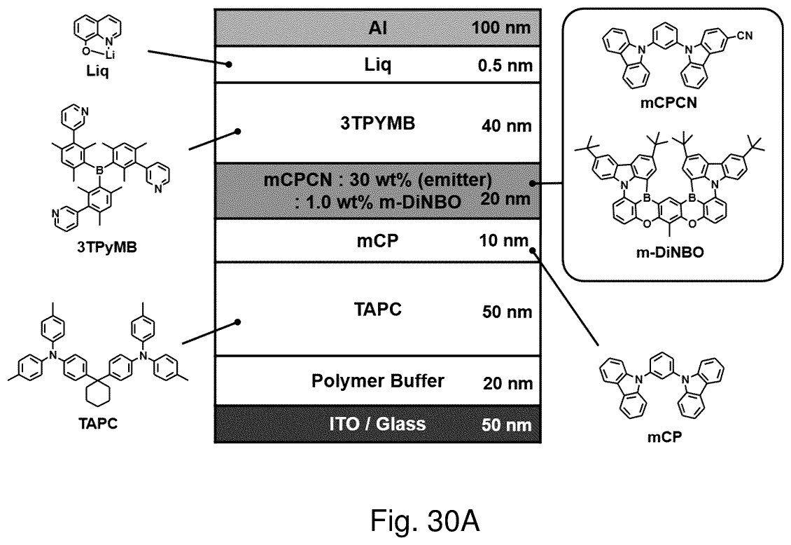

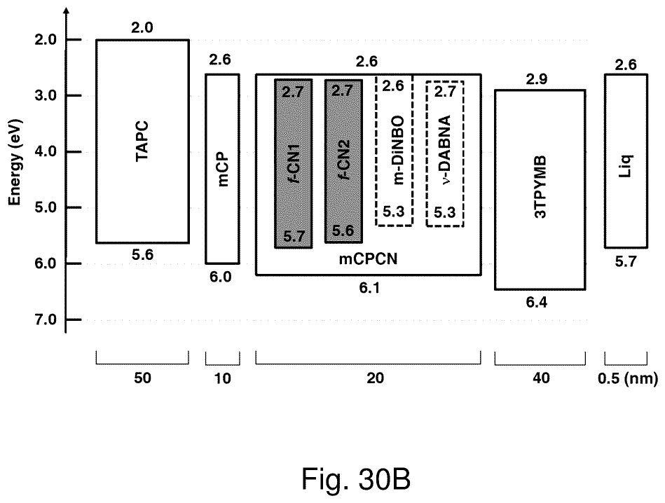

The photophysical properties of the ternary system (i.e., host, dopant sensitizer and terminal emitter) were evaluated to reveal the essential characteristics of the f-CN-based Ir(III) phosphors such as f-CN1 in serving as the sensitizer. This ternary device architecture (c.f. FIGS. 30A and 30B) has been also termed hyper-OLEDs. Two distinctive blue MR-TADF emitters, i.e., v-DABNA and m-DINBO, were initially used as the narrowband emissive terminal emitter. It is notable that these employed organoboron MR-TADF terminal emitters possess relatively slow reverse intersystem crossing rate. Hence, the associated blue OLED devices may suffer from severe efficiency roll-off at the higher current density and, hence, there is a need for efficient phosphorescent dopant sensitizer for bypassing the slower reverse intersystem crossing.

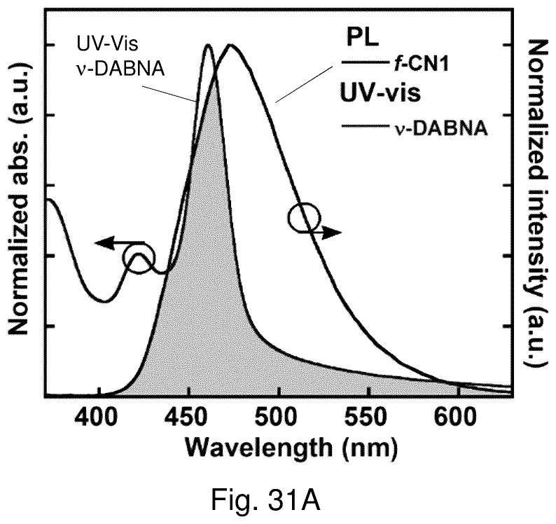

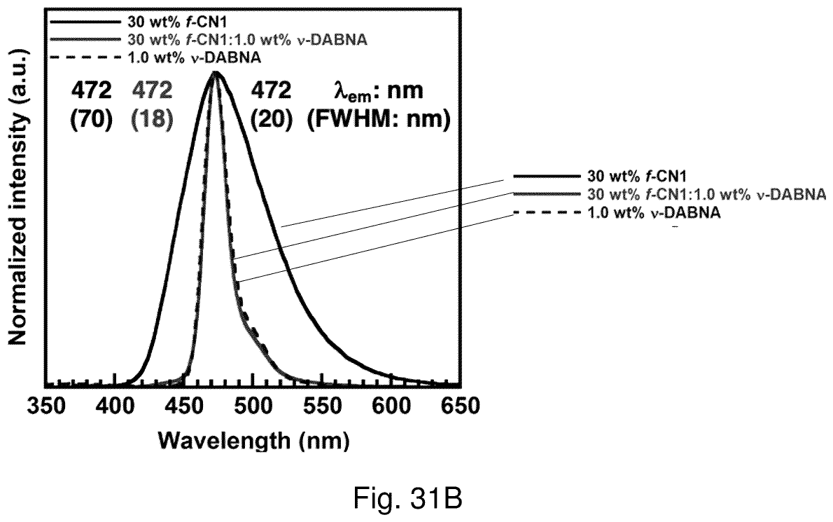

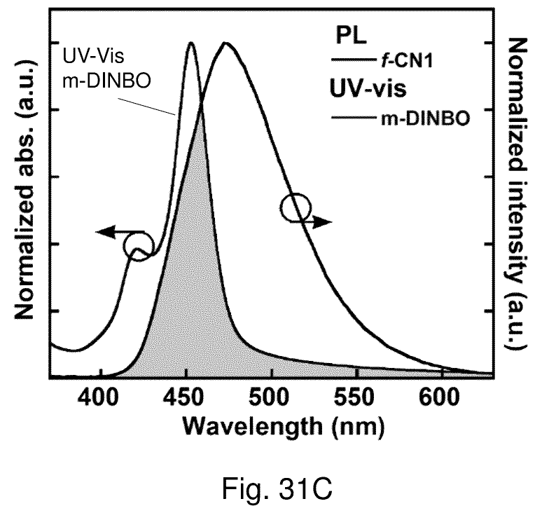

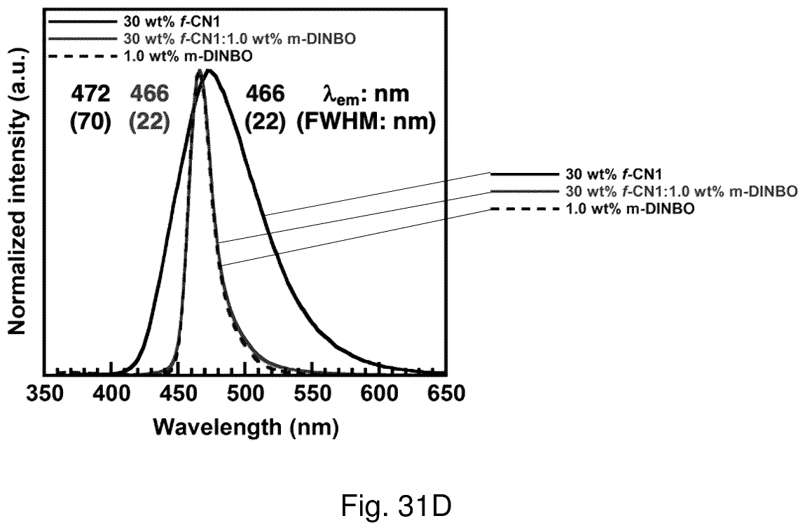

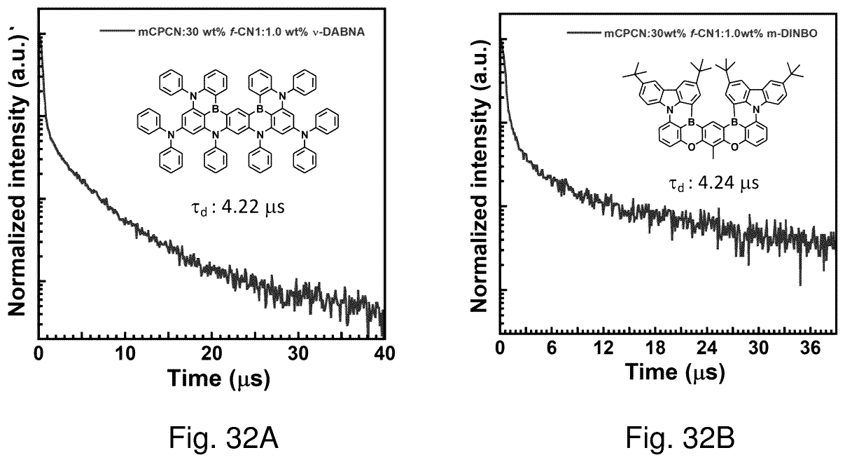

In principle, the PL spectra of f-CN1 showed a large overlap with the absorption spectrum of both blue MR-TADF terminal emitters, implicating superior Forster energy transfer to blue MR-TADF emitters (FIGS. 31A-31D). Moreover, as can be seen, introduction of 1 wt % of organoboron terminal emitter in these ternary systems had effectively realized high PLQY/narrow FWHM values of 100%/18 nm for v-DABNA, and 100%/22 nm for m-DINBO, respectively (FIGS. 31B and 31D). They also achieved an EL emission lifetime τ_{obs} of 4.22 and 4.24 μs (FIGS. 32A and 32B) compared with that of the f-CN1-based system (with PL radiative lifetime Trad of 2.03 μs), to which the slightly lengthened emission lifetime could be attributed to the slower reversed intersystem crossing rate constant of the terminal emitters. Subsequently, the hyper-OLED device using 30 wt % of f-CN2 was also fabricated. All these hyper-OLED performance characteristics are summarized in FIG. 29 for scrutiny.

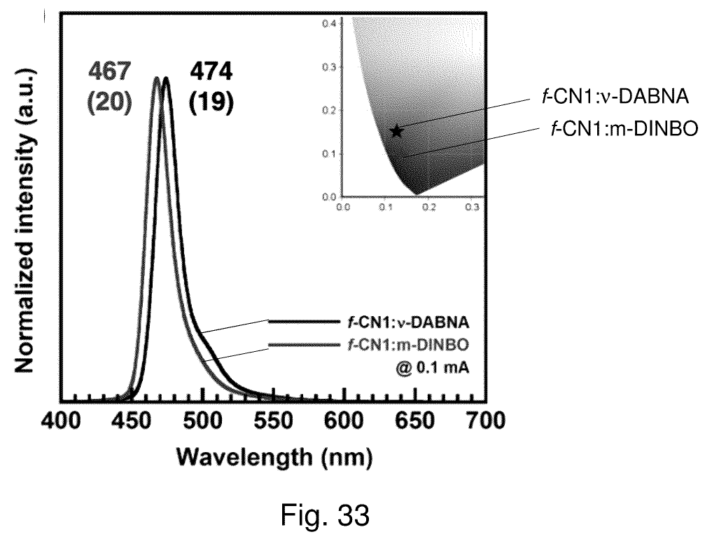

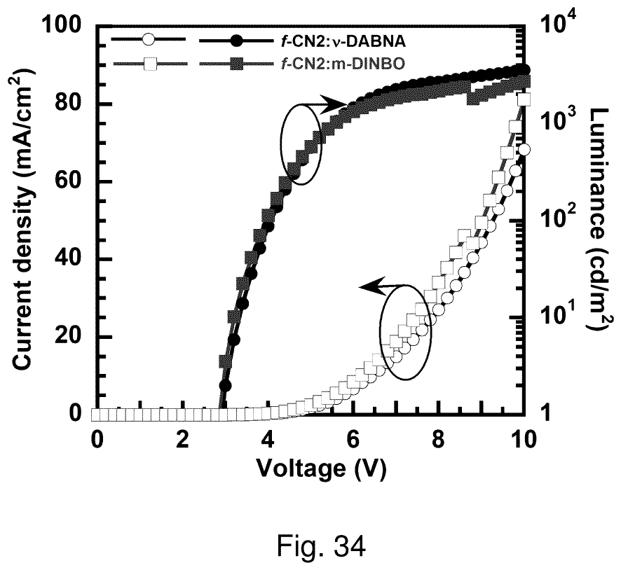

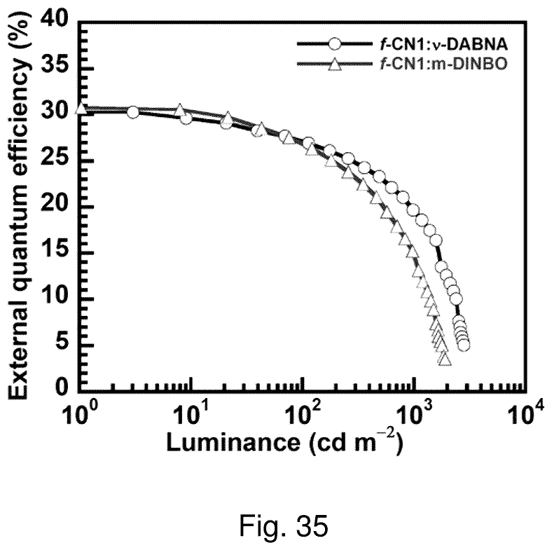

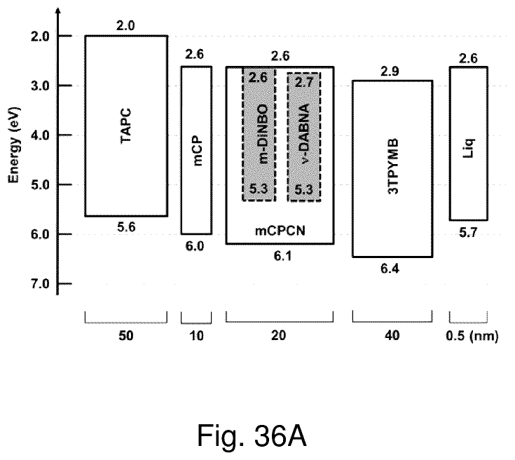

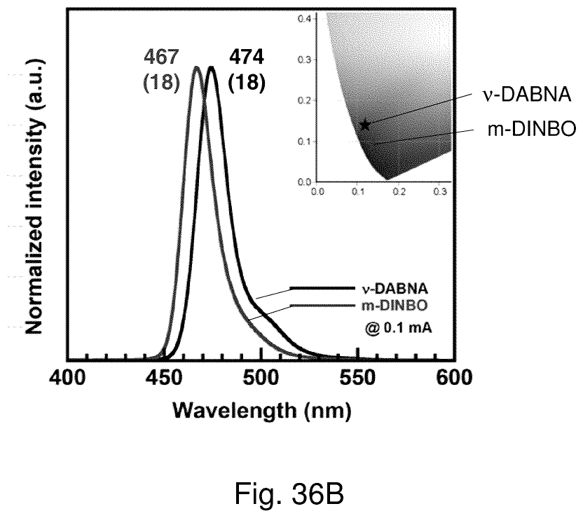

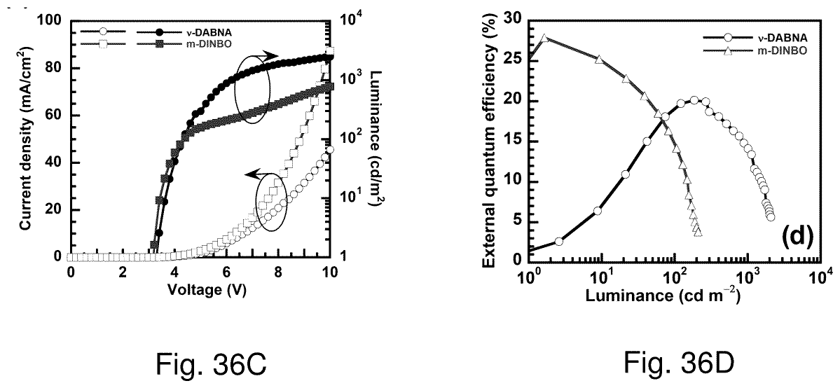

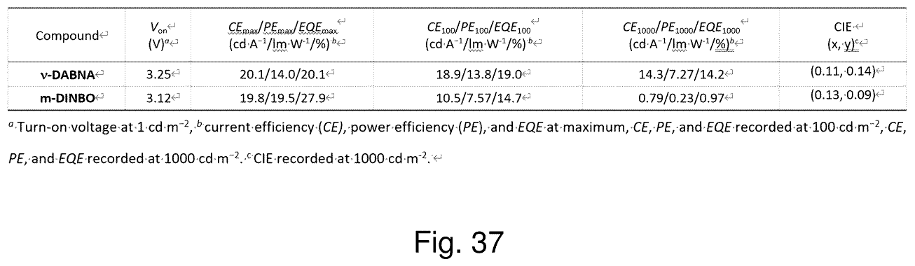

Furthermore, these hyper-OLED devices based on f-CN1 showed blue luminescence with a FWHM of 19 nm and CIE (0.12, 0.16) for v-DABNA, and a FWHM of 20 nm and CIE (0.13, 0.10) for m-DINBO (FIG. 33). As suggested in the photophysical analyses, the highly narrowed EL spectra were obtained without the emission from both the neighboring materials and Ir(III) dopant sensitizer. The J-V-L characteristics displayed in FIG. 34 show that these hyper-OLEDs displayed greater CE compared with those without employment of f-CN1, indicating that f-CN1 helps to increase the carrier injection. Both hyper-OLEDs achieved the EQEₘₐₓ of over 30% (FIGS. 29 and 35), apparently surpassing those of the corresponding purely phosphorescent OLED (EQE=20-28%) (FIGS. 36A-36D and FIG. 37). A significantly reduced efficiency roll-off was observed in these hyper-OLED devices. The possible reasons can be attributed to (i) the shorter τ_{obs} value in the ternary system (τ_{obs}˜4.2 s) than in the binary system (τ_{obs}=5-64 s) with solely the organoboron MRTADF emitter and (ii) the better carrier balance factor.

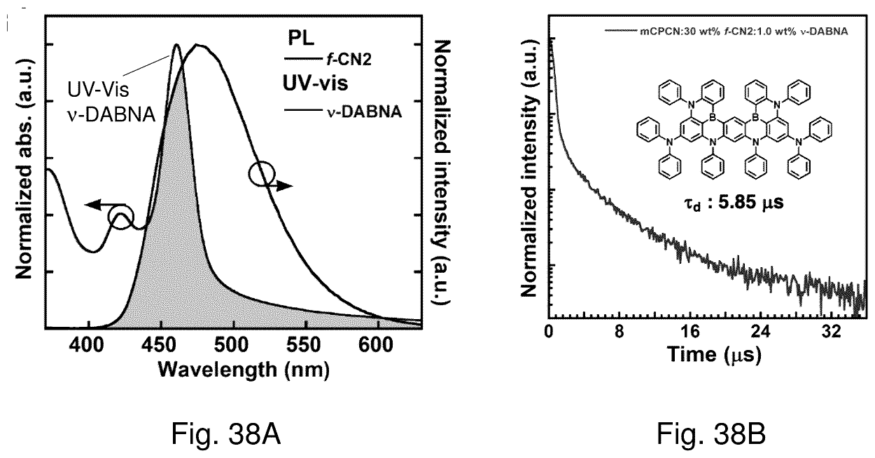

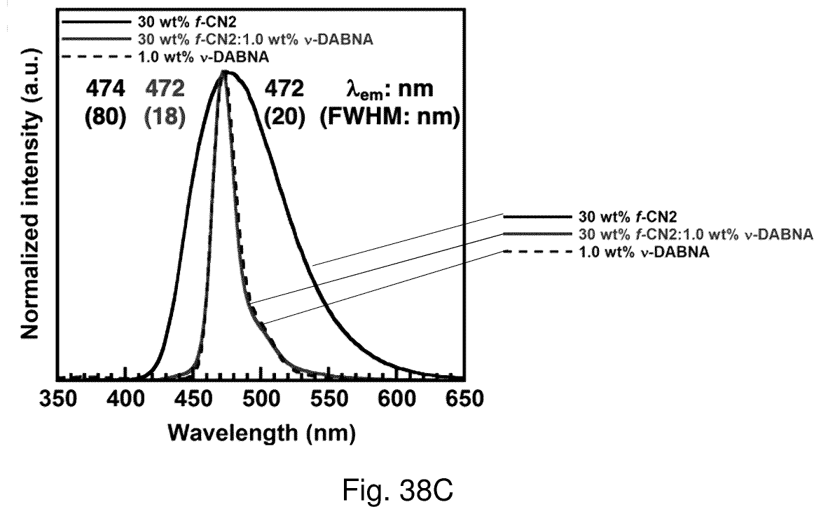

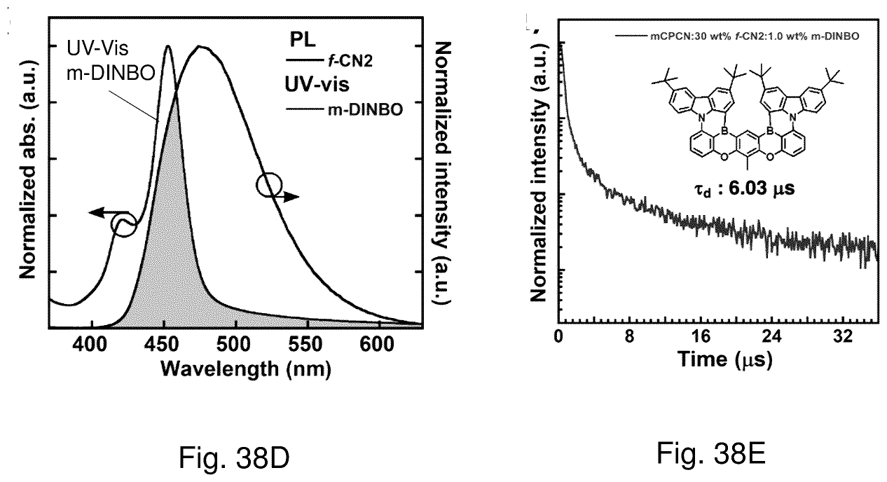

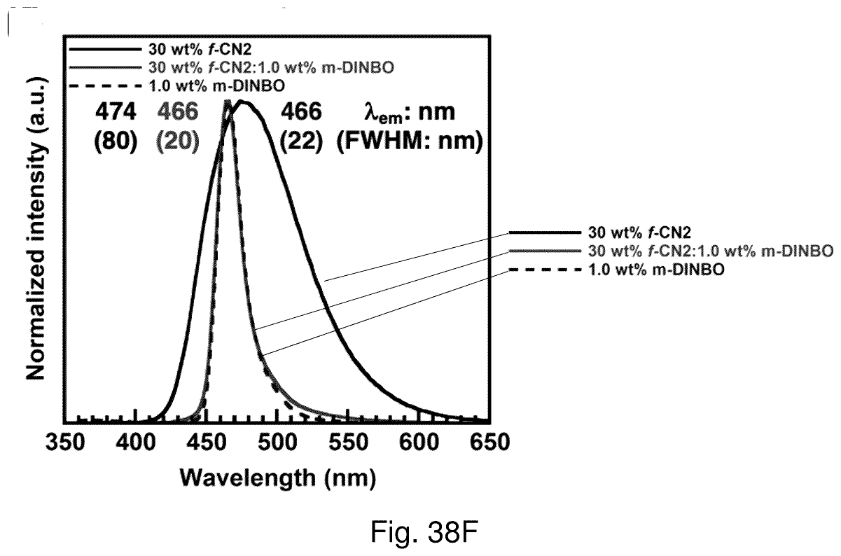

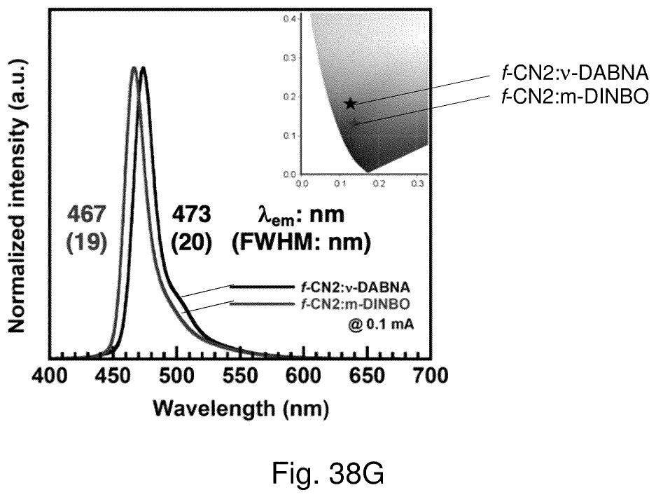

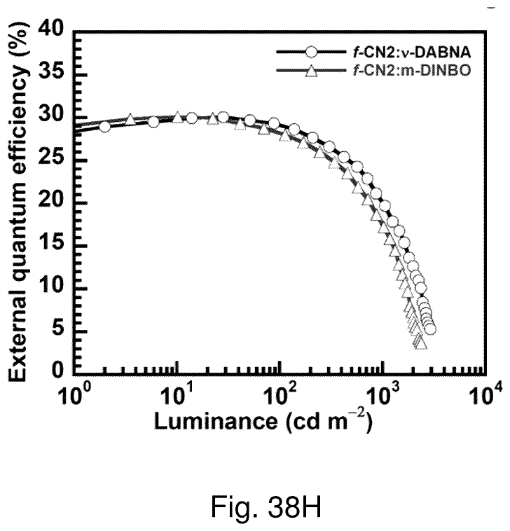

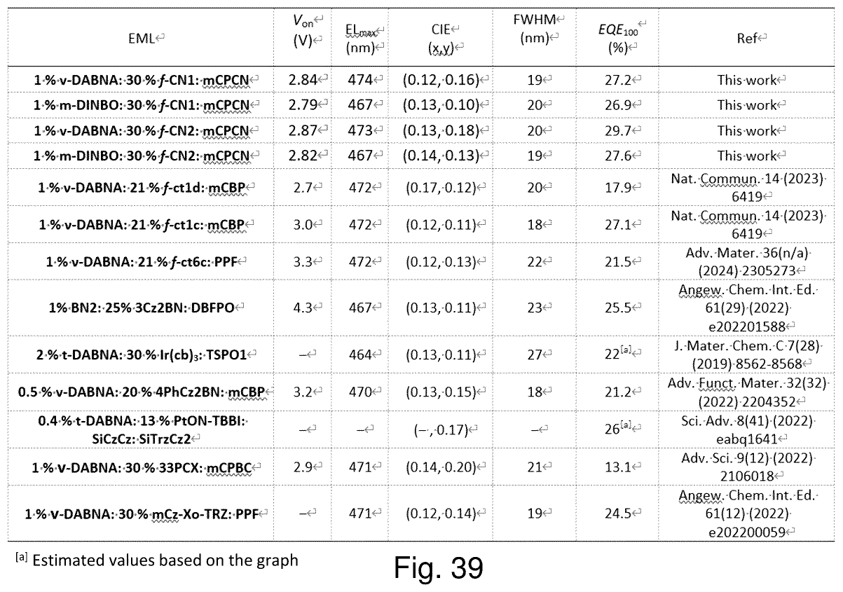

Furthermore, the second emitter f-CN2 can also be used as a sensitizer in fabrication of blue hyper-OLEDs and achieved high EQE values over 30% (FIGS. 38A-38H). These values are comparable to the efficiencies at a practical luminance of 100 cd·m⁻² observed among reported Ir(III) and Pt(II) phosphors and TADF emitters sensitized hyper-OLEDs devices (c.f. FIG. 39). These results showed that the Ir(III) carbene emitters f-CN1 and f-CN2 are superior in realizing highly efficient hyper-OLED with both the blue MR-TADF emitters employed in current studies.

### Example 16

Performance of OLED and Hyper-OLED Devices Derived from Complexes f-Ir(ptBp) and f-Ir(tBpp) (Complexes 47 and 48)

To examine the electroluminescent (EL) characteristics, f-Ir(tBpp)₃ and f-Ir(ptBp)₃ were used as sensitizers for constructing both phosphorescent and hyper-OLED devices. Phosphorescent OLEDs are known to offer the full utilization of all excitons generated during operation, while hyper-OLEDs exhibit another capacity to further improve efficiency by transferring energy from sensitizers to fluorescent emitters. It is believed that the adjustable emission energy, enhanced spin-orbit coupling, and a greater MLCT fraction designates these Ir(III) carbene emitters as promising candidates for realizing effective FRET.

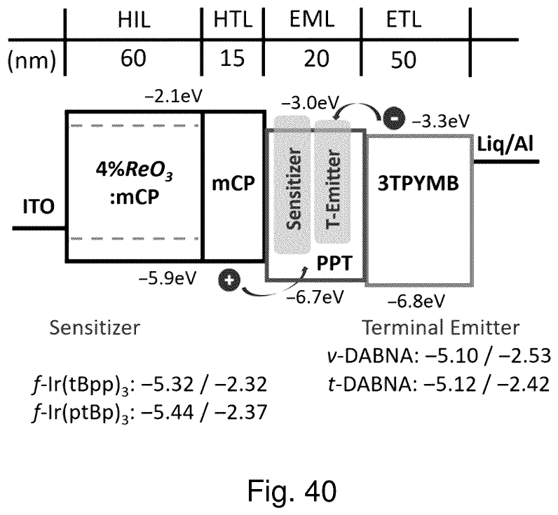

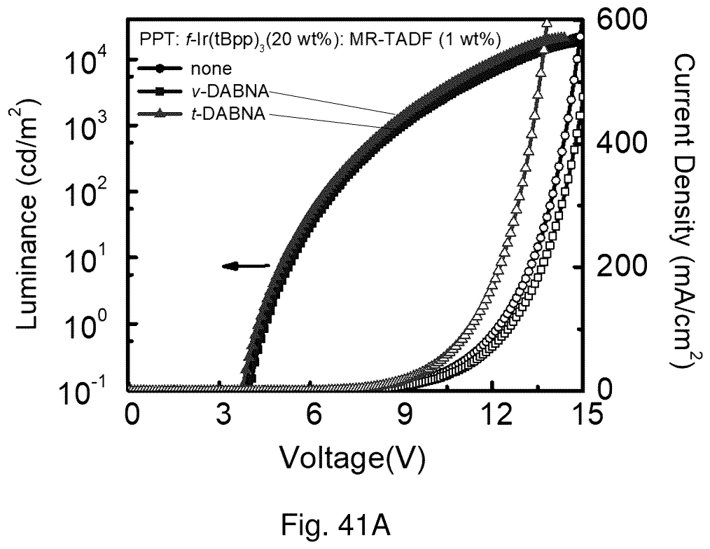

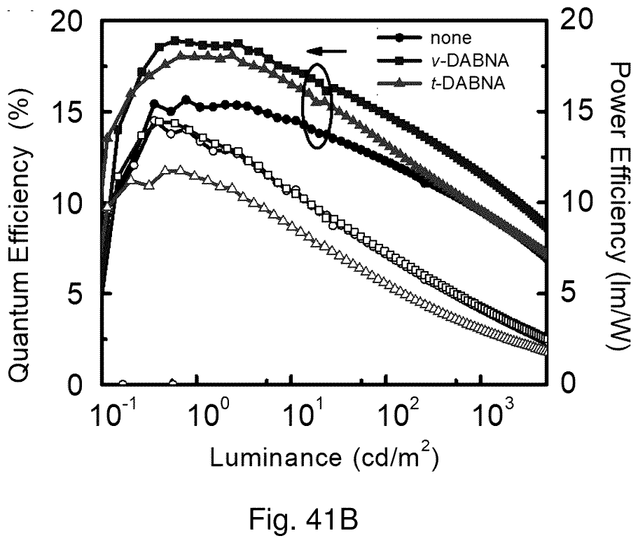

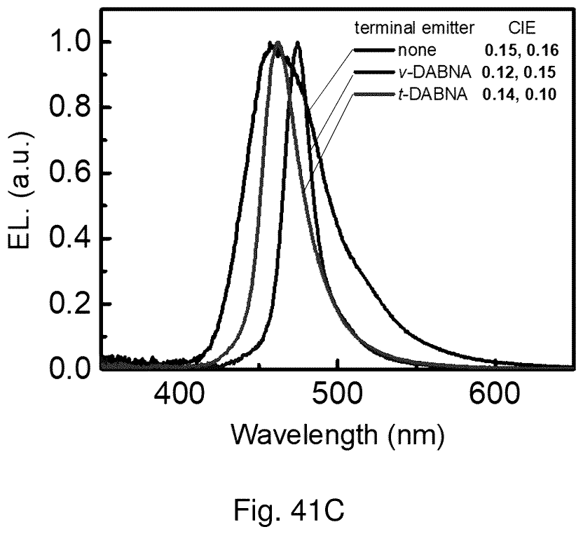

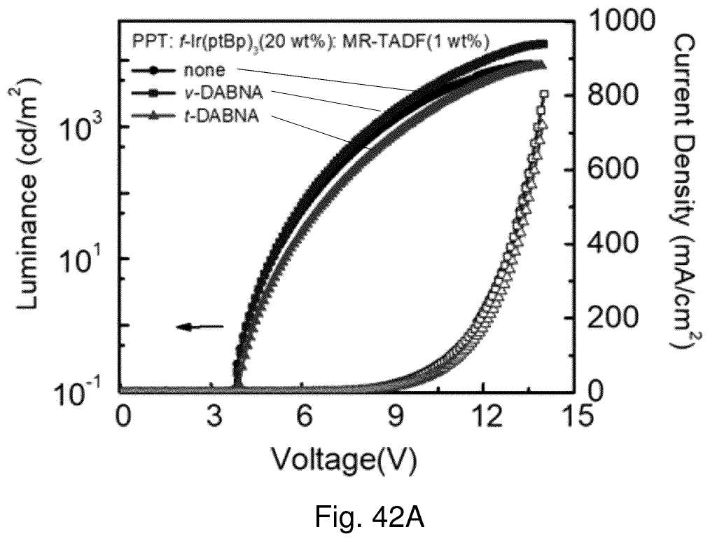

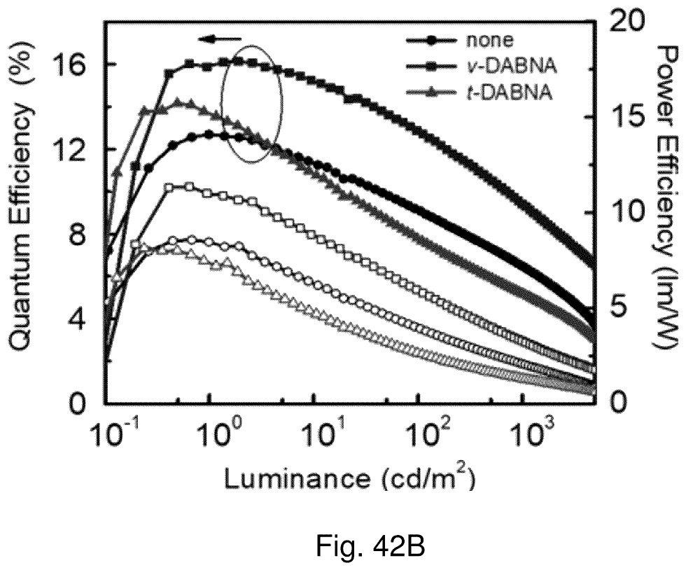

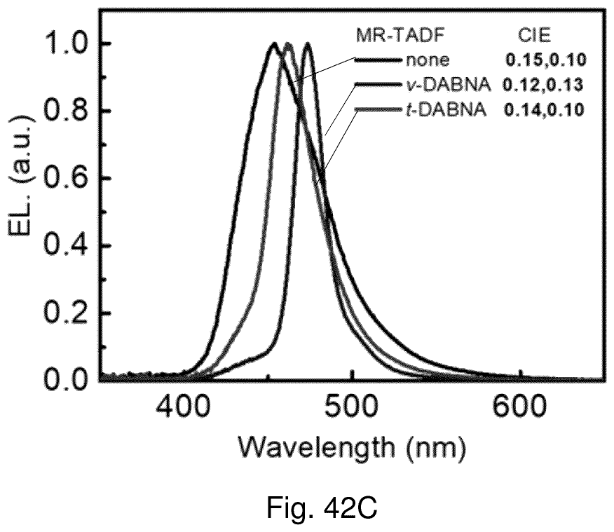

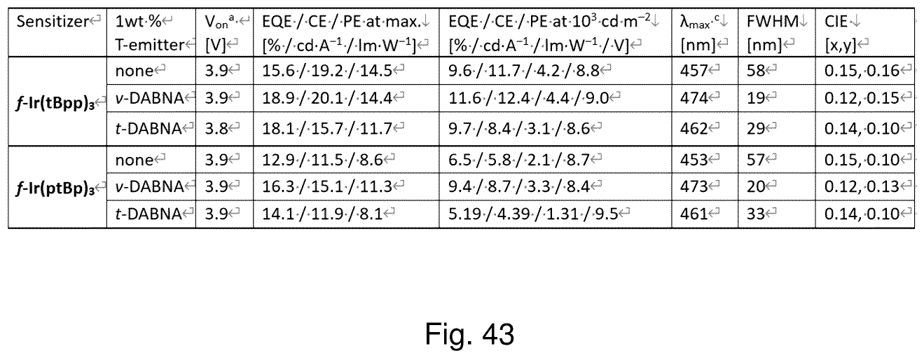

The respective phosphorescent and hyper-OLEDs were constructed using the device structure: indium tin oxide (ITO)/4 wt % rhenium oxide (ReO₃): N,N-dicarbazolyl-3,5-benzene (mCP) (60 nm)/mCP (15 nm)/EML (20 nm)/tris-[3-(3-pyridyl)mesityl]borane (3TPYMB) (50 nm)/lithium 8-hydroxyquinolinolate (Liq) (0.5 nm)/Al (100 nm) (FIG. 40). The hole-transporting layer (HTL) and electron-transporting layer (ETL) consisted of mCP and 3TPYMB, respectively. Thin layers of 4 wt % ReO₃ doped mCP and Liq were also applied to enhance the carrier and charge injection from the respective electrodes. The emissive layer (EML) contained 20 wt % Ir(III) metal phosphors (f-Ir(tBpp)₃ and f-Ir(ptBp)₃) and additional 1 wt % terminal emitters (v-DABNA and t-DABNA) for hyper-OLEDs incorporated into the host material, 2,8-bis(diphenylphosphoryl)dibenzo[b,d]thiophene (PPT). Their EL characteristics are presented in FIGS. 41A-41C and FIGS. 42A-42C, together with the pertinent parameters that consolidated in FIG. 43.

To confirm the device design of this work, the EL characteristics were explored without the addition of MR-TADF terminal emitter. These devices displayed a progressive hypsochromic shifting from sky blue to blue with peak max. at 457, and 453 nm for f-Ir(tBpp)₃ and f-Ir(ptBp)₃, respectively. They were also accompanied by a decrease of full width at half maximum (FWHM) from 81 nm, 58 nm, and to 51 nm, aligning well with their photoluminescence (PL) spectra (FIG. 8B). In comparison to the devices with f-Ir(tBpp)₃, the device with f-Ir(ptBp)₃ demonstrated a slightly superior chromaticity coordinates CIE_{x,y} of 0.15, 0.10 for deep-blue emission. On the other hand, the device based on f-Ir(tBpp)₃ demonstrated the highest efficiency, displaying a maximum external quantum efficiency (EQEₘₐₓ) of 15.6%, a maximum current efficiency (CEₘₐₓ) of 19.2 cd A⁻¹, and a maximum power efficiency (PEₘₐₓ) of 14.5 lm W⁻¹. Conversely, relatively inferior efficiencies, i.e., EQEₘₐₓ, CEₘₐₓ, and PEₘₐₓ values of 12.9%, 11.5 cd A⁻¹, 8.6 lm W⁻¹ were observed for f-Ir(ptBp)₃. The efficiencies seemed to follow the photoluminescence quantum yield (Φ_{PL}) recorded in toluene solution (FIG. 8B) and both the PMMA polymer matrix and PPT host material (FIG. 9B), while f-Ir(tBpp)₃ possesses the faster radiative lifetime among the studied Ir(III) complexes.

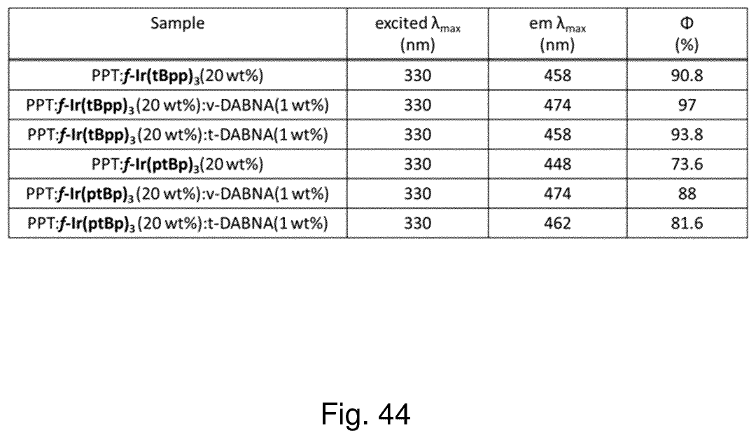

With the objective of achieving deep-blue hyper-OLEDs, a low conc. of MR-TADF terminal emitters (v-DABNA and t-DABNA) was next incorporated into the EML. FIG. 40 illustrates that all Ir(III) dopants possess a fitted energy level arrangement with respect to that of v-DABNA and t-DABNA. Consequently, the sensitizers could suppress the electron trapping in the EML. The concentration is optimized to 1 wt % to prevent undesired concentration quenching. As depicted in FIG. 43, the incorporation of both v-DABNA and t-DABNA have given the substantial enhancements in efficiencies and reduction in FWHM. Moreover, PLQY of the blended thin film of v-DABNA and t-DABNA with the same blending ratios of the Ir(III) phosphors and PPT host are provided in FIG. 44. The high EQEₘₐₓ of devices are in accordance with the results of the high PLQY of blend-films. Notably, the EL performances of f-Ir(tBpp)₃ sensitized device are generally better than that of the f-Ir(ptBp)₃ based device. The deep blue hyper-OLED devices with f-Ir(tBpp)₃ have achieved remarkable EQEₘₐₓ values of 18.9% and 18.1% for terminal emitter v-DABNA and t-DABNA, representing a substantial rise of EQEₘₐₓ in reference to that of parent device (15.6%). Hence, these hyper-OLEDs also exhibited lower turn-on voltages and higher max. EQE and EQE at a brightness of 1000 cd m⁻² in comparison to the pure MR-TADF devices recorded using v-DABNA under identical device architecture. Furthermore, the EL spectrum also exhibited a large reduction in FWHM from 58 nm of parent device to 19 nm and 29 nm for terminal emitter v-DABNA and t-DABNA, respectively.

The invention has been given by way of example only, and various other modifications of and/or alterations to the described embodiment may be made by persons skilled in the art without departing from the scope of the invention as specified in the appended claims.

1. A metal carbene complex for organic light emitting diodes (OLEDs) comprising a ligand L having Formula (I): 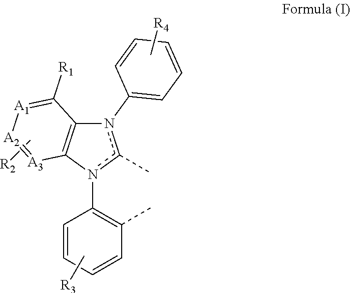
wherein:
R₁ is a peri-substituent selected from the group consisting of alkyl, haloalkyl, alkoxy, aryloxy, aryl, nitrile, and isonitrile;
R₂ represents mono, di, or tri substitutions;
R₃ and R₄ each represent mono or di substitutions;
wherein R₂, R₃ and R₄ are each independently selected from the group consisting of hydrogen, alkyl, haloalkyl, alkoxy, aryloxy, aryl, nitrile, isonitrile, cyanate, isocyanate, and a combination thereof;
A₁, A₂ and A₃ are each independently selected from group consisting of C and N, provided that A₁, A₂ and A₃ are not N at the same time; and
the ligand L is coordinated to a metal M having an atomic number greater than 40.

2. The metal carbene complex as claimed in claim 1, wherein R₁ is selected from the group consisting of C1-C10 linear or branched alkyl, unsubstituted or substituted phenyl, trifluoromethyl, and nitrile.

3. The metal carbene complex as claimed in claim 1, wherein R₁ is selected from the group consisting of C1-C4 linear or branched alkyl, unsubstituted phenyl, trifluoromethyl, and nitrile.

4. The metal carbene complex as claimed in claim 1, wherein R₂ is selected from the group consisting of hydrogen, C1-C10 linear or branched alkyl, unsubstituted or substituted phenyl, trifluoromethyl, nitrile, and a combination thereof.

5. The metal carbene complex as claimed in claim 1, wherein R₃ and R₄ are each independently selected from the group consisting of hydrogen, C1-C10 linear or branched alkyl, trifluoromethyl, nitrile, and a combination thereof.

6. The metal carbene complex as claimed in claim 1, wherein when either R₃ or R₄ includes an alkyl, the maximum number of the alkyl is 2.

7. The metal carbene complex as claimed in claim 1, wherein R₃ and R₄ are each independently located at para-position, meta-position or at both the para- and meta-positions.

8. The metal carbene complex as claimed in claim 1, wherein the metal M is iridium or platinum.

9. The metal carbene complex as claimed in claim 1, wherein the metal carbene complex is homoleptic.

10. The metal carbene complex as claimed in claim 1, wherein the metal carbene complex is heteroleptic.

11. The metal carbene complex as claimed in claim 1, wherein the ligand L has a Formula selected from the group consisting of: 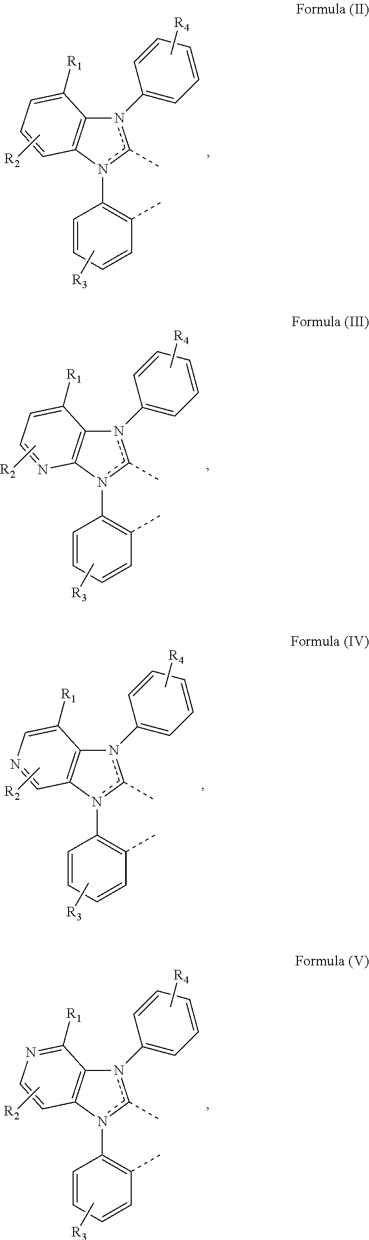 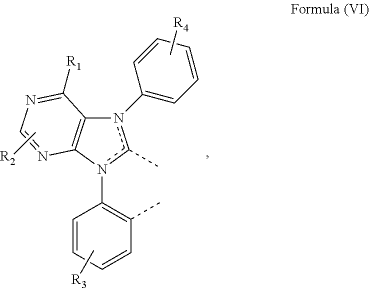
wherein:
R₁ is selected from the group consisting of methyl, ethyl, iso-propyl, tert-butyl, trifluoromethyl, and nitrile;
R₂ is a mono substitution selected from the group consisting of hydrogen, tert-butyl, trifluoromethyl, phenyl, 2,6-dimethylphenyl and nitrile; and
R₃ and R₄ each represent a mono substitution located at para- or meta-position and are each independently selected from the group consisting of hydrogen, tert-butyl, and nitrile.

12. The metal carbene complex as claimed in claim 1 having a Formula selected from the group consisting of: 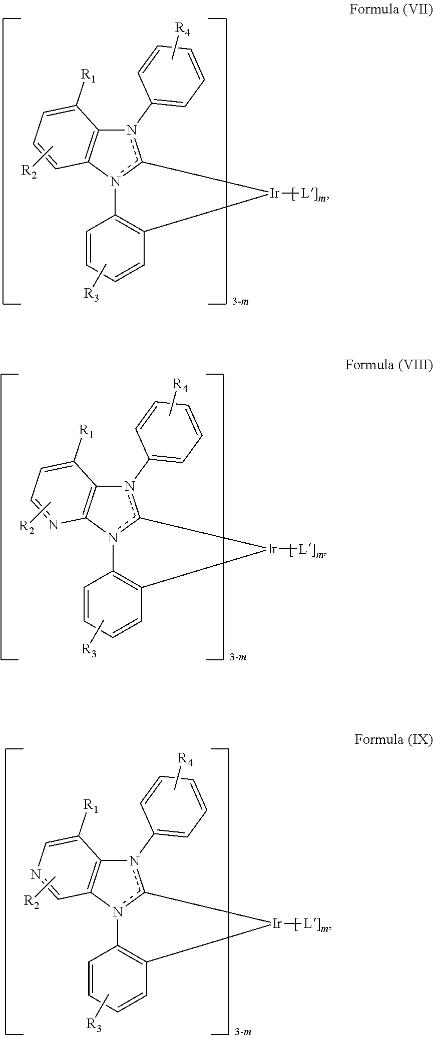 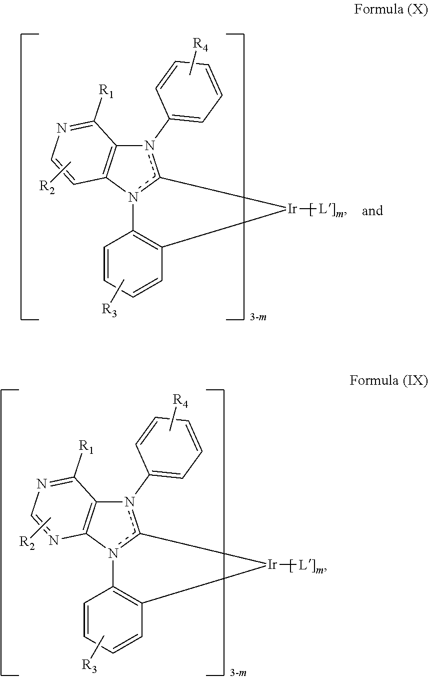
wherein:
R₁ is selected from the group consisting of methyl, ethyl, iso-propyl, tert-butyl, trifluoromethyl, and nitrile;
R₂ represents a mono substitution selected from the group consisting of hydrogen, tert-butyl, trifluoromethyl, phenyl, 2,6-dimethylphenyl and nitrile;
R₃ and R₄ each represent a mono substitution located at para- or meta-position and are each independently selected from the group consisting of hydrogen, tert-butyl, and nitrile;
L′ is a different ligand; and
m is 0, 1, or 2.

13. The metal carbene complex as claimed in claim 12 is a facial isomer.

14. The metal carbene complex as claimed in claim 12, wherein L′ has a Formula of: 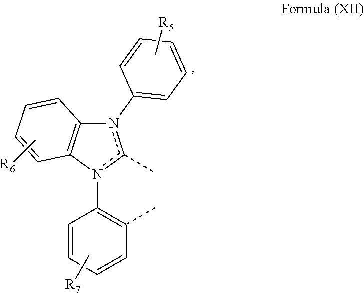
wherein R₅, R₆, and R₇ each represent mono, di, tri, or tetra substitutions; and
wherein R₅, R₆, and R₇ each independently selected from the group consisting of hydrogen, alkyl, haloalkyl, alkoxy, aryloxy, aryl, nitrile, isonitrile, cyanate, and isocyanate, and a combination thereof.

15. The metal carbene complex as claimed in claim 14, wherein L′ has a Formula selected from the group consisting of:

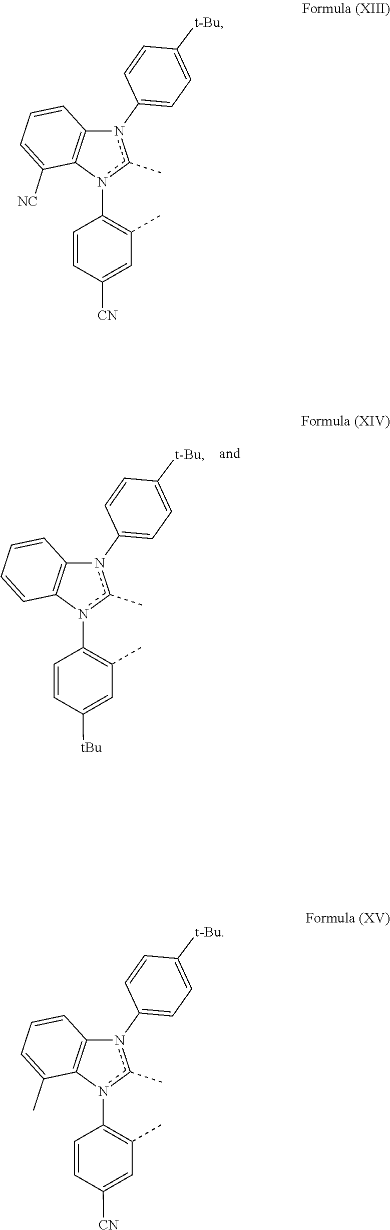

16. The metal carbene complex as claimed in claim 1 further having a Formula selected from the group consisting of: 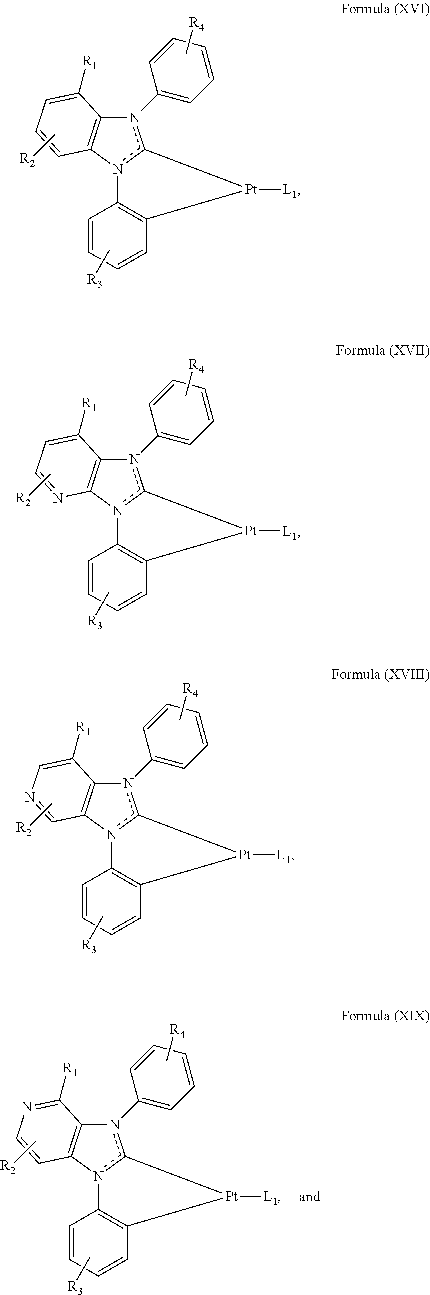 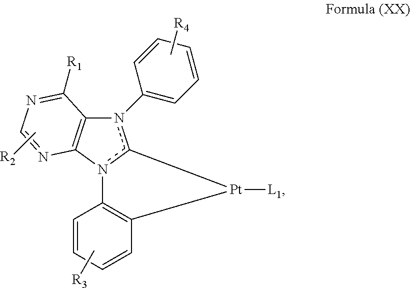
wherein:
R₁ is selected from the group consisting of methyl, ethyl, iso-propyl, tert-butyl, trifluoromethyl, and nitrile;
R₂ represents a mono substitution selected from the group consisting of hydrogen, tert-butyl, trifluoromethyl, phenyl, 2,6-dimethylphenyl and nitrile;
R₃ and R₄ each represent a mono substitution located at para- or meta-position and are each independently selected from the group consisting of hydrogen, tert-butyl, and nitrile; and
L₁ is a different bidentate ligand.

17. The metal carbene complex as claimed in claim 16, wherein L₁ is selected from the group consisting of: 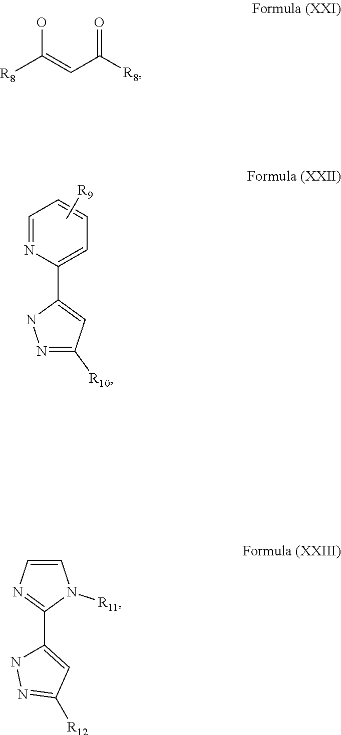
wherein:
R₈ is selected from the group consisting of hydrogen, alkyl, haloalkyl, aryl, and a combination thereof;
R₉ represents mono, di, tri, or tetra substitution, and is selected from the group consisting of hydrogen, alkyl, haloalkyl, alkoxy, aryloxy, aryl, nitrile, isonitrile, cyanate, isocyanate, and a combination thereof; and
R₁₀, R₁₁ and R₁₂ are each independently selected from the group consisting of hydrogen, alkyl, haloalkyl, alkoxy, aryloxy, aryl, nitrile, isonitrile, cyanate, isocyanate, and a combination thereof.

18. An organic light emitting diodes comprising an emissive layer including at least one metal carbene complex as claimed in claim 1.

19. The organic light emitting diodes as claimed in claim 18, wherein the emissive layer further includes a host selected from the group consisting of mCP, mCPCN, mCBP, and DPEPO, to which the at least one metal carbene complex is doped.

20. The organic light emitting diodes as claimed in claim 18, wherein the emissive layer further includes at least one organoboron terminal emitter including v-DABNA, m-DINBO, and t-DABNA.

21. The organic light emitting diodes as claimed in claim 18, wherein the at least one metal carbene complex is about 5 wt % to about 30 wt % of the emissive layer.

22. The organic light emitting diodes as claimed in claim 20, wherein the at least one organoboron terminal emitter is about 1 wt % of the emissive layer.

23. The organic light emitting diodes as claimed in claim 18 further comprising:
an anode and a cathode, between which the emissive layer is disposed;
a hole injection layer disposed between the anode and the emissive layer;
a hole transport layer disposed between the hole injection layer and the emissive layer; and
an electron transport layer disposed between the cathode and the emissive layer.

24. The organic light emitting diodes as claimed in claim 23, wherein the hole transport layer is in direct contact with the hole injection layer and the emissive layer.

25. The organic light emitting diodes as claimed in claim 23 further including an electron injection layer disposed between and is in direct contact with the cathode and the electron transport layer.
